(19) United States
(12) Patent Application Publication
(10) Pub. No.: US 2026/0150496 A1
(43) Pub. Date: May 28, 2026

(54) ACTIVE-MATRIX ORGANIC ELECTROLUMINESCENT DISPLAY

(71) Applicant: BEIJING SUMMER SPROUT TECHNOLOGY CO., LTD., Beijing (CN)

(72) Inventors: Zhihao Cui, Beijing (CN); Renjie Zheng, Beijing (CN); Xingxing Chai, Beijing (CN); Xiaoyong Zhang, Beijing (CN); Menglan Xie, Beijing (CN); Jing Wang, Beijing (CN); Chi Yuen Raymond Kwong, Beijing (CN); Chuanjun Xia, Beijing (CN)

(73) Assignee: BEIJING SUMMER SPROUT TECHNOLOGY CO., LTD., Beijing (CN)

(21) Appl. No.: 19/340,047

(22) Filed: Sep. 25, 2025

(30) Foreign Application Priority Data
Sep. 27, 2024 (CN) 202411363091.5
Sep. 15, 2025 (CN) 202511313931.1

(51) Int. Cl. H10K 50/19; H10K 59/12; H10K 85/30; H10K 85/40; H10K 85/60; H10K 101/40

(52) U.S. Cl. CPC H10K 50/19; H10K 59/12; H10K 85/342; H10K 85/40; H10K 85/626; H10K 85/633; H10K 85/636; H10K 85/654; H10K 85/656; H10K 85/6572; H10K 85/6574; H10K 85/6576; H10K 2101/40

(57) ABSTRACT

Provided is an active-matrix organic electroluminescent display which comprises a stacked organic electroluminescent device. The stacked organic electroluminescent device comprises at least two light-emitting units. At least one common p-type charge generation layer is comprised between two adjacent light-emitting units. The common p-type charge generation layer comprises a first organic material and a second organic material that satisfy a particular energy level relationship. The common p-type charge generation layer has a particular high doping proportion and a particular low lateral conductivity per unit doping. Since the common p-CGL in the active-matrix OLED display of the present disclosure comprises a first organic material and a second organic material that satisfy a particular energy level relationship and has a particular low lateral conductivity per unit doping, the device can obtain excellent device performance while the crosstalk between the pixels is inhibited.

### CROSS-REFERENCE TO RELATED APPLICATION(S)

This application claims priority to Chinese Patent Application No. 202411363091.5 filed on Sep. 27, 2024, and Chinese Patent Application No. 202511313931.1 filed on Sep. 15, 2025, the disclosure of which are incorporated herein by reference in its entireties.

### TECHNICAL FIELD

The present disclosure relates to an active-matrix organic electroluminescent display. More particularly, the present disclosure relates to an active-matrix organic electroluminescent display comprising a stacked organic electroluminescent device.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and Van Slyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and van Slyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

For an active-matrix organic electroluminescent display comprising a stacked organic electroluminescent device, the crosstalk between pixels of the active-matrix organic electroluminescent display is generally caused by the use of a p-type conductive dopant in a common layer, for example, a common p-type charge generation layer. Using the p-type conductive dopant is conducive to improving device performance. Generally, increasing a doping proportion of the p-type conductive dopant is more conducive to improving the device performance. However, an excessively high doping proportion of the p-type conductive dopant causes the existence of a large number of holes in the common layer. Once more holes laterally migrate from one pixel to other pixels via the common layer, pixel or color crosstalk is caused. When a certain particular pixel is displayed, one or more surrounding pixels may also be lit, causing that an unexpected crosstalk phenomenon occurs and a display effect of the display is affected. Therefore, while ensuring that each pixel has excellent performance such as a low voltage and high efficiency, how to inhibit or even eliminate the lateral crosstalk between pixels is an important problem that the industry has been paying attention to and performing research and development on.

### SUMMARY

The present disclosure discloses an active-matrix organic electroluminescent display to solve at least part of the above-mentioned problems. The display comprises a stacked organic electroluminescent device. The stacked organic electroluminescent device comprises at least two light-emitting units. At least one common p-type charge generation layer is comprised between two adjacent light-emitting units. The common p-type charge generation layer comprises a first organic material and a second organic material that satisfy a particular energy level relationship. The common p-type charge generation layer has a particular high doping proportion and a particular low lateral conductivity per unit doping. The energy level difference, doping proportion and lateral conductivity per unit doping of the materials in the common p-type charge generation layer are optimized and adjusted so that the device has comprehensive advantages of a low voltage and high efficiency. Moreover, since the common p-type charge generation layer has a low lateral conductivity per unit doping, it is ensured that the lateral migration amount of holes in the common p-type charge generation layer is at a low level, significantly inhibiting the lateral crosstalk between pixels in the display and having apparent advantages in commercial application.

According to an embodiment of the present disclosure, disclosed is an active-matrix organic electroluminescent display comprising a plurality of pixels;
wherein each of the plurality of pixels comprises at least one stacked organic electroluminescent device;
the stacked organic electroluminescent device comprises an anode, a cathode and at least two light-emitting units disposed between the anode and the cathode;
wherein at least one common p-type charge generation layer is comprised between two adjacent light-emitting units, and the common p-type charge generation layer is shared by at least two pixels;
the common p-type charge generation layer comprises a first organic material and a second organic material;
a LUMO energy level of the first organic material is denoted as LUMO_{first_organic_material}, a HOMO energy level of the second organic material is denoted as HOMO_{second_organic_material}, and −0.1 eV≤LUMO_{first_organic_material}−HOMO_{second_organic_material}<0.20 eV;

a mass doping proportion of the first organic material in the common p-type charge generation layer is A %, and 6≤A≤20; and

a lateral conductivity of the common p-type charge generation layer is B_{A}, a lateral conductivity per unit doping of the common p-type charge generation layer is σ_{A}, wherein σ_{A}=B_{A}/A, and at least one σ_{A} satisfies 0.05×10⁻⁴ S/m≤σ_{A}≤1.0×10⁻⁴ S/m.

According to an embodiment of the present disclosure, further disclosed is an electronic device comprising the active-matrix organic electroluminescent display in the preceding embodiment.

The present disclosure discloses an active-matrix organic electroluminescent display with a particular device structure. The common p-type charge generation layer of the active-matrix organic electroluminescent display comprises the first organic material and the second organic material that have a particular energy level difference and particular high doping proportions. The aspects such as voltage and efficiency are improved, and the active-matrix organic electroluminescent display has excellent overall performance. Moreover, since the common p-type charge generation layer has a low lateral conductivity per unit doping, it is ensured that the lateral migration amount of holes in the organic layer is at a low level, significantly inhibiting the lateral crosstalk of pixels in the display and having apparent advantages in commercial application.

### BRIEF DESCRIPTION OF DRAWINGS

FIG. 1 is a structure diagram of a single-layer organic light-emitting device.

FIG. 2 is a structure diagram of another single-layer organic light-emitting device.

FIG. 3 is a structure diagram of a stacked organic light-emitting device comprised in a display of the present disclosure.

FIG. 4 is a structure diagram of an active-matrix organic electroluminescent display according to the present disclosure.

FIG. 5 is a schematic diagram of a device structure of a crosstalk test device.

### DETAILED DESCRIPTION

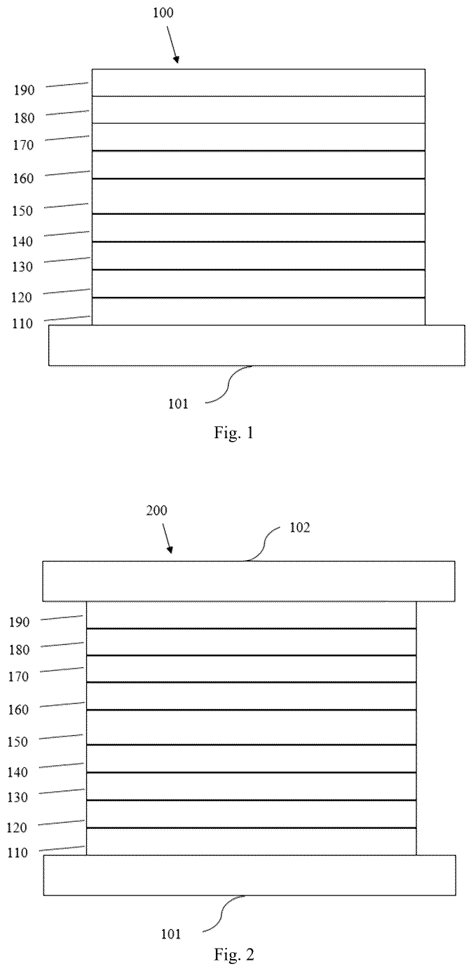

OLEDs can be fabricated on various types of substrates such as glass, plastic, and metal foil. FIG. 1 schematically shows a single-layer organic light-emitting device 100 without limitation. Device 100 may include a substrate 101, an anode 110, a hole injection layer 120, a hole transport layer 130, an electron blocking layer 140, an emissive layer 150, a hole blocking layer 160, an electron transport layer 170, an electron injection layer 180 and a cathode 190. The figures are not necessarily drawn to scale. Some of the layers in the figures can also be omitted as needed. For example, the hole blocking layer 160 can be omitted as needed. Device 100 may be fabricated by depositing the layers described in order. The properties and functions of these various layers, as well as example materials, are described in more detail in U.S. Pat. No. 7,279,704 at cols. 6-10, the contents of which are incorporated by reference herein in its entirety.

More examples for each of these layers are available. For example, a flexible and transparent substrate-anode combination is disclosed in U.S. Pat. No. 5,844,363, which is incorporated by reference herein in its entirety. An example of a p-doped hole transport layer is m-MTDATA doped with F4-TCNQ at a molar ratio of 50:1, as disclosed in U.S. Patent Application Publication No. 2003/0230980, which is incorporated by reference herein in its entirety. Examples of host materials are disclosed in U.S. Pat. No. 6,303,238 to Thompson et al., which is incorporated by reference herein in its entirety. An example of an n-doped electron transport layer is BPhen doped with Li at a molar ratio of 1:1, as disclosed in U.S. Patent Application Publication No. 2003/0230980, which is incorporated by reference herein in its entirety. U.S. Pat. Nos. 5,703,436 and 5,707,745, which are incorporated by reference herein in their entireties, disclose examples of cathodes including composite cathodes having a thin layer of metal such as Mg:Ag with an overlying transparent, electrically-conductive, sputter-deposited ITO layer. The theory and use of blocking layers are described in more detail in U.S. Pat. No. 6,097,147 and U.S. Patent Application Publication No. 2003/0230980, which are incorporated by reference herein in their entireties. Examples of injection layers are provided in U.S. Patent Application Publication No. 2004/0174116, which is incorporated by reference herein in its entirety. A description of protective layers may be found in U.S. Patent Application Publication No. 2004/0174116, which is incorporated by reference herein in its entirety.

The layered structure described above is provided by way of non-limiting examples. Functional OLEDs may be achieved by combining the various layers described in different ways, or layers may be omitted entirely. It may also include other layers not specifically described. Within each layer, a single material or a mixture of multiple materials can be used to achieve optimum performance. Any functional layer may include several sublayers. For example, the emissive layer may have two layers of different emitting materials to achieve desired emission spectrum.

In one embodiment, an OLED may be described as having an “organic layer” disposed between a cathode and an anode. This organic layer may include a single layer or multiple layers.

An OLED can be encapsulated by a barrier layer. FIG. 2 schematically shows a single-layer organic light-emitting device 200 without limitation. FIG. 2 differs from FIG. 1 in that the organic light-emitting device include a barrier layer 102, which is above the cathode 190, to protect it from harmful species from the environment such as moisture and oxygen. “Barrier layer” may be a thin film encapsulation with a thickness of less than 100 micrometers, which includes one or more thin films disposed directly on the device or may be a cover glass adhered to the substrate. Any material that can provide the barrier function can be used as the barrier layer such as glass or organic-inorganic hybrid layers. The barrier layer should be placed directly or indirectly outside of the OLED device. Multilayer thin film encapsulation was described in U.S. Pat. No. 7,968,146, which is incorporated by reference herein in its entirety.

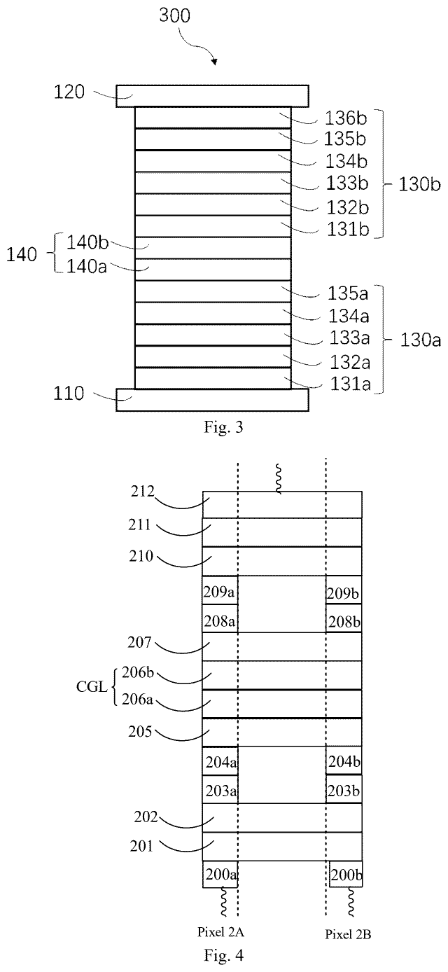

Herein, two or more OLED units can be connected in series by a charge generation layer to form a stacked OLED. FIG. 3 schematically shows a structure diagram of a stacked organic light-emitting device 300 comprised in a display of the present disclosure without limitation. The device 300 may include an anode 110, a first light-emitting unit 130a, a charge generation layer 140, a second light-emitting unit 130b and a cathode 120. The first light-emitting unit 130a includes a hole injection layer 131a, a hole transport layer 132a, an emissive layer 133a, a hole blocking layer 134a and an electron transport layer 135a. Some layers in the first light-emitting unit may be omitted or other layers not explicitly described may be included in the first light-emitting unit as needed, which is not repeated here. The charge generation layer 140 includes an n-type charge generation layer 140a and a p-type charge generation layer 140b. The n-type charge generation layer 140a may also have a function of an electron injection layer of the first light-emitting unit, the p-type charge generation layer 140b may also have a function of a hole injection layer of the second light-emitting unit, and the n-type charge generation layer may also be regarded as an electron injection layer. Other layers may also be included between the n-type charge generation layer 140a and the p-type charge generation layer 140b as needed. For example, a buffer layer may also be included between the n-type charge generation layer 140a and the p-type charge generation layer 140b and is not shown in the figure. The second light-emitting unit 130b includes a hole injection layer 131b, a hole transport layer 132b, an emissive layer 133b, a hole blocking layer 134b, an electron transport layer 135b and an electron injection layer 136b. Some layers in the second light-emitting unit may be omitted as needed. For example, when the p-type charge generation layer 140b also has the function of the hole injection layer of the second light-emitting unit, the hole injection layer 131b in the second light-emitting unit may be omitted or other layers not explicitly described may be included in the second light-emitting unit, which is not repeated here. A barrier layer may also be included above the cathode 120 and is not shown in the figure.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

The materials and structures described herein may be used in other organic electronic devices listed above.

As used herein, “top” means furthest away from the substrate, while “bottom” means closest to the substrate. Where a first layer is described as “disposed over” a second layer, the first layer is disposed further away from the substrate. There may be other layers between the first and second layers, unless it is specified that the first layer is “in contact with” the second layer. For example, a cathode may be described as “disposed over” an anode, even though there are various organic layers in between.

As used herein, “solution processible” means capable of being dissolved, dispersed, or transported in and/or deposited from a liquid medium, either in solution or suspension form.

Herein, the term “independent driving” means that two or more OLED devices are controlled separately through active-matrix driving technology and each pixel is controlled by an independent thin-film transistor (TFT). An active-matrix organic electroluminescent display can independently control the light emission of each pixel so that the pixels can emit light continuously and independently and finally form a required image.

Herein, all “HOMO energy levels” and “LUMO energy levels” are expressed as negative values, and the smaller the numerical value (the larger the absolute value), the deeper the energy level. Herein, the expression that the energy level is larger than a certain number means that the numerical value of the energy level is larger than this number, that is, the absolute value of the energy level is smaller. For example, “−5.30 eV≤LUMO_{first_organic_material}≤−4.80 eV” herein means that the numerical value of the LUMO energy level of the first organic material is equal to or larger than-5.30 eV, and the numerical value of the LUMO energy level of the first organic material is equal to or more negative than-4.80 eV. For example, the LUMO energy level of the first organic material is-5.07 eV. Herein, the expression that the energy level is smaller than a certain number means that the numerical value of the energy level is smaller than this number, that is, the numerical value of the energy level is more negative.

Herein, the energy level difference between the LUMO of the first organic material and the HOMO of the second organic material is defined as LUMO_{first_organic_material}−HOMO_{second_organic_material}.

Herein, “the mass proportion of the first organic material in the common p-type charge generation layer” represents the percentage of the mass of the first organic material in the common p-type charge generation layer to the total mass of the common p-type charge generation layer. For example, assuming that the mass of the first organic material contained in the common p-type charge generation layer is 12 milligrams and the total mass of the common p-type charge generation layer is 100 milligrams, the mass doping proportion of the first organic material in the common p-type charge generation layer is 12%.

Herein, the term “common p-type charge generation layer” refers to the common p-type charge generation layer shared by at least two pixels in the active-matrix organic electroluminescent display, that is, the common p-type charge generation layer is continuous among multiple pixels without division, for example, the common p-type charge generation layer 206b in FIG. 4.

Herein, the term “lateral conductivity per unit doping of the common p-type charge generation layer” means that in the common p-type charge generation layer, the mass doping proportion of the first organic material is A %, the lateral conductivity of the common p-type charge generation layer is B_{A}, then the lateral conductivity per unit doping of the common p-type charge generation layer is σ_{A}, wherein σ_{A}=B_{A}/A. For example, when the mass doping proportion of the first organic material in the common p-type charge generation layer is 15%, the lateral conductivity of the common p-type charge generation layer is B₁₅, then in this case, the lateral conductivity per unit doping σ₁₅ of the common p-type charge generation layer is σ₁₅=B₁₅/15.

As used herein, the term “single-layer device” means that a light-emitting layer (or multiple consecutive light-emitting layers) and a single set of hole transport layer and electron transport layer matched with the light-emitting layer (or the multiple consecutive light-emitting layers) exists between a pair of cathode and anode. Such a device with a single light-emitting layer (or multiple consecutive light-emitting layers) and transport layers matched with the single light-emitting layer (or the multiple consecutive light-emitting layers) is a “single-layer device”.

As used herein, the term “stacked organic electroluminescent device” means that multiple light-emitting units can be vertically stacked to form a stacked OLED (also referred to as a stacked OLED, a tandem OLED or a cascaded OLED) structure. The multiple light-emitting units are connected to each other by a charge generation layer. Compared with an OLED device with only one light-emitting unit (also referred to as a “single-layer device”), the stacked OLED can achieve significant improvements in performance, for example, significantly improved luminescence efficiency and a significantly increased device lifetime.

Herein, the term “p-type conductive doping material” refers to a dopant with an oxidizing ability. The dopant has a strong electron withdrawing ability, and is an electron acceptor.

Herein, materials are the “same as” or “different from” each other. The “same as” therein means that two or more materials have the same chemical structural formula or that two or more materials differ only in that hydrogen in the chemical structural formulas is partially or fully substituted with deuterium. Conversely, the term “different from” therein means that the organic materials used have different chemical structural formulas (the chemical structural formulas differ not only in that hydrogen in the molecular formulas is partially or fully substituted with deuterium).

FIG. 4 schematically shows a structure diagram of an active-matrix organic electroluminescent display according to the present disclosure without limitation. As distinguished by the dashed lines in FIG. 4, the display comprises a pixel 2A and a pixel 2B, each of the pixel 2A and the pixel 2B comprises a stacked OLED device, and the stacked OLED device comprises two light-emitting units. 200a and 200b are an anode of the pixel 2A and an anode of the pixel 2B, respectively. 201 is a common hole injection layer of first light-emitting units. 202 is a common hole transport layer of the first light-emitting units. 203a and 203b are an auxiliary light-emitting layer (a prime layer, also referred to an electron blocking layer) of the first light-emitting unit of the pixel 2A and an auxiliary light-emitting layer (a prime layer, also referred to an electron blocking layer) of the first light-emitting unit of the pixel 2B, respectively. 204a and 204b are a light-emitting layer of the first light-emitting unit of the pixel 2A and a light-emitting layer of the first light-emitting unit of the pixel 2B, respectively. 205 is a common electron transport layer of the first light-emitting units. 206a is a common n-type charge generation layer. 206b is a common p-type charge generation layer. 207 is a hole transport layer of second light-emitting units. 208a and 208b are an auxiliary light-emitting layer (a prime layer, also referred to an electron blocking layer) of the second light-emitting unit of the pixel 2A and an auxiliary light-emitting layer (a prime layer, also referred to an electron blocking layer) of the second light-emitting unit of the pixel 2B, respectively. 209a and 209b are a light-emitting layer of the second light-emitting unit of the pixel 2A and a light-emitting layer of the second light-emitting unit of the pixel 2B, respectively. 210 is a common electron transport layer of the second light-emitting units. 211 is a common electron injection layer of the second light-emitting units. 212 is a common cathode. Single drive currents are applied to the anode 200a and the anode 200b, respectively, and then each pixel operates independently. For example, if a current is applied to the pixel 2A and no current is applied to the pixel 2B, only the pixel 2A is lit. In this process, if the common p-type charge generation layer 206b has an excessively large lateral conductivity per unit doping, a current flows from the pixel 2A to the pixel 2B via the common p-type charge generation layer 206b, resulting in the light emission of the pixel 2B and color crosstalk.

In the present application, multiple pixels share the common p-type charge generation layer. Since the common p-type charge generation layer is uniform and continuous, the mass doping proportion of the first organic material in the common p-type charge generation layer is the same as the mass doping proportion of the first organic material of the single OLED device in the p-type charge generation layer, and the lateral conductivity per unit doping of the common p-type charge generation layer is also the same as the lateral conductivity per unit doping of the p-type charge generation layer of the single OLED device.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small AEs-T. These states may involve CT states. Generally, donor-acceptor luminescent materials are constructed by connecting an electron donor moiety such as amino- or carbazole-derivatives and an electron acceptor moiety such as N-containing six-membered aromatic rings.

### Definition of Terms of Substituents

Halogen or halide—as used herein includes fluorine, chlorine, bromine, and iodine.

Alkyl—as used herein includes both straight and branched chain alkyl groups. Alkyl may be alkyl having 1 to 20 carbon atoms, preferably alkyl having 1 to 12 carbon atoms, and more preferably alkyl having 1 to 6 carbon atoms. Examples of alkyl groups include a methyl group, an ethyl group, a propyl group, an isopropyl group, an n-butyl group, an s-butyl group, an isobutyl group, a t-butyl group, an n-pentyl group, an n-hexyl group, an n-heptyl group, an n-octyl group, an n-nonyl group, an n-decyl group, an n-undecyl group, an n-dodecyl group, an n-tridecyl group, an n-tetradecyl group, an n-pentadecyl group, an n-hexadecyl group, an n-heptadecyl group, an n-octadecyl group, a neopentyl group, a 1-methylpentyl group, a 2-methylpentyl group, a 1-pentylhexyl group, a 1-butylpentyl group, a 1-heptyloctyl group, and a 3-methylpentyl group. Of the above, preferred are a methyl group, an ethyl group, a propyl group, an isopropyl group, a n-butyl group, an s-butyl group, an isobutyl group, a t-butyl group, an n-pentyl group, a neopentyl group, and an n-hexyl group. Additionally, the alkyl group may be optionally substituted.

Cycloalkyl—as used herein includes cyclic alkyl groups. The cycloalkyl groups may be those having 3 to 20 ring carbon atoms, preferably those having 4 to 10 carbon atoms. Examples of cycloalkyl include cyclobutyl, cyclopentyl, cyclohexyl, 4-methylcyclohexyl, 4,4-dimethylcylcohexyl, 1-adamantyl, 2-adamantyl, 1-norbornyl, 2-norbornyl, and the like. Of the above, preferred are cyclopentyl, cyclohexyl, 4-methylcyclohexyl, and 4,4-dimethylcylcohexyl. Additionally, the cycloalkyl group may be optionally substituted.

Heteroalkyl—as used herein, includes a group formed by replacing one or more carbons in an alkyl chain with a hetero-atom(s) selected from the group consisting of a nitrogen atom, an oxygen atom, a sulfur atom, a selenium atom, a phosphorus atom, a silicon atom, a germanium atom, and a boron atom. Heteroalkyl may be those having 1 to 20 carbon atoms, preferably those having 1 to 10 carbon atoms, and more preferably those having 1 to 6 carbon atoms. Examples of heteroalkyl include methoxymethyl, ethoxymethyl, ethoxyethyl, methylthiomethyl, ethylthiomethyl, ethylthioethyl, methoxymethoxymethyl, ethoxymethoxymethyl, ethoxyethoxyethyl, hydroxymethyl, hydroxyethyl, hydroxypropyl, mercaptomethyl, mercaptoethyl, mercaptopropyl, aminomethyl, aminoethyl, aminopropyl, dimethylaminomethyl, trimethylgermanylmethyl, trimethylgermanylethyl, trimethylgermanylisopropyl, dimethylethylgermanylmethyl, dimethylisopropylgermanylmethyl, tert-butyldimethylgermanylmethyl, triethylgermanylmethyl, triethylgermanylethyl, triisopropylgermanylmethyl, triisopropylgermanylethyl, trimethylsilylmethyl, trimethylsilylethyl, trimethylsilylisopropyl, triisopropylsilylmethyl and triisopropylsilylethyl. Additionally, the heteroalkyl group may be optionally substituted.

Alkenyl—as used herein includes straight chain, branched chain, and cyclic alkene groups. Alkenyl may be those having 2 to 20 carbon atoms, preferably those having 2 to 10 carbon atoms. Examples of alkenyl include vinyl, 1-propenyl group, 1-butenyl, 2-butenyl, 3-butenyl, 1,3-butandienyl, 1-methylvinyl, styryl, 2,2-diphenylvinyl, 1,2-diphenylvinyl, 1-methylallyl, 1,1-dimethylallyl, 2-methylallyl, 1-phenylallyl, 2-phenylallyl, 3-phenylallyl, 3,3-diphenylallyl, 1,2-dimethylallyl, 1-phenyl-1-butenyl, 3-phenyl-1-butenyl, cyclopentenyl, cyclopentadienyl, cyclohexenyl, cycloheptenyl, cycloheptatrienyl, cyclooctenyl, cyclooctatetraenyl, and norbornenyl. Additionally, the alkenyl group may be optionally substituted.

Alkynyl—as used herein includes straight chain alkynyl groups. Alkynyl may be those having 2 to 20 carbon atoms, preferably those having 2 to 10 carbon atoms. Examples of alkynyl groups include ethynyl, propynyl, propargyl, 1-butynyl, 2-butynyl, 3-butynyl, 1-pentynyl, 2-pentynyl, 3,3-dimethyl-1-butynyl, 3-ethyl-3-methyl-1-pentynyl, 3,3-diisopropyl-1-pentynyl, phenylethynyl, phenylpropynyl, etc. Of the above, preferred are ethynyl, propynyl, propargyl, 1-butynyl, 2-butynyl, 3-butynyl, 1-pentynyl, and phenylethynyl. Additionally, the alkynyl group may be optionally substituted.

Aryl or an aromatic group—as used herein includes non-condensed and condensed systems. Aryl may be those having 6 to 30 carbon atoms, preferably those having 6 to 20 carbon atoms, and more preferably those having 6 to 12 carbon atoms. Examples of aryl groups include phenyl, biphenyl, terphenyl, triphenylene, tetraphenylene, naphthalene, anthracene, phenalene, phenanthrene, fluorene, pyrene, chrysene, perylene, and azulene, preferably phenyl, biphenyl, terphenyl, triphenylene, fluorene, and naphthalene. Examples of non-condensed aryl groups include phenyl, biphenyl-2-yl, biphenyl-3-yl, biphenyl-4-yl, p-terphenyl-4-yl, p-terphenyl-3-yl, p-terphenyl-2-yl, m-terphenyl-4-yl, m-terphenyl-3-yl, m-terphenyl-2-yl, o-tolyl, m-tolyl, p-tolyl, p-(2-phenylpropyl)phenyl, 4′-methylbiphenylyl, 4″-t-butyl-p-terphenyl-4-yl, o-cumenyl, m-cumenyl, p-cumenyl, 2,3-xylyl, 3,4-xylyl, 2,5-xylyl, mesityl, and m-quarterphenyl. Additionally, the aryl group may be optionally substituted.

Heterocyclic groups or heterocycle—as used herein include non-aromatic cyclic groups. Non-aromatic heterocyclic groups include saturated heterocyclic groups having 3 to 20 ring atoms and unsaturated non-aromatic heterocyclic groups having 3 to 20 ring atoms, where at least one ring atom is selected from the group consisting of a nitrogen atom, an oxygen atom, a sulfur atom, a selenium atom, a silicon atom, a phosphorus atom, a germanium atom, and a boron atom. Preferred non-aromatic heterocyclic groups are those having 3 to 7 ring atoms, each of which includes at least one hetero-atom such as nitrogen, oxygen, silicon, or sulfur. Examples of non-aromatic heterocyclic groups include oxiranyl, oxetanyl, tetrahydrofuranyl, tetrahydropyranyl, dioxolanyl, dioxanyl, aziridinyl, dihydropyrrolyl, tetrahydropyrrolyl, piperidinyl, oxazolidinyl, morpholinyl, piperazinyl, oxepinyl, thiepinyl, azepinyl, and tetrahydrosilolyl. Additionally, the heterocyclic group may be optionally substituted.

Heteroaryl—as used herein, includes non-condensed and condensed hetero-aromatic groups having 1 to 5 hetero-atoms, where at least one hetero-atom is selected from the group consisting of a nitrogen atom, an oxygen atom, a sulfur atom, a selenium atom, a silicon atom, a phosphorus atom, a germanium atom, and a boron atom. A hetero-aromatic group is also referred to as heteroaryl. Heteroaryl may be those having 3 to 30 carbon atoms, preferably those having 3 to 20 carbon atoms, and more preferably those having 3 to 12 carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridoindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, benzofuropyridine, furodipyridine, benzothienopyridine, thienodipyridine, benzoselenophenopyridine, and selenophenodipyridine, preferably dibenzothiophene, dibenzofuran, dibenzoselenophene, carbazole, indolocarbazole, imidazole, pyridine, triazine, benzimidazole, 1,2-azaborine, 1,3-azaborine, 1,4-azaborine, borazine, and aza-analogs thereof. Additionally, the heteroaryl group may be optionally substituted.

Alkoxy—as used herein, is represented by —O-alkyl, —O-cycloalkyl, —O-heteroalkyl, or —O-heterocyclic group. Examples and preferred examples of alkyl, cycloalkyl, heteroalkyl, and heterocyclic groups are the same as those described above. Alkoxy groups may be those having 1 to 20 carbon atoms, preferably those having 1 to 6 carbon atoms. Examples of alkoxy groups include methoxy, ethoxy, propoxy, butoxy, pentyloxy, hexyloxy, cyclopropyloxy, cyclobutyloxy, cyclopentyloxy, cyclohexyloxy, tetrahydrofuranyloxy, tetrahydropyranyloxy, methoxypropyloxy, ethoxyethyloxy, methoxymethyloxy, and ethoxymethyloxy. Additionally, the alkoxy group may be optionally substituted.

Aryloxy—as used herein, is represented by —O-aryl or —O-heteroaryl. Examples and preferred examples of aryl and heteroaryl are the same as those described above. Aryloxy groups may be those having 6 to 30 carbon atoms, preferably those having 6 to 20 carbon atoms. Examples of aryloxy groups include phenoxy and biphenyloxy. Additionally, the aryloxy group may be optionally substituted.

Arylalkyl—as used herein, contemplates alkyl substituted with an aryl group. Arylalkyl may be those having 7 to 30 carbon atoms, preferably those having 7 to 20 carbon atoms, and more preferably those having 7 to 13 carbon atoms. Examples of arylalkyl groups include benzyl, 1-phenylethyl, 2-phenylethyl, 1-phenylisopropyl, 2-phenylisopropyl, phenyl-t-butyl, alpha-naphthylmethyl, 1-alpha-naphthylethyl, 2-alpha-naphthylethyl, 1-alpha-naphthylisopropyl, 2-alpha-naphthylisopropyl, beta-naphthylmethyl, 1-beta-naphthylethyl, 2-beta-naphthylethyl, 1-beta-naphthylisopropyl, 2-beta-naphthylisopropyl, p-methylbenzyl, m-methylbenzyl, o-methylbenzyl, p-chlorobenzyl, m-chlorobenzyl, o-chlorobenzyl, p-bromobenzyl, m-bromobenzyl, o-bromobenzyl, p-iodobenzyl, m-iodobenzyl, o-iodobenzyl, p-hydroxybenzyl, m-hydroxybenzyl, o-hydroxybenzyl, p-aminobenzyl, m-aminobenzyl, o-aminobenzyl, p-nitrobenzyl, m-nitrobenzyl, o-nitrobenzyl, p-cyanobenzyl, m-cyanobenzyl, o-cyanobenzyl, 1-hydroxy-2-phenylisopropyl, and 1-chloro-2-phenylisopropyl. Of the above, preferred are benzyl, p-cyanobenzyl, m-cyanobenzyl, o-cyanobenzyl, 1-phenylethyl, 2-phenylethyl, 1-phenylisopropyl, and 2-phenylisopropyl. Additionally, the arylalkyl group may be optionally substituted.

Alkylsilyl—as used herein, contemplates a silyl group substituted with an alkyl group. Alkylsilyl groups may be those having 3 to 20 carbon atoms, preferably those having 3 to 10 carbon atoms. Examples of alkylsilyl groups include trimethylsilyl, triethylsilyl, methyldiethylsilyl, ethyldimethylsilyl, tripropylsilyl, tributylsilyl, triisopropylsilyl, methyldiisopropylsilyl, dimethylisopropylsilyl, tri-t-butylsilyl, triisobutylsilyl, dimethyl t-butylsilyl, and methyldi-t-butylsilyl. Additionally, the alkylsilyl group may be optionally substituted.

Arylsilyl—as used herein, contemplates a silyl group substituted with at least one aryl group. Arylsilyl groups may be those having 6 to 30 carbon atoms, preferably those having 8 to 20 carbon atoms. Examples of arylsilyl groups include triphenylsilyl, phenyldibiphenylylsilyl, diphenylbiphenylsilyl, phenyldiethylsilyl, diphenylethylsilyl, phenyldimethylsilyl, diphenylmethylsilyl, phenyldiisopropylsilyl, diphenylisopropylsilyl, diphenylbutylsilyl, diphenylisobutylsilyl, diphenyl t-butylsilyl. Additionally, the arylsilyl group may be optionally substituted.

Alkylgermanyl—as used herein contemplates germanyl substituted with an alkyl group. The alkylgermanyl may be those having 3 to 20 carbon atoms, preferably those having 3 to 10 carbon atoms. Examples of alkylgermanyl include trimethylgermanyl, triethylgermanyl, methyldiethylgermanyl, ethyldimethylgermanyl, tripropylgermanyl, tributylgermanyl, triisopropylgermanyl, methyldiisopropylgermanyl, dimethylisopropylgermanyl, tri-t-butylgermanyl, triisobutylgermanyl, dimethyl-t-butylgermanyl, and methyldi-t-butylgermanyl. Additionally, the alkylgermanyl may be optionally substituted.

Arylgermanyl—as used herein contemplates a germanyl substituted with at least one aryl group or heteroaryl group. Arylgermanyl may be those having 6 to 30 carbon atoms, preferably those having 8 to 20 carbon atoms. Examples of arylgermanyl include triphenylgermanyl, phenyldibiphenylylgermanyl, diphenylbiphenylgermanyl, phenyldiethylgermanyl, diphenylethylgermanyl, phenyldimethylgermanyl, diphenylmethylgermanyl, phenyldiisopropylgermanyl, diphenylisopropylgermanyl, diphenylbutylgermanyl, diphenylisobutylgermanyl, and diphenyl-t-butylgermanyl. Additionally, the arylgermanyl may be optionally substituted.

The term “aza” in azadibenzofuran, azadibenzothiophene, etc. means that one or more of C—H groups in the respective aromatic fragment are replaced by a nitrogen atom. For example, azatriphenylene encompasses dibenzo[f,h]quinoxaline, dibenzo[f,h]quinoline and other analogs with two or more nitrogens in the ring system. One of ordinary skill in the art can readily envision other nitrogen analogs of the aza-derivatives described above, and all such analogs are intended to be encompassed by the terms as set forth herein.

In the present disclosure, unless otherwise defined, when any term of the group consisting of substituted alkyl, substituted cycloalkyl, substituted heteroalkyl, substituted heterocyclic group, substituted arylalkyl, substituted alkoxy, substituted aryloxy, substituted alkenyl, substituted alkynyl, substituted aryl, substituted heteroaryl, substituted alkylsilyl, substituted arylsilyl, substituted alkylgermanyl, substituted arylgermanyl, substituted amino, substituted acyl, substituted carbonyl, a substituted carboxylic acid group, a substituted ester group, substituted sulfinyl, substituted sulfonyl, and substituted phosphino is used, it means that any group of alkyl, cycloalkyl, heteroalkyl, heterocyclic group, arylalkyl, alkoxy, aryloxy, alkenyl, alkynyl, aryl, heteroaryl, alkylsilyl, arylsilyl, alkylgermanyl, arylgermanyl, amino, acyl, carbonyl, a carboxylic acid group, an ester group, sulfinyl, sulfonyl, and phosphino may be substituted with one or more groups selected from the group consisting of deuterium, halogen, unsubstituted alkyl having 1 to 20 carbon atoms, unsubstituted cycloalkyl having 3 to 20 ring carbon atoms, unsubstituted heteroalkyl having 1 to 20 carbon atoms, an unsubstituted heterocyclic group having 3 to 20 ring atoms, unsubstituted arylalkyl having 7 to 30 carbon atoms, unsubstituted alkoxy having 1 to 20 carbon atoms, unsubstituted aryloxy having 6 to 30 carbon atoms, unsubstituted alkenyl having 2 to 20 carbon atoms, unsubstituted alkynyl having 2 to 20 carbon atoms, unsubstituted aryl having 6 to 30 carbon atoms, unsubstituted heteroaryl having 3 to 30 carbon atoms, unsubstituted alkylsilyl having 3 to 20 carbon atoms, unsubstituted arylsilyl group having 6 to 20 carbon atoms, unsubstituted alkylgermanyl group having 3 to 20 carbon atoms, unsubstituted arylgermanyl group having 6 to 20 carbon atoms, unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group, and combinations thereof.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or an attached fragment are considered to be equivalent.

In the compounds mentioned in the present disclosure, hydrogen atoms may be partially or fully replaced by deuterium. Other atoms such as carbon and nitrogen may also be replaced by their other stable isotopes. The replacement by other stable isotopes in the compounds may be preferred due to its enhancements of device efficiency and stability.

In the compounds mentioned in the present disclosure, multiple substitutions refer to a range that includes di-substitutions, up to the maximum available substitutions. When substitution in the compounds mentioned in the present disclosure represents multiple substitutions (including di-, tri-, and tetra-substitutions, etc.), that means the substituent may exist at a plurality of available substitution positions on its linking structure, the substituents present at a plurality of available substitution positions may have the same structure or different structures.

In the compounds mentioned in the present disclosure, adjacent substituents in the compounds cannot be joined to form a ring unless otherwise explicitly defined, for example, adjacent substituents can be optionally joined to form a ring. In the compounds mentioned in the present disclosure, the expression that adjacent substituents can be optionally joined to form a ring includes a case where adjacent substituents may be joined to form a ring and a case where adjacent substituents are not joined to form a ring. When adjacent substituents can be optionally joined to form a ring, the ring formed may be monocyclic or polycyclic (including spirocyclic, endocyclic, fusedcyclic, and etc.), as well as alicyclic, heteroalicyclic, aromatic, or heteroaromatic. In such expression, adjacent substituents may refer to substituents bonded to the same atom, substituents bonded to carbon atoms which are directly bonded to each other, or substituents bonded to carbon atoms which are more distant from each other. Preferably, adjacent substituents refer to substituents bonded to the same carbon atom and substituents bonded to carbon atoms which are directly bonded to each other.

The expression that adjacent substituents can be optionally joined to form a ring is also intended to mean that two substituents bonded to the same carbon atom are joined to each other via a chemical bond to form a ring, which can be exemplified by the following formula:

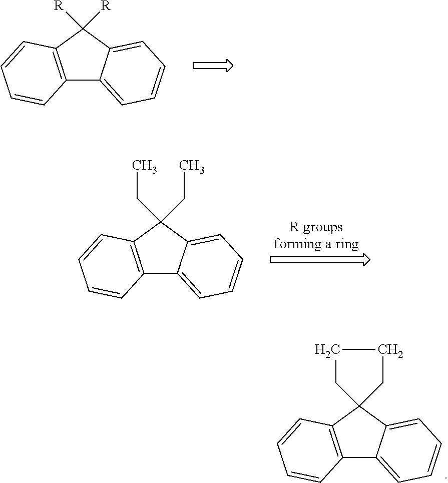

The expression that adjacent substituents can be optionally joined to form a ring is also intended to mean that two substituents bonded to carbon atoms which are directly bonded to each other are joined to each other via a chemical bond to form a ring, which can be exemplified by the following formula:

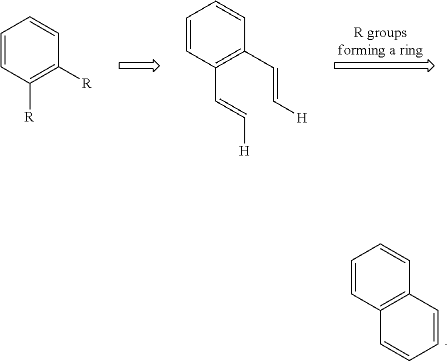

The expression that adjacent substituents can be optionally joined to form a ring is also intended to mean that two substituents bonded to further distant carbon atoms are joined to each other via a chemical bond to form a ring, which can be exemplified by the following formula:

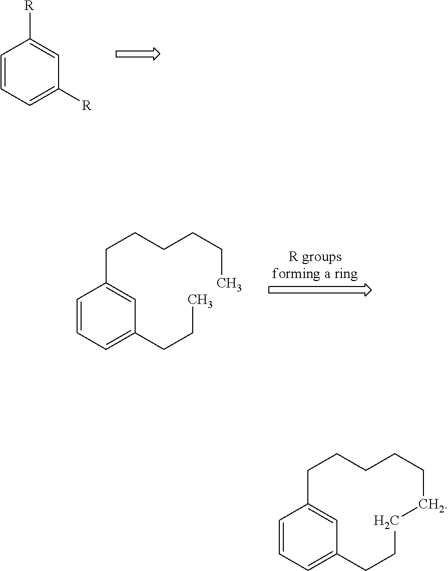

Furthermore, the expression that adjacent substituents can be optionally joined to form a ring is also intended to mean that, in the case where one of the two substituents bonded to carbon atoms which are directly bonded to each other represents hydrogen, the second substituent is bonded at a position at which the hydrogen atom is bonded, thereby forming a ring. This is exemplified by the following formula:

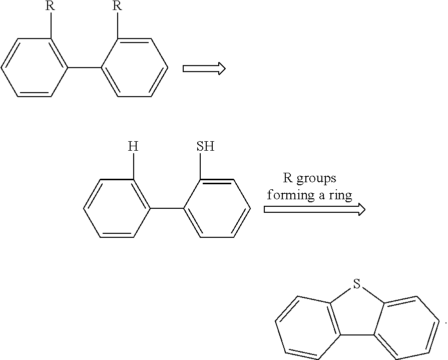

According to an embodiment of the present disclosure, disclosed is an active-matrix organic electroluminescent display comprising a plurality of pixels;
wherein each of the plurality of pixels comprises at least one stacked organic electroluminescent device;
the stacked organic electroluminescent device comprises an anode, a cathode and at least two light-emitting units disposed between the anode and the cathode;
wherein at least one common p-type charge generation layer is comprised between two adjacent light-emitting units, and the common p-type charge generation layer is shared by at least two pixels;
the common p-type charge generation layer comprises a first organic material and a second organic material;
a LUMO energy level of the first organic material is denoted as LUMO_{first_organic_material}, a HOMO energy level of the second organic material is denoted as HOMO_{second_organic_material}, and −0.1 eV≤LUMO_{first_organic_material}−HOMO_{second_organic_material}<0.20 eV;
a mass doping proportion of the first organic material in the common p-type charge generation layer is A %, and 6≤A≤20; and
a lateral conductivity of the common p-type charge generation layer is B_{A}, a lateral conductivity per unit doping of the common p-type charge generation layer is σ_{A}, wherein σ_{A}=B_{A}/A, and at least one σ_{A} satisfies 0.05×10⁻⁴ S/m≤σ_{A}≤1.0×10⁻⁴ S/m.

According to an embodiment of the present disclosure, the first organic material is a p-type conductive doping material and the second organic material is a hole transporting material.

According to an embodiment of the present disclosure, the first organic material is selected from the following compounds: quinones or quinone derivatives, radialene compounds, dehydrobenzoxazole and dehydrobenzothiazole compounds, and bisoxazole or bisthiazole compounds.

According to an embodiment of the present disclosure, the first organic material has a structure represented by Formula 1:

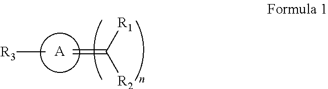

wherein,
n is selected from an integer from 1 to 6;
the ring A is selected from a conjugated ring having 3 to 30 ring atoms;
R₃ represents mono-substitution, multiple substitutions or non-substitution;
R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁, R₂ and R₃ can be optionally joined to form a ring.

Herein, the expression that “the ring A is selected from a conjugated ring having 3 to 30 ring atoms” is intended to mean that the ring A is a ring structure having 3 to 30 ring atoms and the ring A has a structural feature of being conjugated. For example, the ring A includes, but is not limited to, the structures shown by Formula A-1 to Formula A-13 in the present application. The ring A may be a monocyclic structure or a polycyclic structure, wherein the polycyclic ring may be a parallel-ring structure or a fused-ring structure or may be an integrally conjugated structure formed by connecting two conjugated rings by a double bond, such as the structure shown by Formula A-12 in the present application. The ring A may be a carbocyclic ring or a heterocyclic ring.

Herein, the expression that “adjacent substituents R₁, R₂ and R₃ can be optionally joined to form a ring” is intended to mean that any one or more of groups of adjacent substituents, such as substituents R₃, substituents R₁ and R₂, substituents R₁ and R₃, and substituents R₂ and R₃, can be joined to form a ring. Obviously, it is also possible that none of these substituents are joined to form a ring.

According to an embodiment of the present disclosure, n is an even number.

According to an embodiment of the present disclosure, n is selected from 2, 4 or 6.

According to an embodiment of the present disclosure, n is selected from 1, 2 or 3.

According to an embodiment of the present disclosure, n is selected from 1 or 2.

According to an embodiment of the present disclosure, the ring A is selected from a conjugated ring having 3 to 20 ring atoms.

According to an embodiment of the present disclosure, the ring A is selected from a conjugated ring having 4 to 20 ring atoms.

According to an embodiment of the present disclosure, at least one of the substituents R₁, R₂ and R₃ is a substituent comprising at least one electron withdrawing group.

According to an embodiment of the present disclosure, R₁ and/or R₂ are a substituent comprising at least one electron withdrawing group.

According to an embodiment of the present disclosure, the Hammett constant of the electron withdrawing group is greater than or equal to 0.05.

According to an embodiment of the present disclosure, the Hammett constant of the electron withdrawing group is greater than or equal to 0.3.

According to an embodiment of the present disclosure, the Hammett constant of the electron withdrawing group is greater than or equal to 0.5.

In the present disclosure, the Hammett substituent constant value of the electron withdrawing group is ≥0.05, for example, ≥0.1 or ≥0.2; preferably ≥0.3; more preferably ≥ 0.5. The electron withdrawing ability is relatively strong, which can significantly reduce the LUMO energy level of the compound and achieve the improvement of a charge mobility.

It should be noted that the Hammett substituent constant value includes Hammett substituent para-constant and/or meta-constant. As long as the conditions that the para-constant and the meta-constant are both greater than 0 and one of the para-constant and the meta-constant is greater than or equal to 0.05 are satisfied, the substituent can be used as the group selected in the present disclosure.

According to an embodiment of the present disclosure, the electron withdrawing group is selected from the group consisting of: halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, an aza-aromatic ring group and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group and an aza-aromatic ring group: alkyl having 1 to 20 carbon atoms, cycloalkyl having 3 to 20 ring carbon atoms, heteroalkyl having 1 to 20 carbon atoms, a heterocyclic group having 3 to 20 ring atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms and combinations thereof.

According to an embodiment of the present disclosure, the electron withdrawing group is selected from the group consisting of: halogen, a nitroso group, a nitro group, an acyl group, a carbonyl group, a carboxylic acid group, an ester group, SF₅, a boranyl group, a sulfinyl group, a sulfonyl group, a phosphoroso group, an aza-aromatic ring group and any one of the following groups substituted with one or more of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms and combinations thereof.

According to an embodiment of the present disclosure, the electron withdrawing group is selected from the group consisting of: fluorine, an acyl group, a carbonyl group, an ester group, SF₅, a boranyl group, an aza-aromatic ring group and any one of the following groups substituted with one or more of fluorine, a cyano group, an isocyano group, SCN, OCN, SF₅, CF₃, OCF₃, SCF₃ and an aza-aromatic ring group: alkyl having 1 to 20 carbon atoms, cycloalkyl having 3 to 20 ring carbon atoms, heteroalkyl having 1 to 20 carbon atoms, arylalkyl having 7 to 30 carbon atoms, alkoxy having 1 to 20 carbon atoms, aryloxy having 6 to 30 carbon atoms, alkenyl having 2 to 20 carbon atoms, alkynyl having 2 to 20 carbon atoms, aryl having 6 to 30 carbon atoms, heteroaryl having 3 to 30 carbon atoms, alkylsilyl having 3 to 20 carbon atoms, arylsilyl having 6 to 20 carbon atoms and combinations thereof.

According to an embodiment of the present disclosure, the ring A is selected from the group consisting of Formula A-1 to Formula A-13:

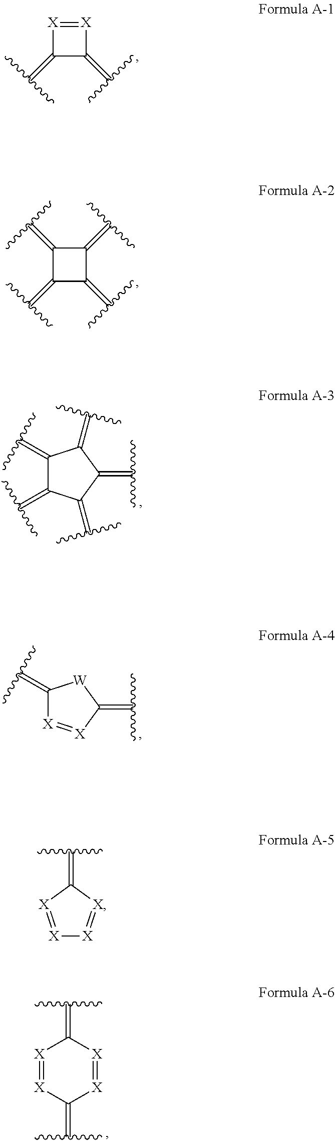

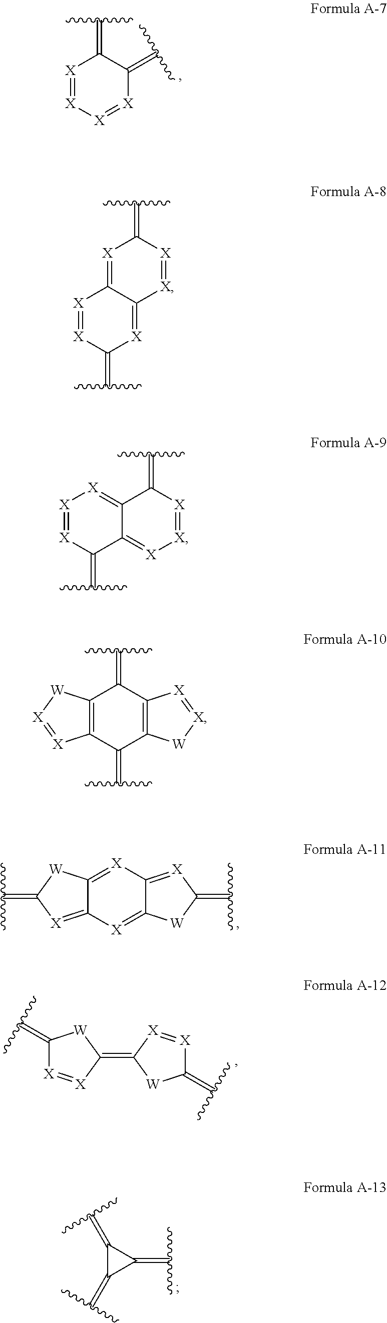

wherein,
X is, at each occurrence identically or differently, selected from N or CR₃;
W is, at each occurrence identically or differently, selected from O, S, Se or NR₃;
R₃ is, at each occurrence identically or differently, selected from hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group or a combination thereof;
adjacent substituents R₃ can be optionally joined to form a ring; and
[symbol] represents a position where Formula A-1 to Formula A-13 are joined to the double bond in Formula 1.

According to an embodiment of the present disclosure, the ring A is selected from Formula A-6, Formula A-8, Formula A-10, Formula A-11 or Formula A-12.

According to an embodiment of the present disclosure, the first organic material has a structure represented by any one of Formula 1-1 to Formula 1-4:

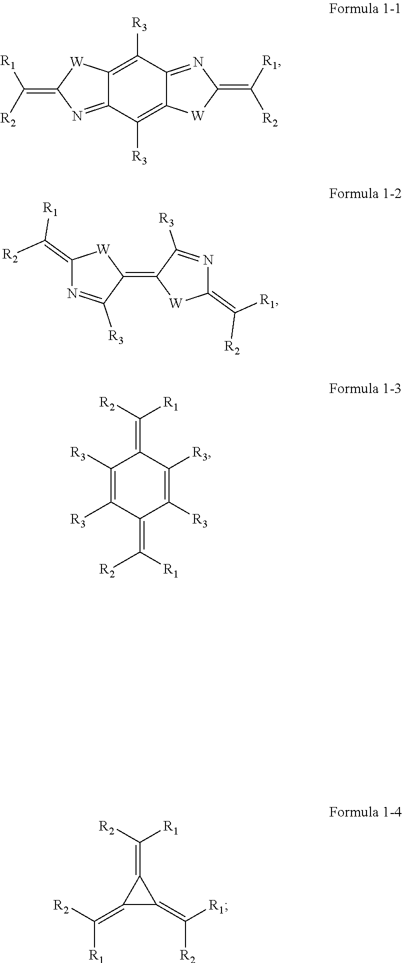

wherein W is, at each occurrence identically or differently, selected from the group consisting of O, S, Se and NR₃;
R₁, R₂ and R₃ are, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, substituted or unsubstituted amino having 0 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R₁, R₂ and R₃ can be optionally joined to form a ring.

According to an embodiment of the present disclosure, W is, at each occurrence identically or differently, selected from O, S or Se.

According to an embodiment of the present disclosure, W is, at each occurrence identically or differently, selected from O or S.

According to an embodiment of the present disclosure, W is selected from O.

According to an embodiment of the present disclosure, R₁, R₂ and R₃ are, at each occurrence identically or differently, selected from the group consisting of: hydrogen, deuterium, halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, a phosphoroso group, unsubstituted alkyl having 1 to 20 carbon atoms, unsubstituted cycloalkyl having 3 to 20 ring carbon atoms, unsubstituted alkoxy having 1 to 20 carbon atoms, unsubstituted alkenyl having 2 to 20 carbon atoms, unsubstituted aryl having 6 to 30 carbon atoms, unsubstituted heteroaryl having 3 to 30 carbon atoms and any one of following groups substituted with one or more groups of halogen, a nitroso group, a nitro group, an acyl group, a carbonyl group, a carboxylic acid group, an ester group, a cyano group, an isocyano group, SCN, OCN, SF₅, a boranyl group, a sulfinyl group, a sulfonyl group, and a phosphoroso group: alkyl having 1 to 20 carbon atoms, cycloalkyl having 3 to 20 ring carbon atoms, alkoxy having 1 to 20 carbon atoms, alkenyl having 2 to 20 carbon atoms, aryl having 6 to 30 carbon atoms, heteroaryl having 3 to 30 carbon atoms and combinations thereof.

According to an embodiment of the present disclosure, R₁, R₂ and R₃ are, at each occurrence identically or differently, selected from the group consisting of: hydrogen, deuterium, methyl, isopropyl, NO₂, SO₂CH₃, SCF₃, C₂F₅, OC₂F₅, OCH₃, diphenylmethylsilyl, phenyl, methoxyphenyl, para-methylphenyl, 2,6-diisopropylphenyl, biphenyl, polyfluorophenyl, difluoropyridyl, nitrophenyl, dimethylthiazolyl, vinyl substituted with one or more of CN or CF₃, acetenyl substituted with one of CN or CF₃, dimethylphosphoroso, diphenylphosphoroso, F, CF₃, OCF₃, SF₅, SO₂CF₃, a cyano group, an isocyano group, SCN, OCN, trifluoromethylphenyl, trifluoromethoxyphenyl, bis(trifluoromethyl)phenyl, bis(trifluoromethoxy)phenyl, 4-cyanotetrafluorophenyl, phenyl or biphenyl substituted with one or more of F, CN or CF₃, tetrafluoropyridyl, pyrimidinyl, triazinyl, diphenylboranyl, oxaboraanthryl and combinations thereof.

According to an embodiment of the present disclosure, R₁ and R₂ are, at each occurrence identically or differently, selected from the group consisting of: halogen, a cyano group, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted aryl having 6 to 30 carbon atoms, substituted or unsubstituted heteroaryl having 3 to 30 carbon atoms and combinations thereof.

According to an embodiment of the present disclosure, R₁ and R₂ are, at each occurrence identically or differently, selected from the group consisting of: a cyano group, substituted or unsubstituted aryl having 6 to 30 carbon atoms, substituted or unsubstituted heteroaryl having 3 to 30 carbon atoms and combinations thereof.

According to an embodiment of the present disclosure, R₁ is selected from a cyano group.

According to an embodiment of the present disclosure, R₁ and R₂ are both selected from a cyano group.

According to an embodiment of the present disclosure, R₃ is selected from substituted or unsubstituted aryl having 6 to 30 carbon atoms, substituted or unsubstituted heteroaryl having 3 to 30 carbon atoms or a combination thereof.

According to an embodiment of the present disclosure, the first organic material has a structure represented by Formula 1-1 or Formula 1-2.

According to an embodiment of the present disclosure, the first organic material has a structure represented by Formula 1-1.

According to an embodiment of the present disclosure, the first organic material is selected from the group consisting of Compound 1-1 to Compound 1-47, Compound 2-1 to Compound 2-22, Compound 3-1 to Compound 3-8 and Compound 4-1 to Compound 4-11:

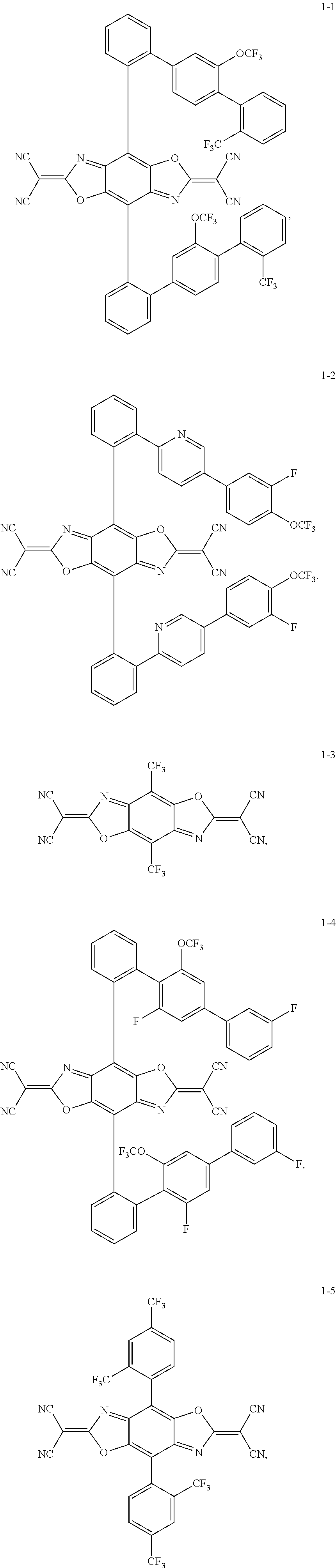

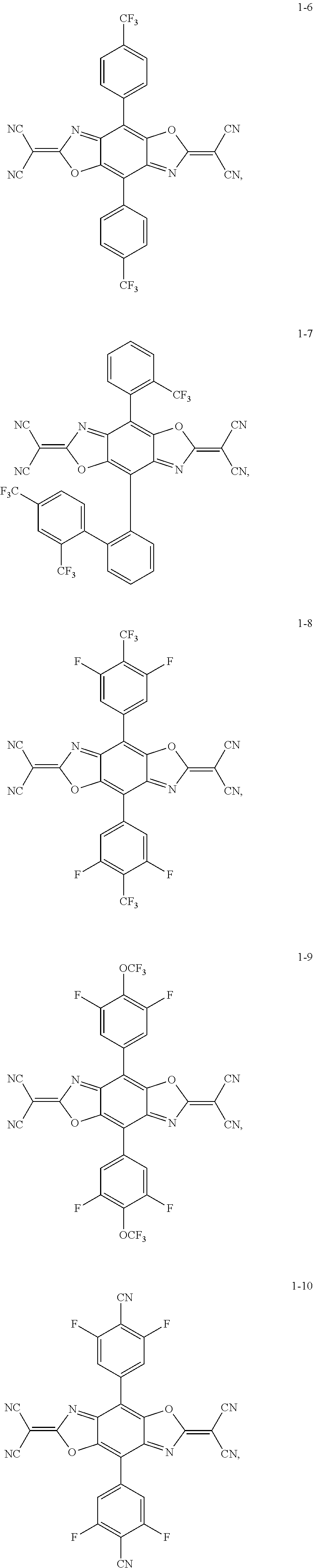 [SMILES: N#CC(C#N)=c1nc2c(-c3ccc(C(F)(F)F)cc3)c3oc(=C(C#N)C#N)nc3c(-c3ccc(C(F)(F)F)cc3)c2o1 ; N#CC(C#N)=c1nc2c(-c3ccccc3C(F)(F)F)c3oc(=C(C#N)C#N)nc3c(-c3ccccc3-c3ccc(C(F)(F)F)cc3C(F)(F)F)c2o1 ; N#CC(C#N)=c1nc2c(-c3cc(F)c(C(F)(F)F)c(F)c3)c3oc(=C(C#N)C#N)nc3c(-c3cc(F)c(C(F)(F)F)c(F)c3)c2o1 ; N#CC(C#N)=c1nc2c(-c3cc(F)c(OC(F)(F)F)c(F)c3)c3oc(=C(C#N)C#N)nc3c(-c3cc(F)c(OC(F)(F)F)c(F)c3)c2o1 ; N#CC(C#N)=c1nc2c(-c3cc(F)c(C#N)c(F)c3)c3oc(=C(C#N)C#N)nc3c(-c3cc(F)c(C#N)c(F)c3)c2o1]

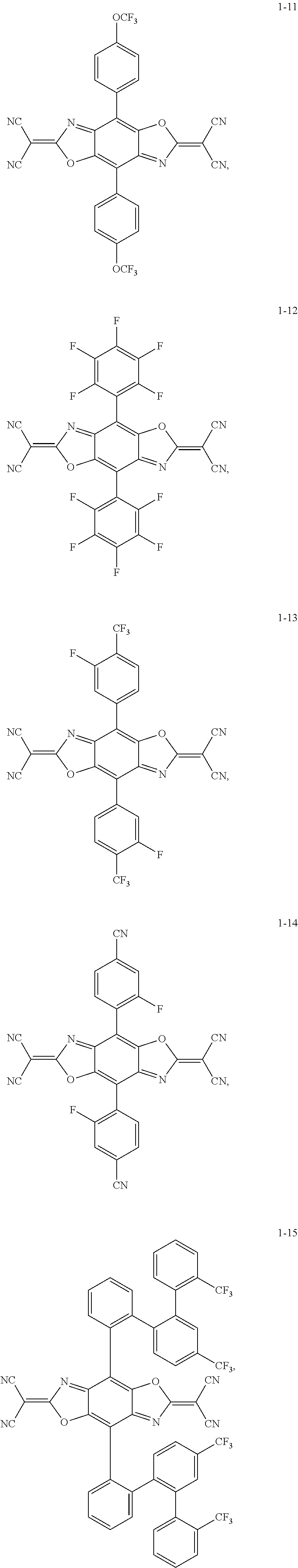 [SMILES: N#CC(C#N)=c1nc2c(-c3ccc(OC(F)(F)F)cc3)c3oc(=C(C#N)C#N)nc3c(-c3ccc(OC(F)(F)F)cc3)c2o1 ; N#CC(C#N)=c1nc2c(-c3c(F)c(F)c(F)c(F)c3F)c3oc(=C(C#N)C#N)nc3c(-c3c(F)c(F)c(F)c(F)c3F)c2o1 ; N#CC(C#N)=c1nc2c(-c3ccc(C(F)(F)F)c(F)c3)c3oc(=C(C#N)C#N)nc3c(-c3ccc(C(F)(F)F)c(F)c3)c2o1 ; N#CC(C#N)=c1nc2c(-c3ccc(C#N)cc3F)c3oc(=C(C#N)C#N)nc3c(-c3ccc(C#N)cc3F)c2o1 ; N#CC(C#N)=c1nc2c(-c3ccccc3-c3ccc(C(F)(F)F)cc3-c3ccccc3C(F)(F)F)c3oc(=C(C#N)C#N)nc3c(-c3ccccc3-c3ccc(C(F)(F)F)cc3-c3ccccc3C(F)(F)F)c2o1]

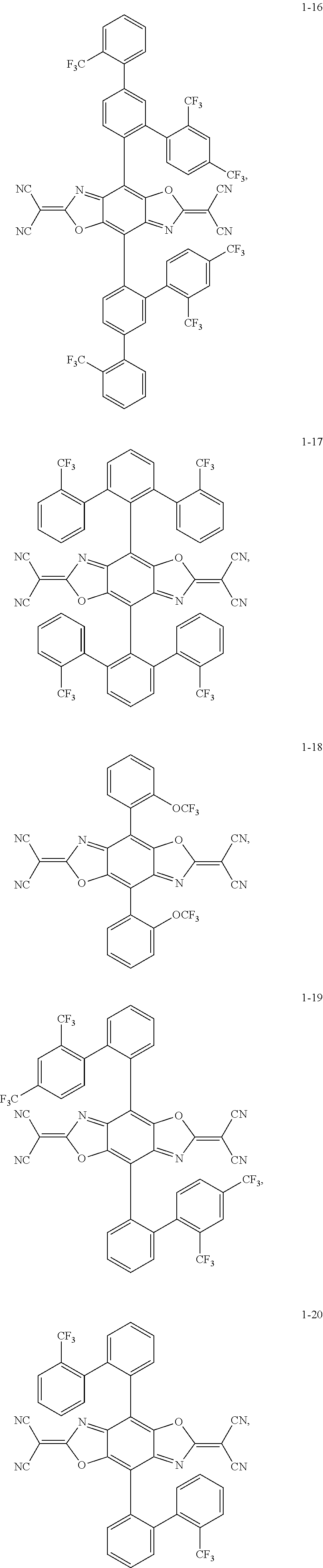

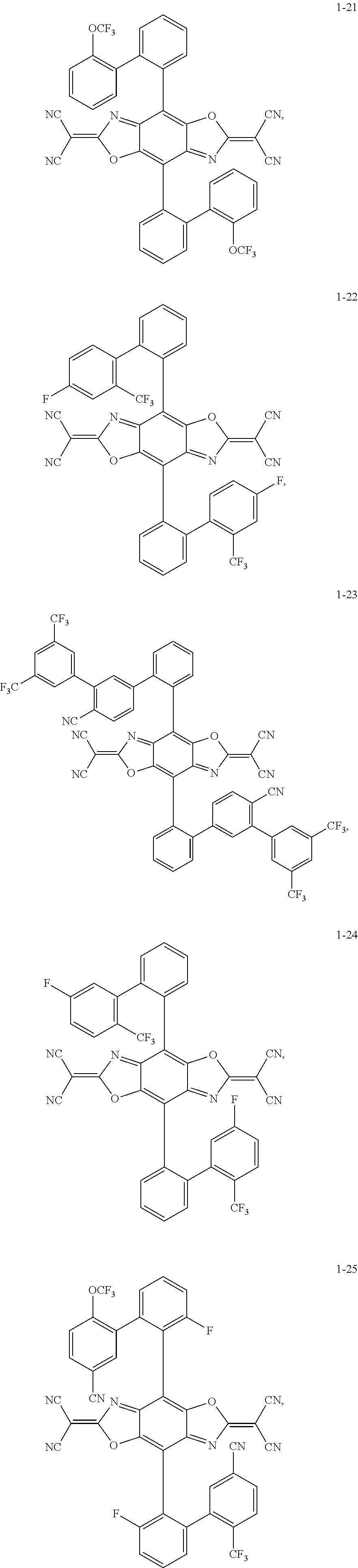

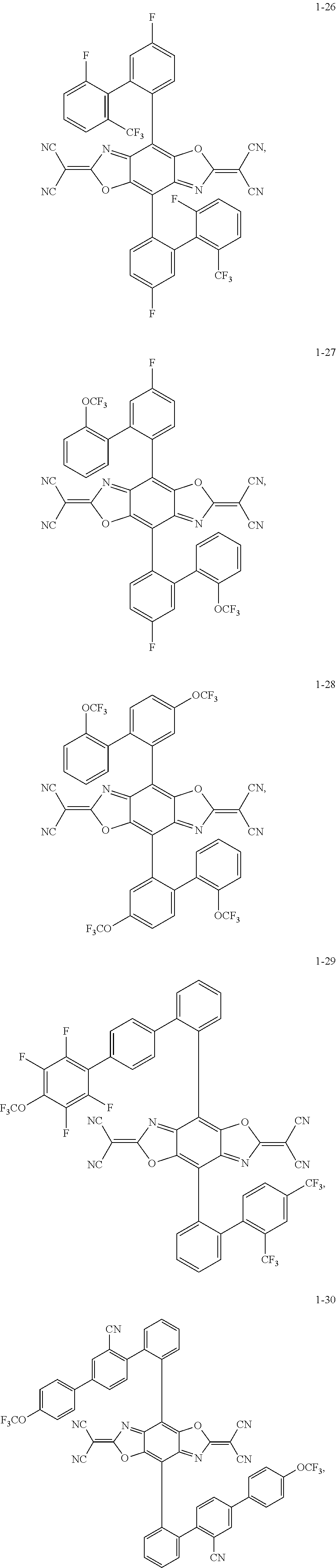

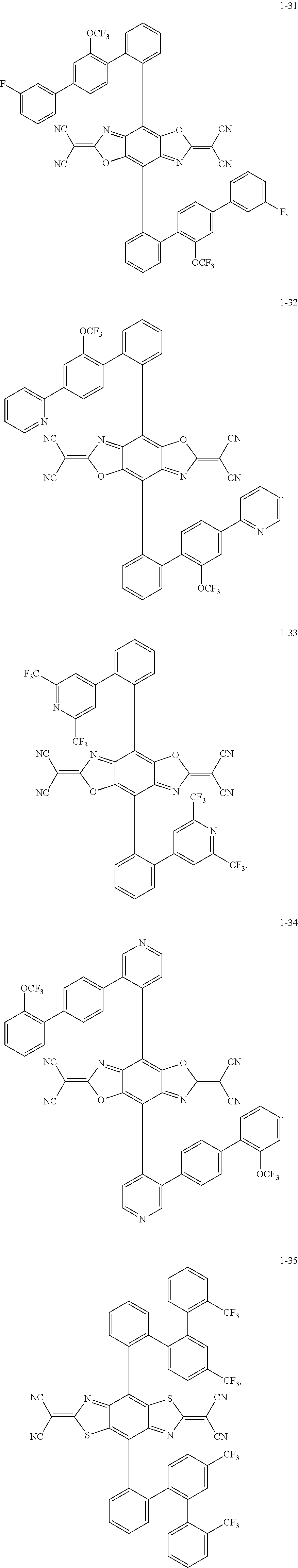

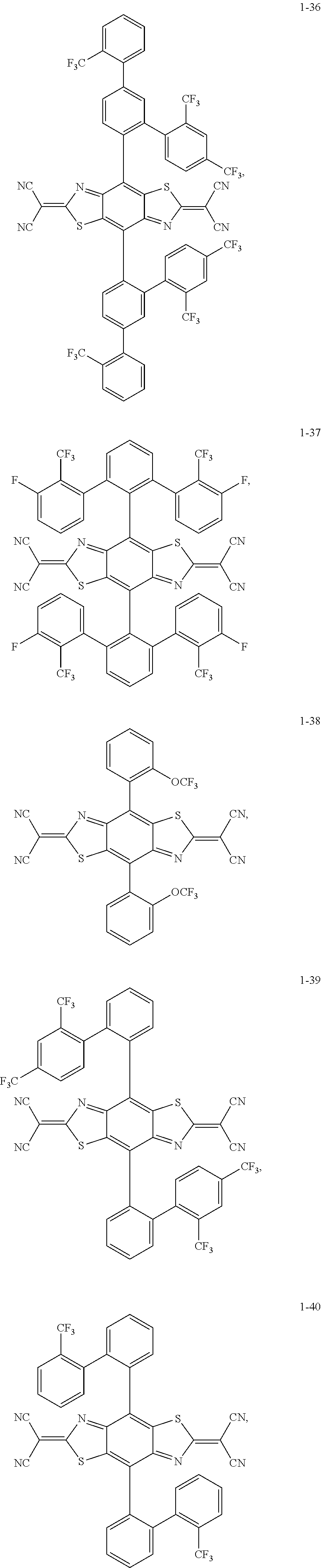

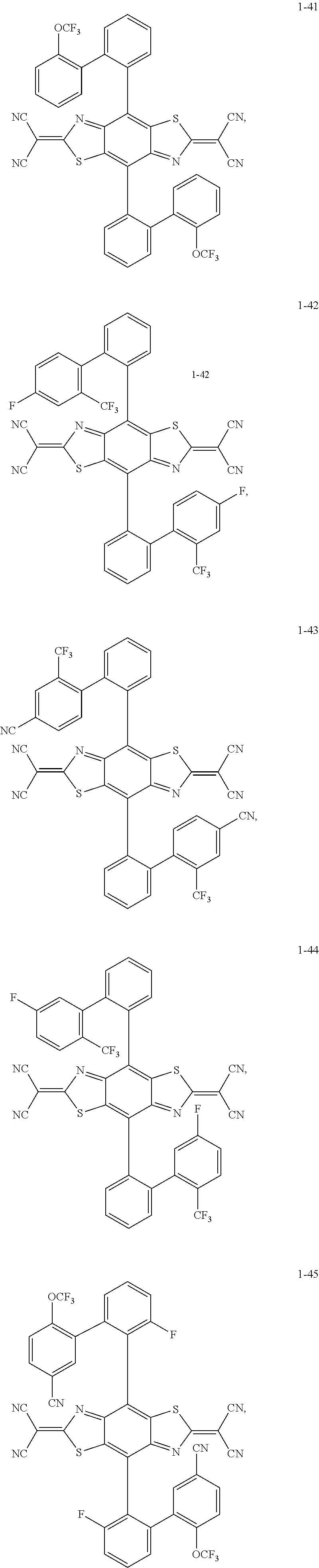

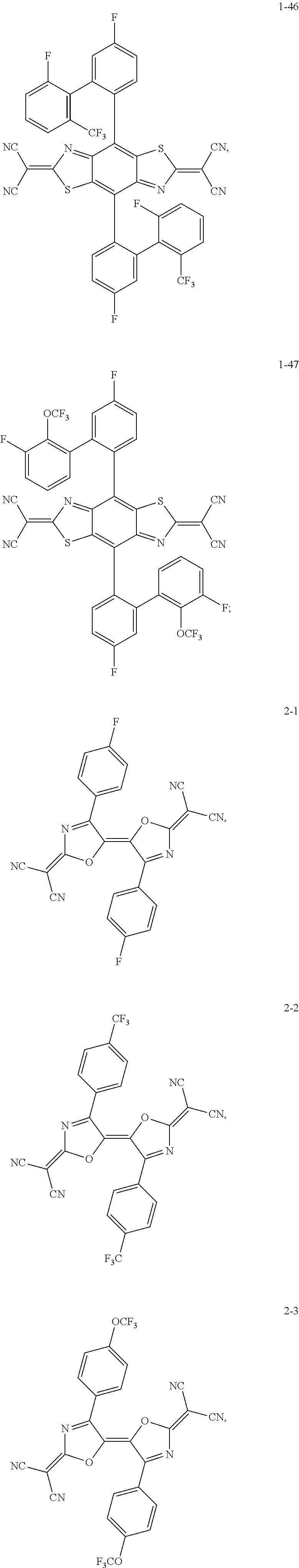 [SMILES: N#CC(C#N)=c1nc2c(-c3ccc(F)cc3-c3c(F)cccc3C(F)(F)F)c3sc(=C(C#N)C#N)nc3c(-c3ccc(F)cc3-c3c(F)cccc3C(F)(F)F)c2s1 ; N#CC(C#N)=c1nc2c(-c3ccc(F)cc3-c3cccc(F)c3OC(F)(F)F)c3sc(=C(C#N)C#N)nc3c(-c3ccc(F)cc3-c3cccc(F)c3OC(F)(F)F)c2s1 ; N#CC(C#N)=c1nc(-c2ccc(F)cc2)/c(=c2\oc(=C(C#N)C#N)nc2-c2ccc(F)cc2)o1 ; N#CC(C#N)=c1nc(-c2ccc(C(F)(F)F)cc2)/c(=c2\oc(=C(C#N)C#N)nc2-c2ccc(C(F)(F)F)cc2)o1 ; N#CC(C#N)=c1nc(-c2ccc(OC(F)(F)F)cc2)/c(=c2\oc(=C(C#N)C#N)nc2-c2ccc(OC(F)(F)F)cc2)o1]

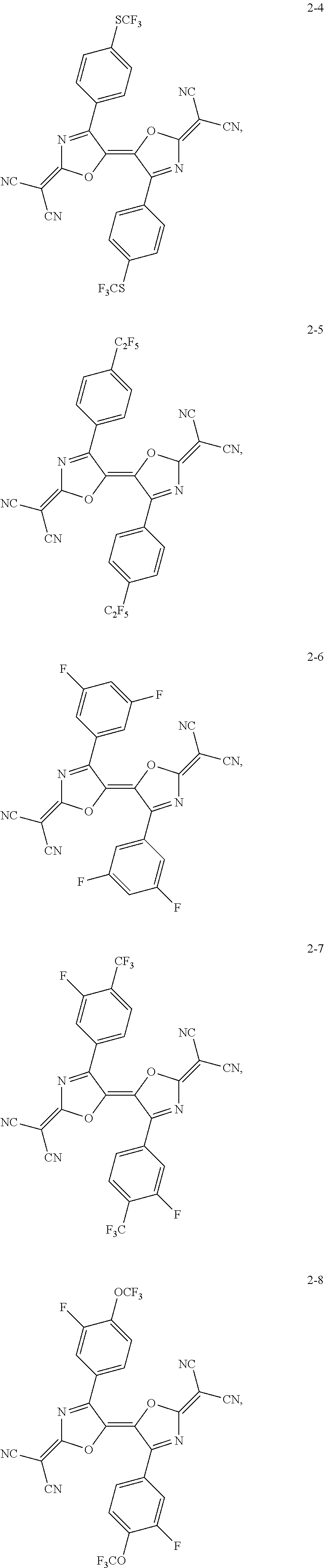

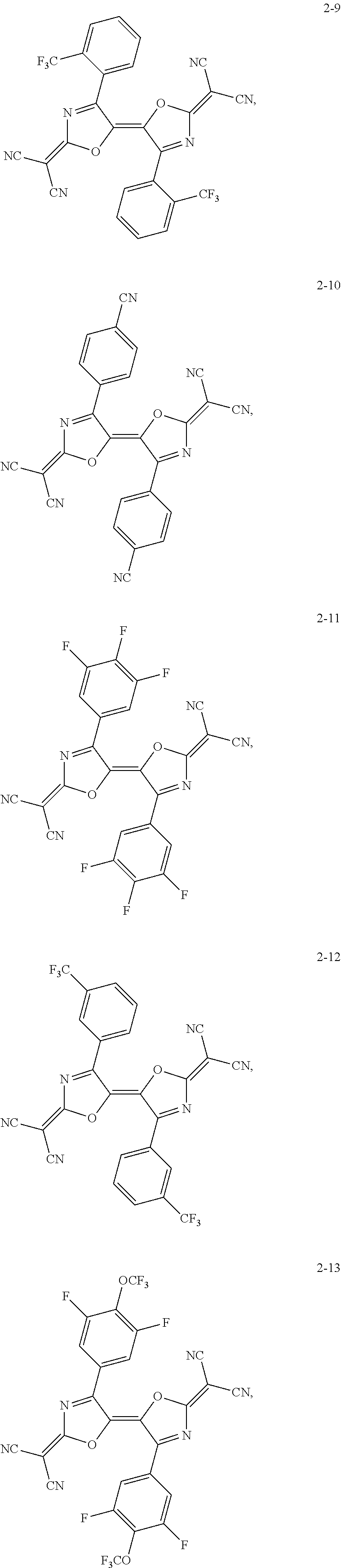 [SMILES: N#CC(C#N)=c1nc(-c2ccccc2C(F)(F)F)/c(=c2\oc(=C(C#N)C#N)nc2-c2ccccc2C(F)(F)F)o1 ; N#CC(C#N)=c1nc(-c2ccc(C#N)cc2)/c(=c2\oc(=C(C#N)C#N)nc2-c2ccc(C#N)cc2)o1 ; N#CC(C#N)=c1nc(-c2cc(F)c(F)c(F)c2)/c(=c2\oc(=C(C#N)C#N)nc2-c2cc(F)c(F)c(F)c2)o1 ; N#CC(C#N)=c1nc(-c2cccc(C(F)(F)F)c2)/c(=c2\oc(=C(C#N)C#N)nc2-c2cccc(C(F)(F)F)c2)o1 ; N#CC(C#N)=c1nc(-c2cc(F)c(OC(F)(F)F)c(F)c2)/c(=c2\oc(=C(C#N)C#N)nc2-c2cc(F)c(OC(F)(F)F)c(F)c2)o1]

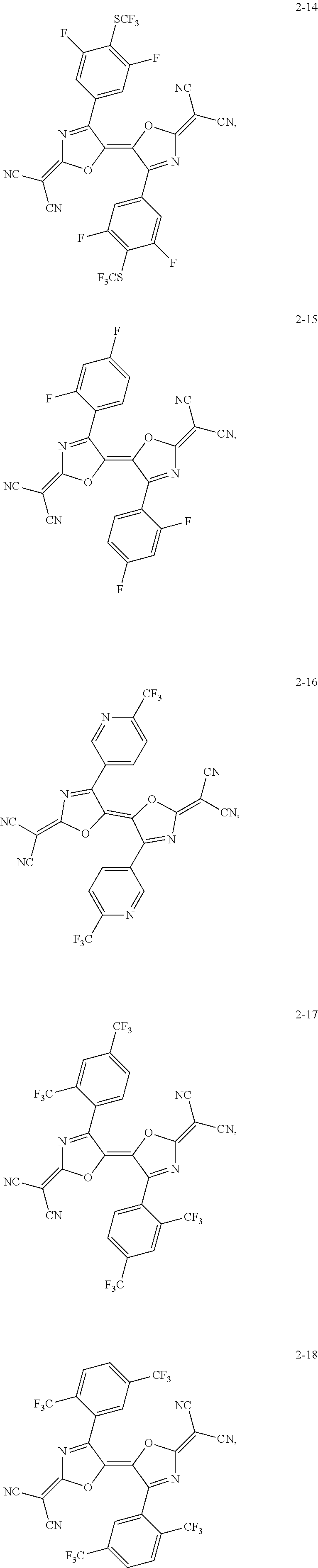

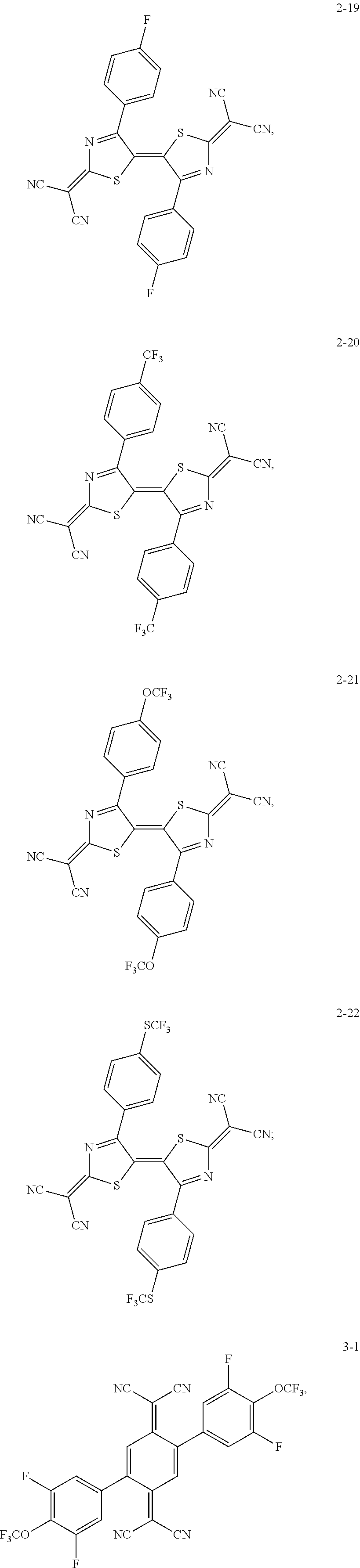

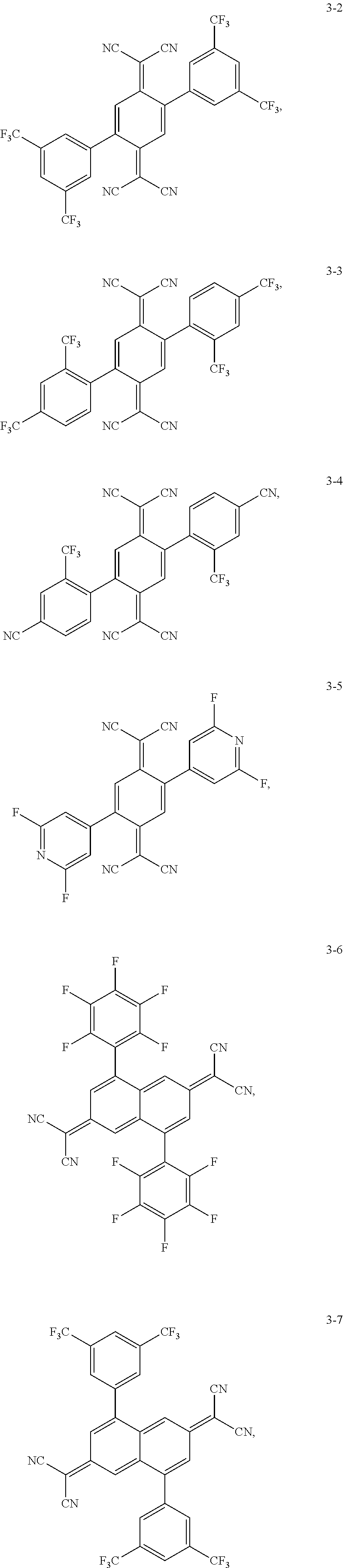

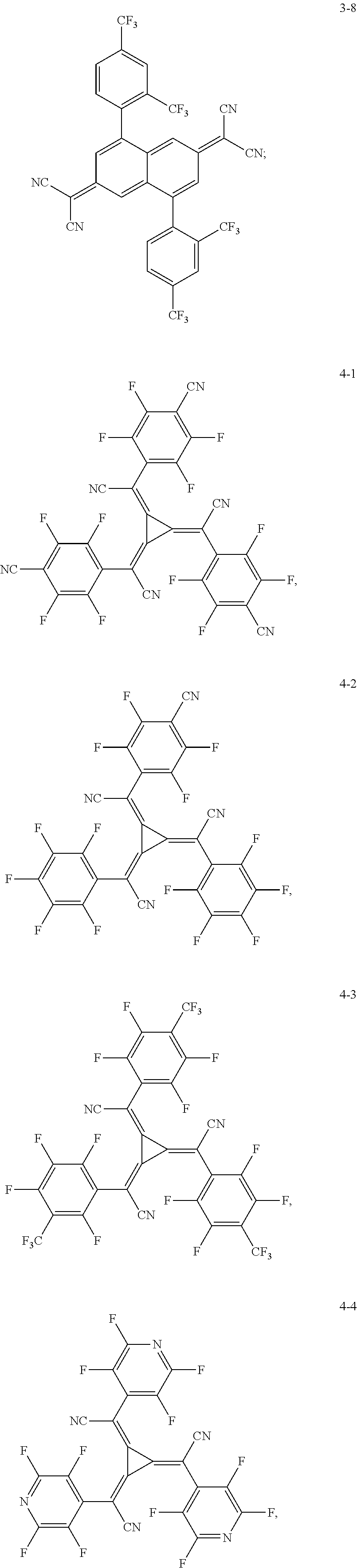 [SMILES: N#CC(C#N)=c1cc(-c2ccc(C(F)(F)F)cc2C(F)(F)F)c2cc(=C(C#N)C#N)cc(-c3ccc(C(F)(F)F)cc3C(F)(F)F)c2c1 ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#C/C(=C1/C(=C(\C#N)c2c(F)c(F)c(C#N)c(F)c2F)/C1=C(\C#N)c1c(F)c(F)c(F)c(F)c1F)c1c(F)c(F)c(F)c(F)c1F ; N#C/C(=C1/C(=C(\C#N)c2c(F)c(F)c(F)c(C(F)(F)F)c2F)/C1=C(\C#N)c1c(F)c(F)c(C(F)(F)F)c(F)c1F)c1c(F)c(F)c(C(F)(F)F)c(F)c1F ; N#CC(=C1C(=C(C#N)c2c(F)c(F)nc(F)c2F)C1=C(C#N)c1c(F)c(F)nc(F)c1F)c1c(F)c(F)nc(F)c1F]

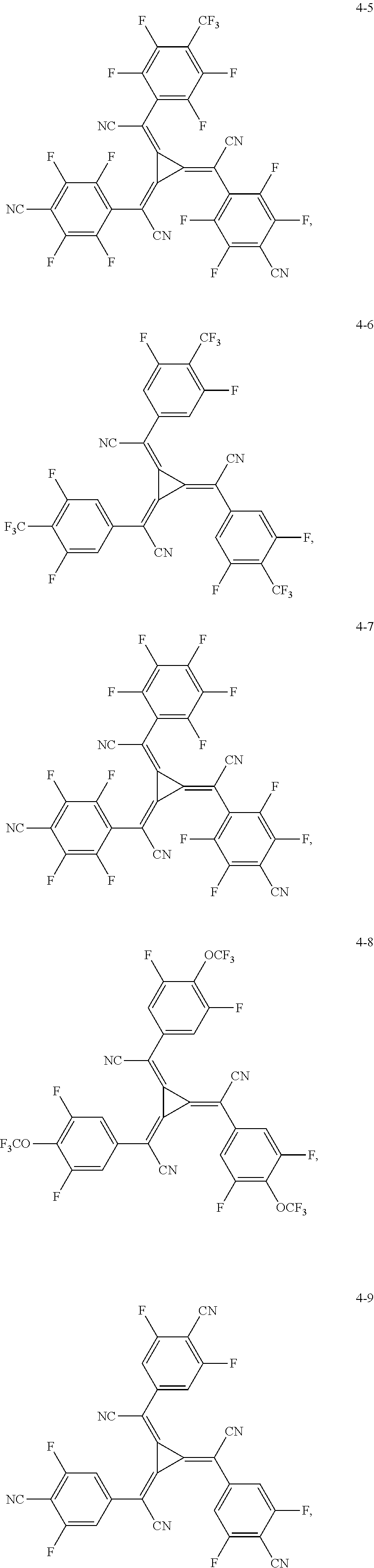

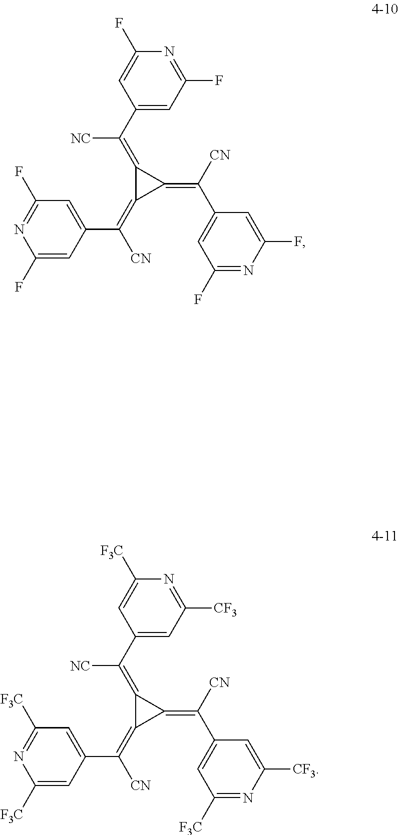 [SMILES: N#CC(=C1C(=C(C#N)c2cc(F)nc(F)c2)C1=C(C#N)c1cc(F)nc(F)c1)c1cc(F)nc(F)c1 ; N#CC(=C1C(=C(C#N)c2cc(C(F)(F)F)nc(C(F)(F)F)c2)C1=C(C#N)c1cc(C(F)(F)F)nc(C(F)(F)F)c1)c1cc(C(F)(F)F)nc(C(F)(F)F)c1]

According to an embodiment of the present disclosure, hydrogen in the structures of Compound 1-1 to Compound 1-47, Compound 2-1 to Compound 2-22, Compound 3-1 to Compound 3-8 and Compound 4-1 to Compound 4-11 can be partially or fully substituted with deuterium.

According to an embodiment of the present disclosure, the first organic material is selected from the group consisting of Compound 1-1 to Compound 1-47, Compound 2-1 to Compound 2-22, Compound 3-1 to Compound 3-8, Compound 4-1 to Compound 4-11, Compound 2-23, Compound 6-1 to Compound 6-47; Compound 2-23, Compound 6-1 to Compound 6-47 are as follows:

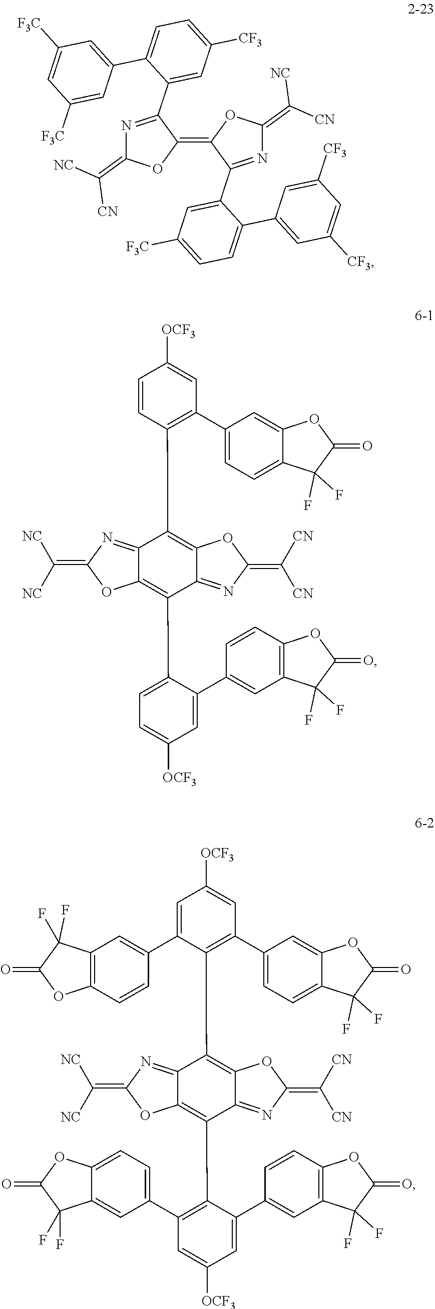 [SMILES: N#CC(C#N)=c1nc(-c2cc(C(F)(F)F)ccc2-c2cc(C(F)(F)F)cc(C(F)(F)F)c2)/c(=c2\oc(=C(C#N)C#N)nc2-c2cc(C(F)(F)F)ccc2-c2cc(C(F)(F)F)cc(C(F)(F)F)c2)o1 ; N#CC(C#N)=c1nc2c(-c3ccc(OC(F)(F)F)cc3-c3ccc4c(c3)C(F)(F)C(=O)O4)c3oc(=C(C#N)C#N)nc3c(-c3ccc(OC(F)(F)F)cc3-c3ccc4c(c3)OC(=O)C4(F)F)c2o1 ; N#CC(C#N)=c1nc2c(-c3c(-c4ccc5c(c4)C(F)(F)C(=O)O5)cc(OC(F)(F)F)cc3-c3ccc4c(c3)C(F)(F)C(=O)O4)c3oc(=C(C#N)C#N)nc3c(-c3c(-c4ccc5c(c4)OC(=O)C5(F)F)cc(OC(F)(F)F)cc3-c3ccc4c(c3)C(F)(F)C(=O)O4)c2o1]

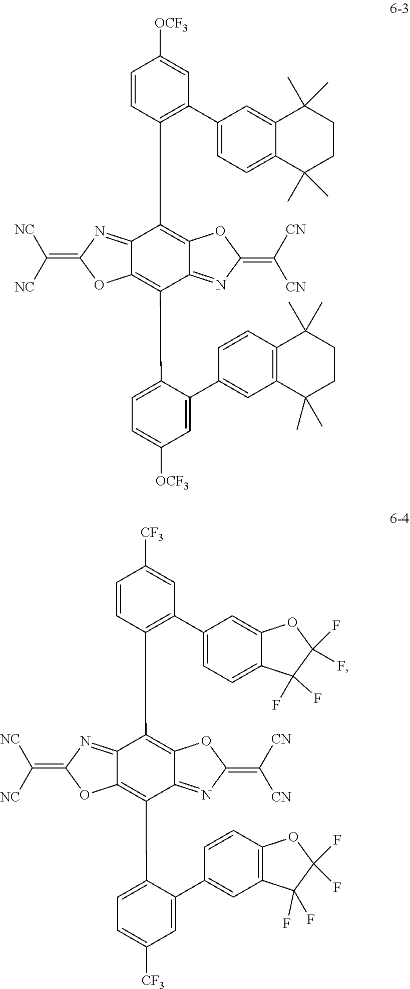 [SMILES: CC1(C)CCC(C)(C)c2cc(-c3cc(OC(F)(F)F)ccc3-c3c4nc(=C(C#N)C#N)oc4c(-c4ccc(OC(F)(F)F)cc4-c4ccc5c(c4)C(C)(C)CCC5(C)C)c4nc(=C(C#N)C#N)oc34)ccc21 ; N#CC(C#N)=c1nc2c(-c3ccc(C(F)(F)F)cc3-c3ccc4c(c3)C(F)(F)C(F)(F)O4)c3oc(=C(C#N)C#N)nc3c(-c3ccc(C(F)(F)F)cc3-c3ccc4c(c3)OC(F)(F)C4(F)F)c2o1]

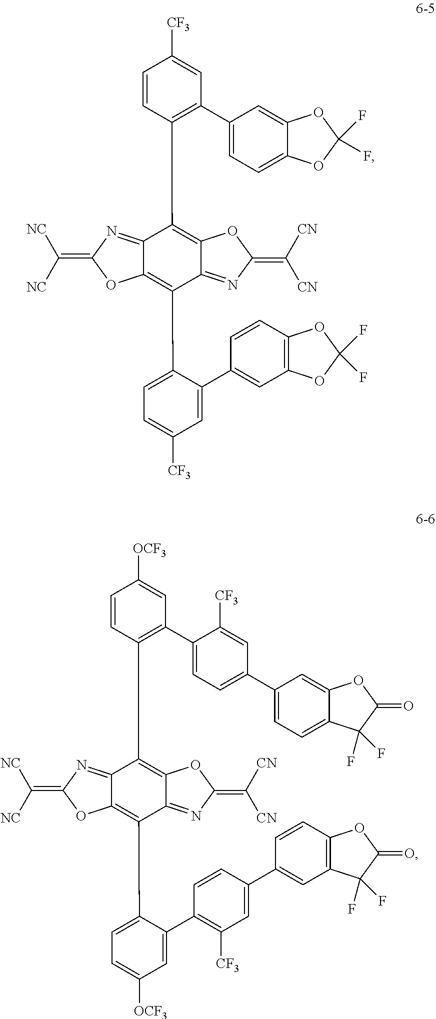 [SMILES: N#CC(C#N)=c1nc2c(-c3ccc(C(F)(F)F)cc3-c3ccc4c(c3)OC(F)(F)O4)c3oc(=C(C#N)C#N)nc3c(-c3ccc(C(F)(F)F)cc3-c3ccc4c(c3)OC(F)(F)O4)c2o1 ; N#CC(C#N)=c1nc2c(-c3ccc(OC(F)(F)F)cc3-c3ccc(-c4ccc5c(c4)C(F)(F)C(=O)O5)cc3C(F)(F)F)c3oc(=C(C#N)C#N)nc3c(-c3ccc(OC(F)(F)F)cc3-c3ccc(-c4ccc5c(c4)OC(=O)C5(F)F)cc3C(F)(F)F)c2o1]

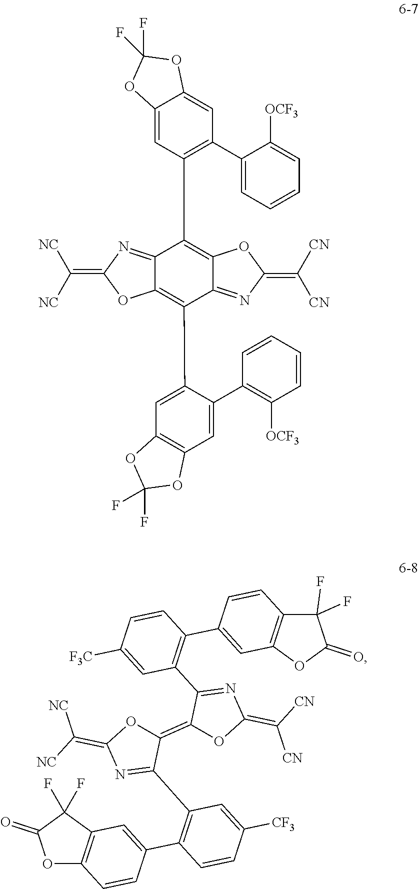 [SMILES: N#CC(C#N)=c1nc2c(-c3cc4c(cc3-c3ccccc3OC(F)(F)F)OC(F)(F)O4)c3oc(=C(C#N)C#N)nc3c(-c3cc4c(cc3-c3ccccc3OC(F)(F)F)OC(F)(F)O4)c2o1 ; N#CC(C#N)=c1nc(-c2cc(C(F)(F)F)ccc2-c2ccc3c(c2)OC(=O)C3(F)F)/c(=c2\oc(=C(C#N)C#N)nc2-c2cc(C(F)(F)F)ccc2-c2ccc3c(c2)C(F)(F)C(=O)O3)o1]

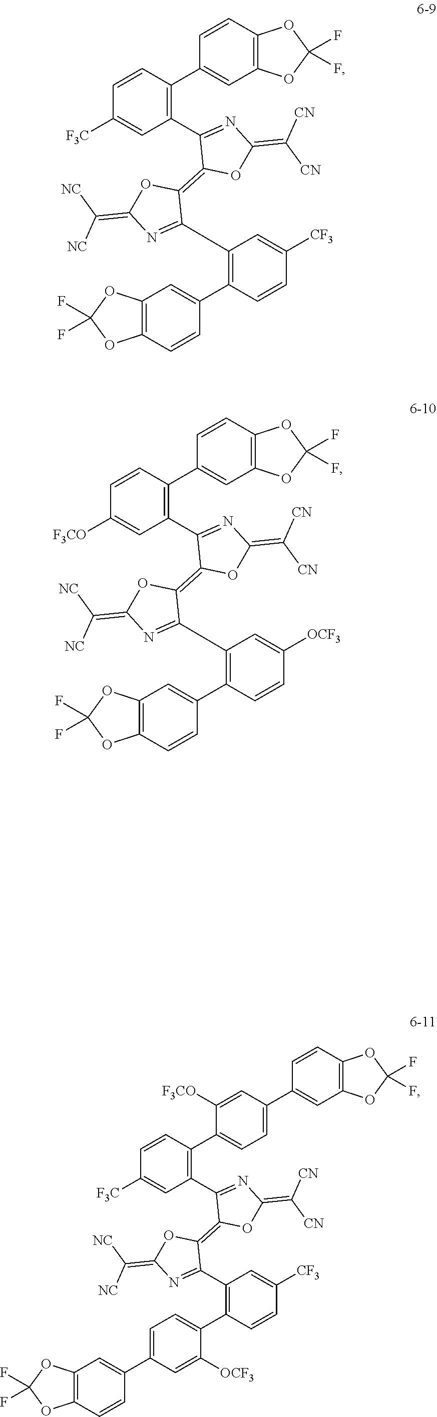 [SMILES: N#CC(C#N)=c1nc(-c2cc(C(F)(F)F)ccc2-c2ccc3c(c2)OC(F)(F)O3)/c(=c2\oc(=C(C#N)C#N)nc2-c2cc(C(F)(F)F)ccc2-c2ccc3c(c2)OC(F)(F)O3)o1 ; N#CC(C#N)=c1nc(-c2cc(OC(F)(F)F)ccc2-c2ccc3c(c2)OC(F)(F)O3)/c(=c2\oc(=C(C#N)C#N)nc2-c2cc(OC(F)(F)F)ccc2-c2ccc3c(c2)OC(F)(F)O3)o1 ; N#CC(C#N)=c1nc(-c2cc(C(F)(F)F)ccc2-c2ccc(-c3ccc4c(c3)OC(F)(F)O4)cc2OC(F)(F)F)/c(=c2\oc(=C(C#N)C#N)nc2-c2cc(C(F)(F)F)ccc2-c2ccc(-c3ccc4c(c3)OC(F)(F)O4)cc2OC(F)(F)F)o1]

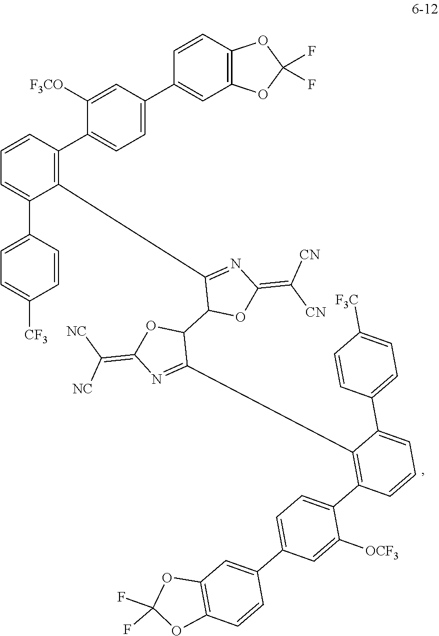 [SMILES: N#CC(C#N)=C1N=C(c2c(-c3ccc(C(F)(F)F)cc3)cccc2-c2ccc(-c3ccc4c(c3)OC(F)(F)O4)cc2OC(F)(F)F)C(C2OC(=C(C#N)C#N)N=C2c2c(-c3ccc(C(F)(F)F)cc3)cccc2-c2ccc(-c3ccc4c(c3)OC(F)(F)O4)cc2OC(F)(F)F)O1]

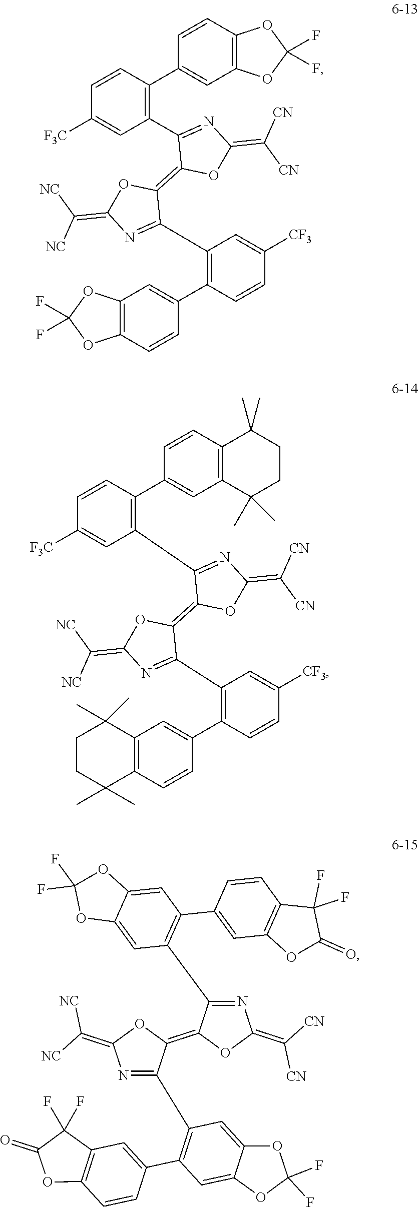 [SMILES: N#CC(C#N)=c1nc(-c2cc(C(F)(F)F)ccc2-c2ccc3c(c2)OC(F)(F)O3)/c(=c2\oc(=C(C#N)C#N)nc2-c2cc(C(F)(F)F)ccc2-c2ccc3c(c2)OC(F)(F)O3)o1 ; CC1(C)CCC(C)(C)c2cc(-c3ccc(C(F)(F)F)cc3-c3nc(=C(C#N)C#N)o/c3=c3/oc(=C(C#N)C#N)nc3-c3cc(C(F)(F)F)ccc3-c3ccc4c(c3)C(C)(C)CCC4(C)C)ccc21 ; N#CC(C#N)=c1nc(-c2cc3c(cc2-c2ccc4c(c2)OC(=O)C4(F)F)OC(F)(F)O3)/c(=c2\oc(=C(C#N)C#N)nc2-c2cc3c(cc2-c2ccc4c(c2)C(F)(F)C(=O)O4)OC(F)(F)O3)o1]

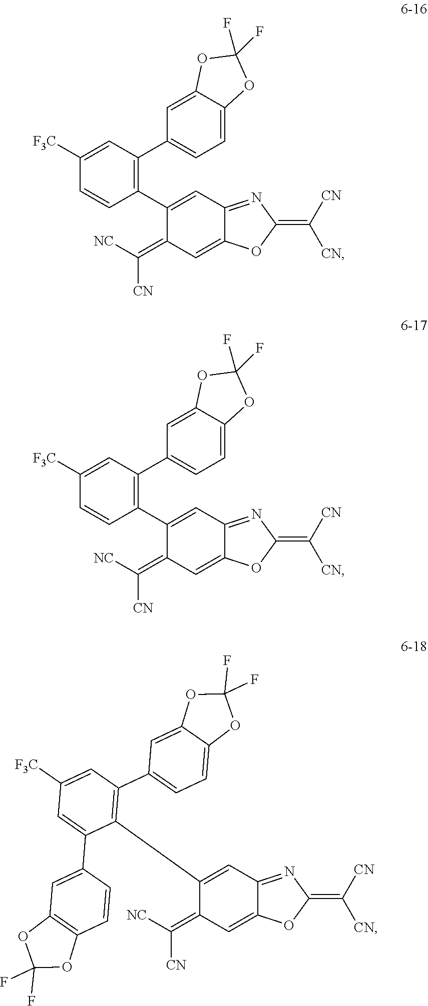 [SMILES: N#CC(C#N)=c1nc2cc(-c3ccc(C(F)(F)F)cc3-c3ccc4c(c3)OC(F)(F)O4)c(=C(C#N)C#N)cc2o1 ; N#CC(C#N)=c1nc2cc(-c3ccc(C(F)(F)F)cc3-c3ccc4c(c3)OC(F)(F)O4)c(=C(C#N)C#N)cc2o1 ; N#CC(C#N)=c1nc2cc(-c3c(-c4ccc5c(c4)OC(F)(F)O5)cc(C(F)(F)F)cc3-c3ccc4c(c3)OC(F)(F)O4)c(=C(C#N)C#N)cc2o1]

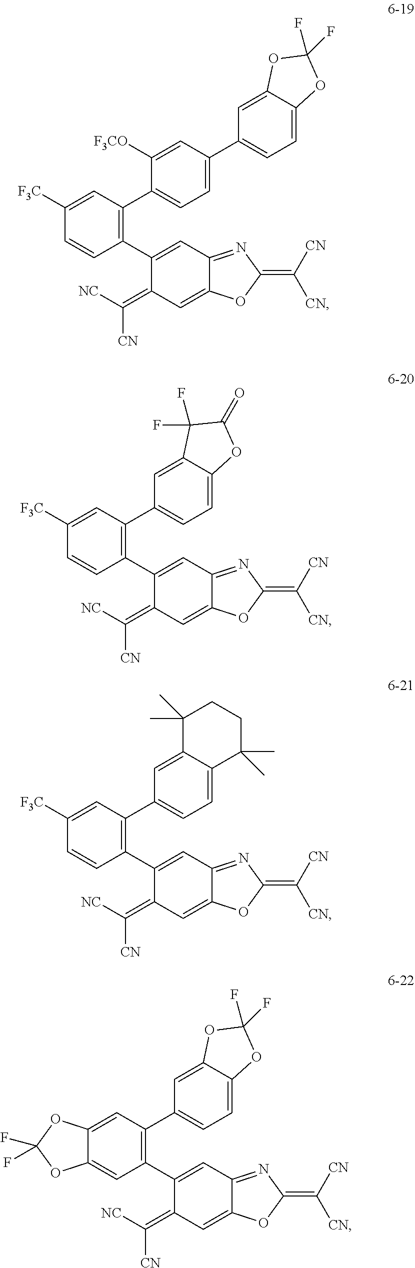 [SMILES: N#CC(C#N)=c1nc2cc(-c3ccc(C(F)(F)F)cc3-c3ccc(-c4ccc5c(c4)OC(F)(F)O5)cc3OC(F)(F)F)c(=C(C#N)C#N)cc2o1 ; N#CC(C#N)=c1nc2cc(-c3ccc(C(F)(F)F)cc3-c3ccc4c(c3)C(F)(F)C(=O)O4)c(=C(C#N)C#N)cc2o1 ; CC1(C)CCC(C)(C)c2cc(-c3cc(C(F)(F)F)ccc3-c3cc4nc(=C(C#N)C#N)oc4cc3=C(C#N)C#N)ccc21 ; N#CC(C#N)=c1nc2cc(-c3cc4c(cc3-c3ccc5c(c3)OC(F)(F)O5)OC(F)(F)O4)c(=C(C#N)C#N)cc2o1]

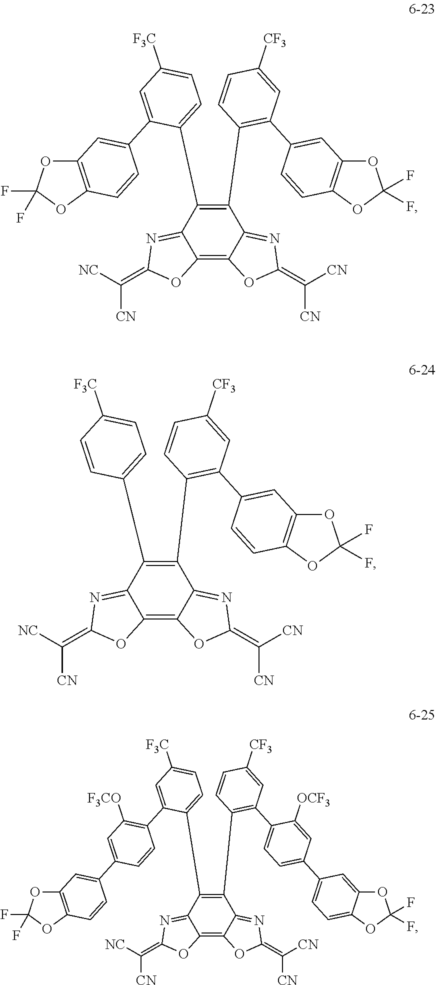 [SMILES: N#CC(C#N)=c1nc2c(-c3ccc(C(F)(F)F)cc3-c3ccc4c(c3)OC(F)(F)O4)c(-c3ccc(C(F)(F)F)cc3-c3ccc4c(c3)OC(F)(F)O4)c3nc(=C(C#N)C#N)oc3c2o1 ; N#CC(C#N)=c1nc2c(-c3ccc(C(F)(F)F)cc3)c(-c3ccc(C(F)(F)F)cc3-c3ccc4c(c3)OC(F)(F)O4)c3nc(=C(C#N)C#N)oc3c2o1 ; N#CC(C#N)=c1nc2c(-c3ccc(C(F)(F)F)cc3-c3ccc(-c4ccc5c(c4)OC(F)(F)O5)cc3OC(F)(F)F)c(-c3ccc(C(F)(F)F)cc3-c3ccc(-c4ccc5c(c4)OC(F)(F)O5)cc3OC(F)(F)F)c3nc(=C(C#N)C#N)oc3c2o1]

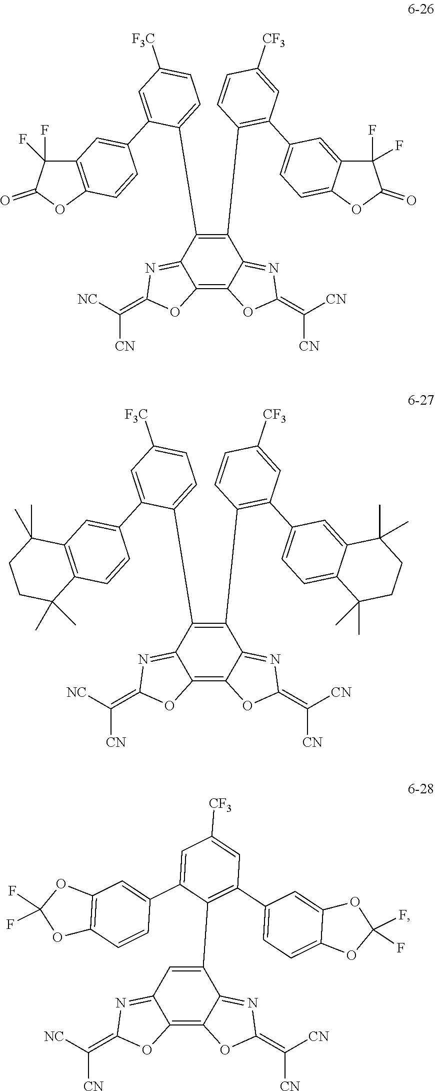 [SMILES: N#CC(C#N)=c1nc2c(-c3ccc(C(F)(F)F)cc3-c3ccc4c(c3)C(F)(F)C(=O)O4)c(-c3ccc(C(F)(F)F)cc3-c3ccc4c(c3)C(F)(F)C(=O)O4)c3nc(=C(C#N)C#N)oc3c2o1 ; CC1(C)CCC(C)(C)c2cc(-c3cc(C(F)(F)F)ccc3-c3c(-c4ccc(C(F)(F)F)cc4-c4ccc5c(c4)C(C)(C)CCC5(C)C)c4nc(=C(C#N)C#N)oc4c4oc(=C(C#N)C#N)nc34)ccc21 ; N#CC(C#N)=c1nc2cc(-c3c(-c4ccc5c(c4)OC(F)(F)O5)cc(C(F)(F)F)cc3-c3ccc4c(c3)OC(F)(F)O4)c3nc(=C(C#N)C#N)oc3c2o1]

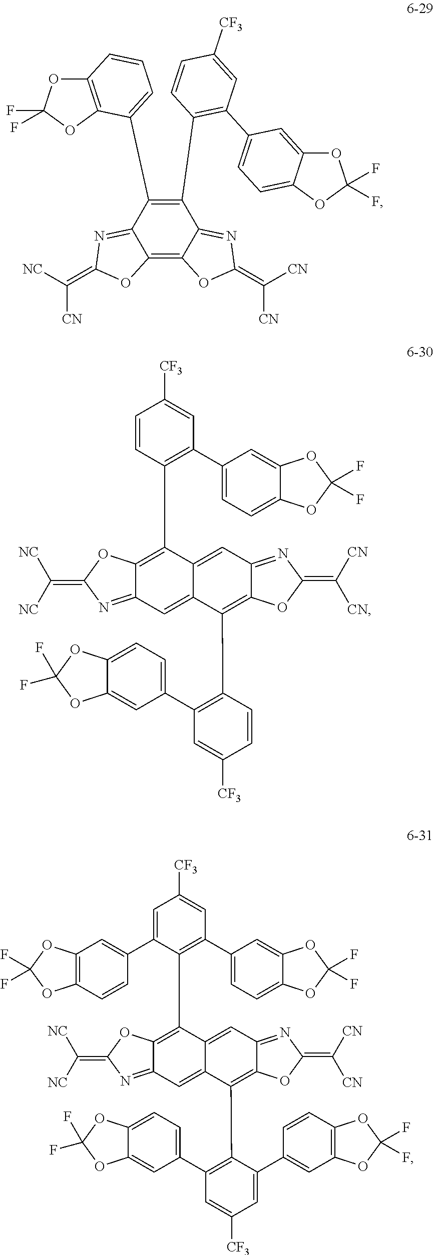 [SMILES: N#CC(C#N)=c1nc2c(-c3ccc(C(F)(F)F)cc3-c3ccc4c(c3)OC(F)(F)O4)c(-c3cccc4c3OC(F)(F)O4)c3nc(=C(C#N)C#N)oc3c2o1 ; N#CC(C#N)=c1nc2cc3c(-c4ccc(C(F)(F)F)cc4-c4ccc5c(c4)OC(F)(F)O5)c4oc(=C(C#N)C#N)nc4cc3c(-c3ccc(C(F)(F)F)cc3-c3ccc4c(c3)OC(F)(F)O4)c2o1 ; N#CC(C#N)=c1nc2cc3c(-c4c(-c5ccc6c(c5)OC(F)(F)O6)cc(C(F)(F)F)cc4-c4ccc5c(c4)OC(F)(F)O5)c4oc(=C(C#N)C#N)nc4cc3c(-c3c(-c4ccc5c(c4)OC(F)(F)O5)cc(C(F)(F)F)cc3-c3ccc4c(c3)OC(F)(F)O4)c2o1]

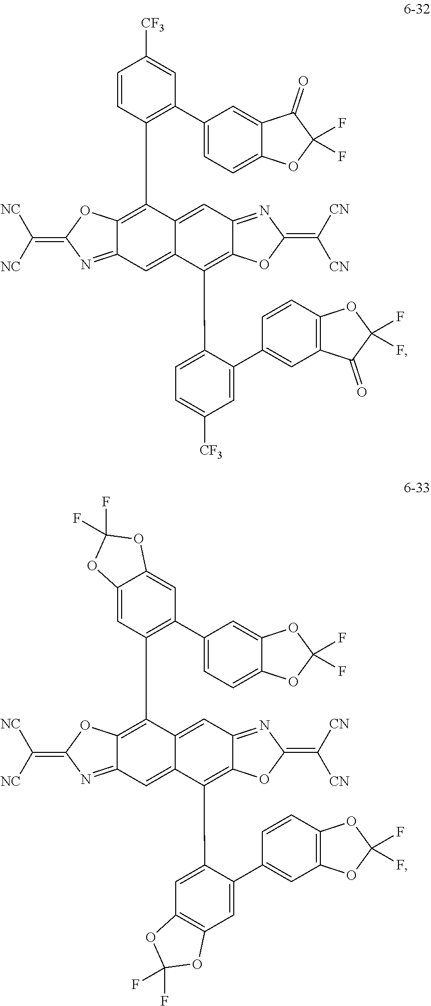 [SMILES: N#CC(C#N)=c1nc2cc3c(-c4ccc(C(F)(F)F)cc4-c4ccc5c(c4)C(=O)C(F)(F)O5)c4oc(=C(C#N)C#N)nc4cc3c(-c3ccc(C(F)(F)F)cc3-c3ccc4c(c3)C(=O)C(F)(F)O4)c2o1 ; N#CC(C#N)=c1nc2cc3c(-c4cc5c(cc4-c4ccc6c(c4)OC(F)(F)O6)OC(F)(F)O5)c4oc(=C(C#N)C#N)nc4cc3c(-c3cc4c(cc3-c3ccc5c(c3)OC(F)(F)O5)OC(F)(F)O4)c2o1]

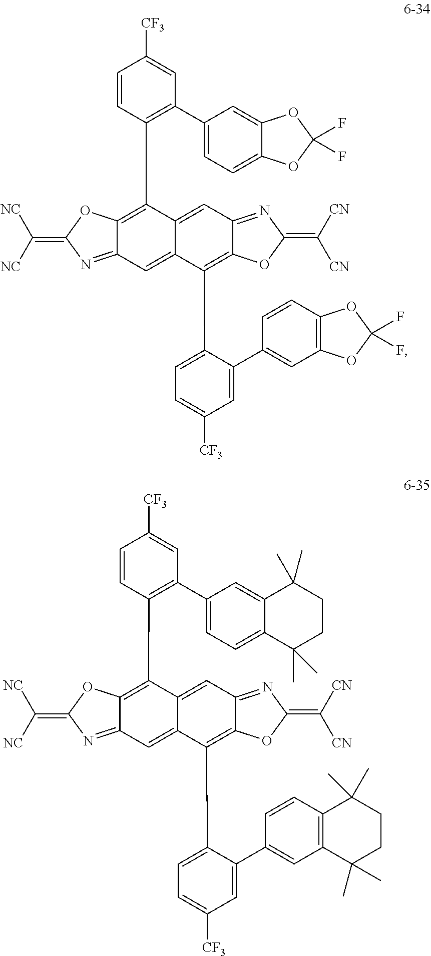 [SMILES: N#CC(C#N)=c1nc2cc3c(-c4ccc(C(F)(F)F)cc4-c4ccc5c(c4)OC(F)(F)O5)c4oc(=C(C#N)C#N)nc4cc3c(-c3ccc(C(F)(F)F)cc3-c3ccc4c(c3)OC(F)(F)O4)c2o1 ; CC1(C)CCC(C)(C)c2cc(-c3cc(C(F)(F)F)ccc3-c3c4cc5nc(=C(C#N)C#N)oc5c(-c5ccc(C(F)(F)F)cc5-c5ccc6c(c5)C(C)(C)CCC6(C)C)c4cc4nc(=C(C#N)C#N)oc34)ccc21]

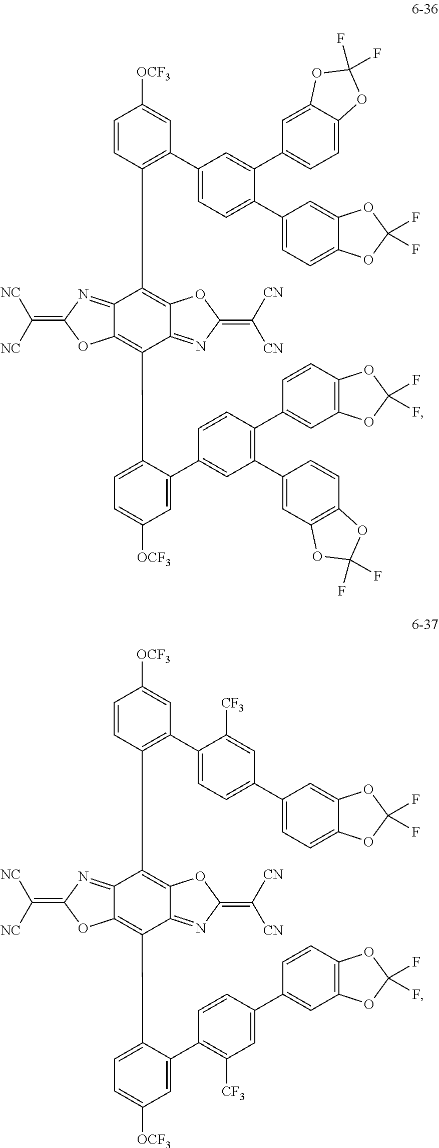 [SMILES: N#CC(C#N)=c1nc2c(-c3ccc(OC(F)(F)F)cc3-c3ccc(-c4ccc5c(c4)OC(F)(F)O5)c(-c4ccc5c(c4)OC(F)(F)O5)c3)c3oc(=C(C#N)C#N)nc3c(-c3ccc(OC(F)(F)F)cc3-c3ccc(-c4ccc5c(c4)OC(F)(F)O5)c(-c4ccc5c(c4)OC(F)(F)O5)c3)c2o1 ; N#CC(C#N)=c1nc2c(-c3ccc(OC(F)(F)F)cc3-c3ccc(-c4ccc5c(c4)OC(F)(F)O5)cc3C(F)(F)F)c3oc(=C(C#N)C#N)nc3c(-c3ccc(OC(F)(F)F)cc3-c3ccc(-c4ccc5c(c4)OC(F)(F)O5)cc3C(F)(F)F)c2o1]

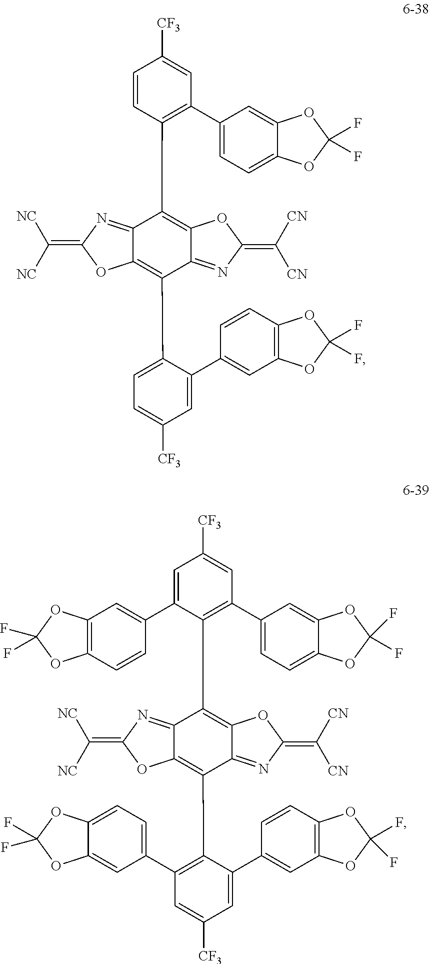 [SMILES: N#CC(C#N)=c1nc2c(-c3ccc(C(F)(F)F)cc3-c3ccc4c(c3)OC(F)(F)O4)c3oc(=C(C#N)C#N)nc3c(-c3ccc(C(F)(F)F)cc3-c3ccc4c(c3)OC(F)(F)O4)c2o1 ; N#CC(C#N)=c1nc2c(-c3c(-c4ccc5c(c4)OC(F)(F)O5)cc(C(F)(F)F)cc3-c3ccc4c(c3)OC(F)(F)O4)c3oc(=C(C#N)C#N)nc3c(-c3c(-c4ccc5c(c4)OC(F)(F)O5)cc(C(F)(F)F)cc3-c3ccc4c(c3)OC(F)(F)O4)c2o1]

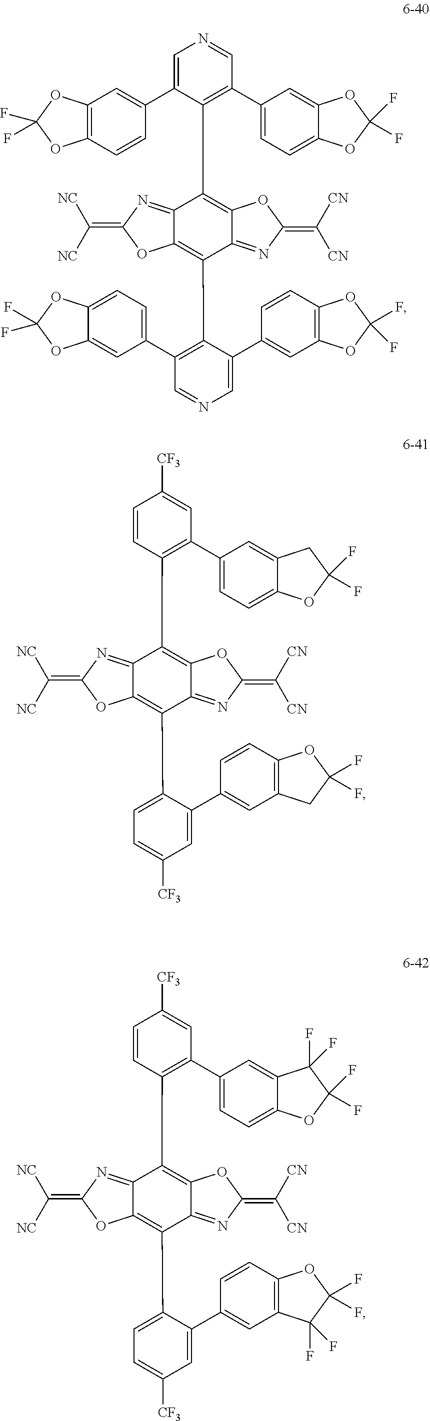 [SMILES: N#CC(C#N)=c1nc2c(-c3c(-c4ccc5c(c4)OC(F)(F)O5)cncc3-c3ccc4c(c3)OC(F)(F)O4)c3oc(=C(C#N)C#N)nc3c(-c3c(-c4ccc5c(c4)OC(F)(F)O5)cncc3-c3ccc4c(c3)OC(F)(F)O4)c2o1 ; N#CC(C#N)=c1nc2c(-c3ccc(C(F)(F)F)cc3-c3ccc4c(c3)CC(F)(F)O4)c3oc(=C(C#N)C#N)nc3c(-c3ccc(C(F)(F)F)cc3-c3ccc4c(c3)CC(F)(F)O4)c2o1 ; N#CC(C#N)=c1nc2c(-c3ccc(C(F)(F)F)cc3-c3ccc4c(c3)C(F)(F)C(F)(F)O4)c3oc(=C(C#N)C#N)nc3c(-c3ccc(C(F)(F)F)cc3-c3ccc4c(c3)C(F)(F)C(F)(F)O4)c2o1]

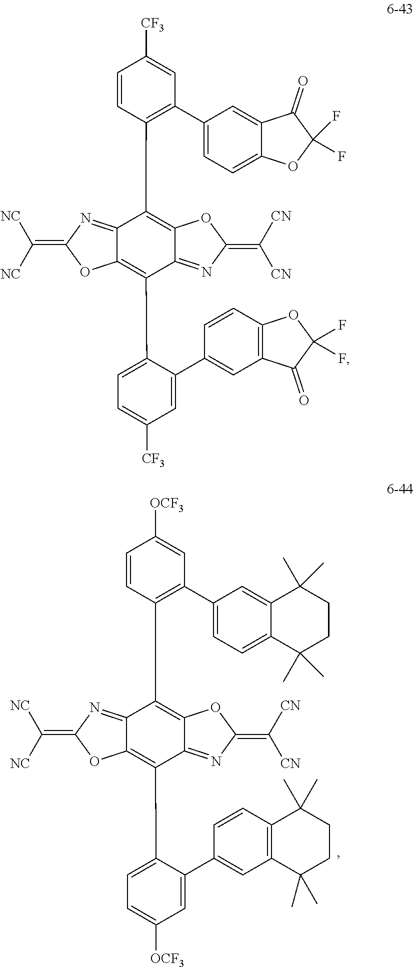

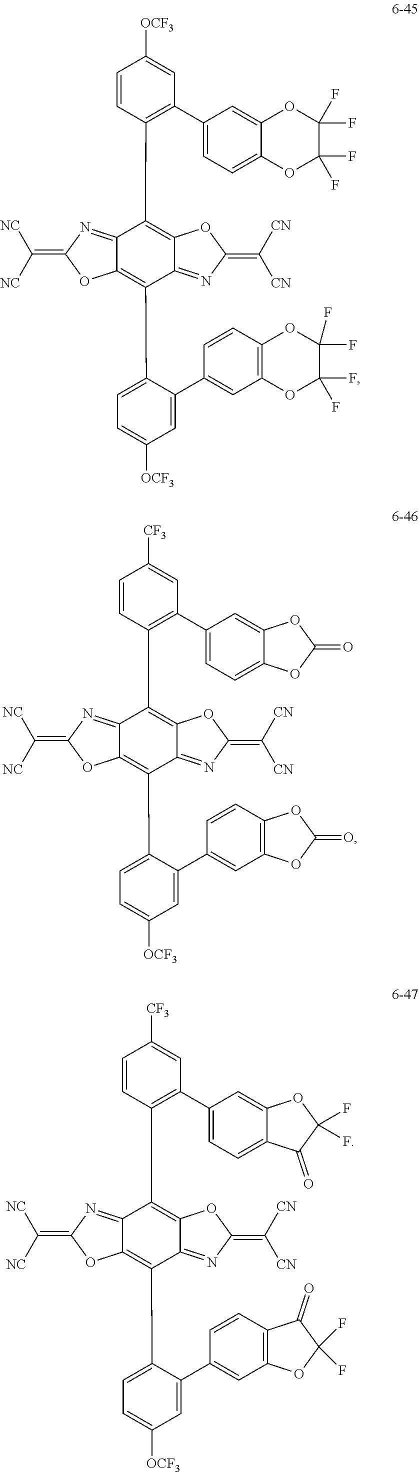 [SMILES: N#CC(C#N)=c1nc2c(-c3ccc(OC(F)(F)F)cc3-c3ccc4c(c3)OC(F)(F)C(F)(F)O4)c3oc(=C(C#N)C#N)nc3c(-c3ccc(OC(F)(F)F)cc3-c3ccc4c(c3)OC(F)(F)C(F)(F)O4)c2o1 ; N#CC(C#N)=c1nc2c(-c3ccc(C(F)(F)F)cc3-c3ccc4oc(=O)oc4c3)c3oc(=C(C#N)C#N)nc3c(-c3ccc(OC(F)(F)F)cc3-c3ccc4oc(=O)oc4c3)c2o1 ; N#CC(C#N)=c1nc2c(-c3ccc(C(F)(F)F)cc3-c3ccc4c(c3)OC(F)(F)C4=O)c3oc(=C(C#N)C#N)nc3c(-c3ccc(OC(F)(F)F)cc3-c3ccc4c(c3)OC(F)(F)C4=O)c2o1]

According to an embodiment of the present disclosure, hydrogen in the structures of Compound 2-23, Compound 6-1 to Compound 6-47 can be partially or fully substituted with deuterium.

According to an embodiment of the present disclosure, the second organic material is selected from the group consisting of the following compounds: a compound having a triarylamine unit, a spirobifluorene compound, a pentacene compound, an oligothiophene compound, an oligophenyl compound, an oligophenylenevinylene compound, an oligofluorene compound, a porphyrin complex or a metallic phthalocyanine complex.

According to an embodiment of the present disclosure, the second organic material comprises any one or more chemical structural units selected from the group consisting of: triarylamine, carbazole, fluorene, spirobifluorene, thiophene, furan, phenyl, oligophenylenevinylene, oligofluorene and combinations thereof.

According to an embodiment of the present disclosure, the second organic material comprises a monotriarylamine structural unit or a bistriarylamine structural unit.

According to an embodiment of the present disclosure, the second organic material comprises any one or more chemical structural units selected from the group consisting of: a monotriarylamine-carbazole structural unit, a monotriarylamine-thiophene structural unit, a monotriarylamine-furan structural unit, a monotriarylamine-fluorene structural unit, a bistriarylamine-carbazole structural unit, a bistriarylamine-thiophene structural unit, a bistriarylamine-furan structural unit and a bistriarylamine-fluorene structural unit.

According to an embodiment of the present disclosure, the second organic material is a monotriarylamine compound or a bistriarylamine compound.

According to an embodiment of the present disclosure, the second organic material is selected from a monotriarylamine-carbazole compound, a monotriarylamine-thiophene compound, a monotriarylamine-furan compound, a monotriarylamine-fluorene compound, a bistriarylamine-carbazole compound, a bistriarylamine-thiophene compound, a bistriarylamine-furan compound and a bistriarylamine-fluorene compound.

According to an embodiment of the present disclosure, the second organic material has a structure represented by Formula 2 or Formula 3:

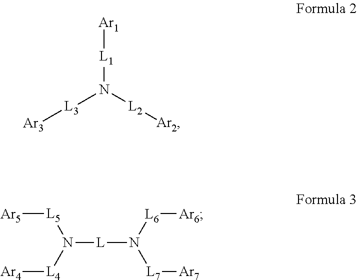

wherein Ar₁ to Ar₇ are, at each occurrence identically or differently, selected from substituted or unsubstituted aryl having 6 to 30 carbon atoms, substituted or unsubstituted heteroaryl having 3 to 30 carbon atoms or a combination thereof; L is selected from substituted or unsubstituted arylene having 6 to 30 carbon atoms, substituted or unsubstituted heteroarylene having 3 to 30 carbon atoms or a combination thereof; and
L₁ to L₇ are, at each occurrence identically or differently, selected from a single bond, substituted or unsubstituted arylene having 6 to 30 carbon atoms, substituted or unsubstituted heteroarylene having 3 to 30 carbon atoms or a combination thereof.

According to an embodiment of the present disclosure, Formula 2 represents a monoamine compound containing only the one amino N atom shown.

According to an embodiment of the present disclosure, Ar₁ to Ar₇ are, at each occurrence identically or differently, selected from substituted or unsubstituted phenyl, substituted or unsubstituted biphenyl, substituted or unsubstituted terphenyl, substituted or unsubstituted naphthyl, substituted or unsubstituted dibenzofuranyl, substituted or unsubstituted dibenzothienyl, substituted or unsubstituted dibenzoselenophenyl, substituted or unsubstituted carbazolyl, substituted or unsubstituted phenanthryl, substituted or unsubstituted triphenylenyl, substituted or unsubstituted pyridyl, substituted or unsubstituted anthryl, substituted or unsubstituted pyrenyl, substituted or unsubstituted fluorenyl or a combination thereof.

According to an embodiment of the present disclosure, L is identically or differently selected from substituted or unsubstituted phenylene, substituted or unsubstituted biphenylylene, substituted or unsubstituted terphenylene, substituted or unsubstituted naphthylene, substituted or unsubstituted dibenzofuranylene, substituted or unsubstituted dibenzothienylene, substituted or unsubstituted dibenzoselenophenylene, substituted or unsubstituted carbazolylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene or a combination thereof.

According to an embodiment of the present disclosure, L₁ to L₇ are, at each occurrence identically or differently, selected from a single bond, substituted or unsubstituted phenylene, substituted or unsubstituted biphenylylene, substituted or unsubstituted terphenylene, substituted or unsubstituted naphthylene, substituted or unsubstituted dibenzofuranylene, substituted or unsubstituted dibenzothienylene, substituted or unsubstituted dibenzoselenophenylene, substituted or unsubstituted carbazolylene, substituted or unsubstituted phenanthrylene, substituted or unsubstituted triphenylenylene, substituted or unsubstituted pyridylene, substituted or unsubstituted anthrylene, substituted or unsubstituted pyrenylene, substituted or unsubstituted fluorenylene or a combination thereof.

According to an embodiment of the present disclosure, the second organic material has a structure represented by Formula 2-1:

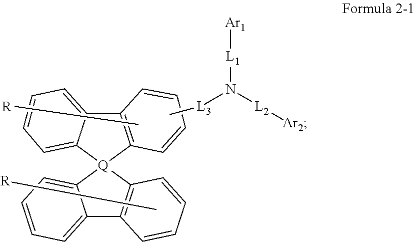

wherein Q is selected from C, Si or Ge;
Ar₁ and Ar₂ are, at each occurrence identically or differently, selected from substituted or unsubstituted aryl having 6 to 30 carbon atoms, substituted or unsubstituted heteroaryl having 3 to 30 carbon atoms or a combination thereof;
L₁ and L₂ are, at each occurrence identically or differently, selected from a single bond, substituted or unsubstituted arylene having 6 to 30 carbon atoms, substituted or unsubstituted heteroarylene having 3 to 30 carbon atoms or a combination thereof;
R represents, at each occurrence identically or differently, mono-substitution, multiple substitutions or non-substitution;
R is, at each occurrence identically or differently, selected from the group consisting of: hydrogen, deuterium, halogen, substituted or unsubstituted alkyl having 1 to 20 carbon atoms, substituted or unsubstituted cycloalkyl having 3 to 20 ring carbon atoms, substituted or unsubstituted heteroalkyl having 1 to 20 carbon atoms, substituted or unsubstituted heterocyclic group having 3 to 20 ring atoms, substituted or unsubstituted arylalkyl having 7 to 30 carbon atoms, substituted or unsubstituted alkoxy having 1 to 20 carbon atoms, substituted or unsubstituted aryloxy having 6 to 30 carbon atoms, substituted or unsubstituted alkenyl having 2 to 20 carbon atoms, substituted or unsubstituted alkynyl having 2 to 20 carbon atoms, substituted or unsubstituted aryl having 6 to 30 carbon atoms, substituted or unsubstituted heteroaryl having 3 to 30 carbon atoms, substituted or unsubstituted alkylsilyl having 3 to 20 carbon atoms, substituted or unsubstituted arylsilyl having 6 to 20 carbon atoms, substituted or unsubstituted alkylgermanyl having 3 to 20 carbon atoms, substituted or unsubstituted arylgermanyl having 6 to 20 carbon atoms, an acyl group, a carbonyl group, a carboxylic acid group, an ester group, a cyano group, an isocyano group, a hydroxyl group, a sulfanyl group, a sulfinyl group, a sulfonyl group, a phosphino group and combinations thereof; and
adjacent substituents R can be optionally joined to form a ring.

According to an embodiment of the present disclosure, the second organic material is selected from the group consisting of Compound HT-1 to Compound HT-60:

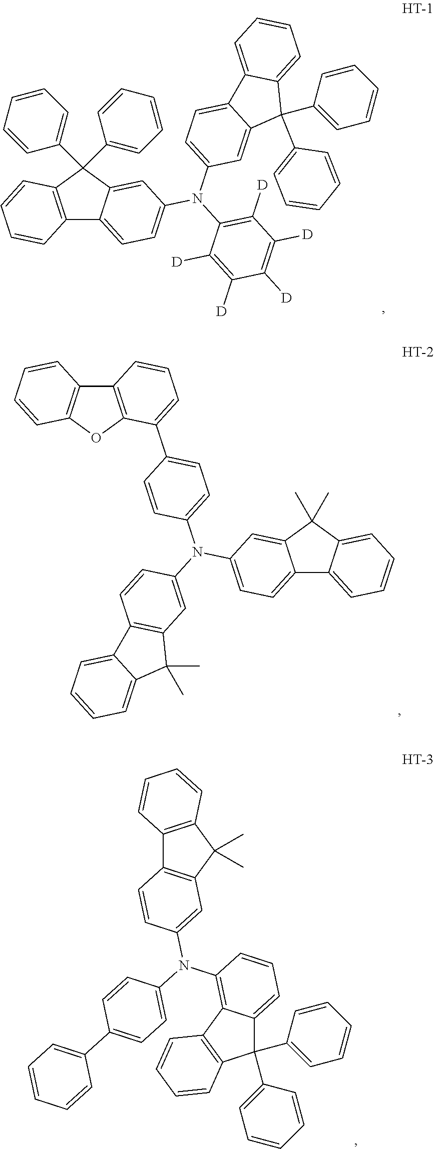 [SMILES: [2H]c1c([2H])c([2H])c(N(c2ccc3c(c2)C(c2ccccc2)(c2ccccc2)c2ccccc2-3)c2ccc3c(c2)C(c2ccccc2)(c2ccccc2)c2ccccc2-3)c([2H])c1[2H] ; CC1(C)c2ccccc2-c2ccc(N(c3ccc(-c4cccc5c4oc4ccccc45)cc3)c3ccc4c(c3)C(C)(C)c3ccccc3-4)cc21 ; CC1(C)c2ccccc2-c2ccc(N(c3ccc(-c4ccccc4)cc3)c3cccc4c3-c3ccccc3C4(c3ccccc3)c3ccccc3)cc21]

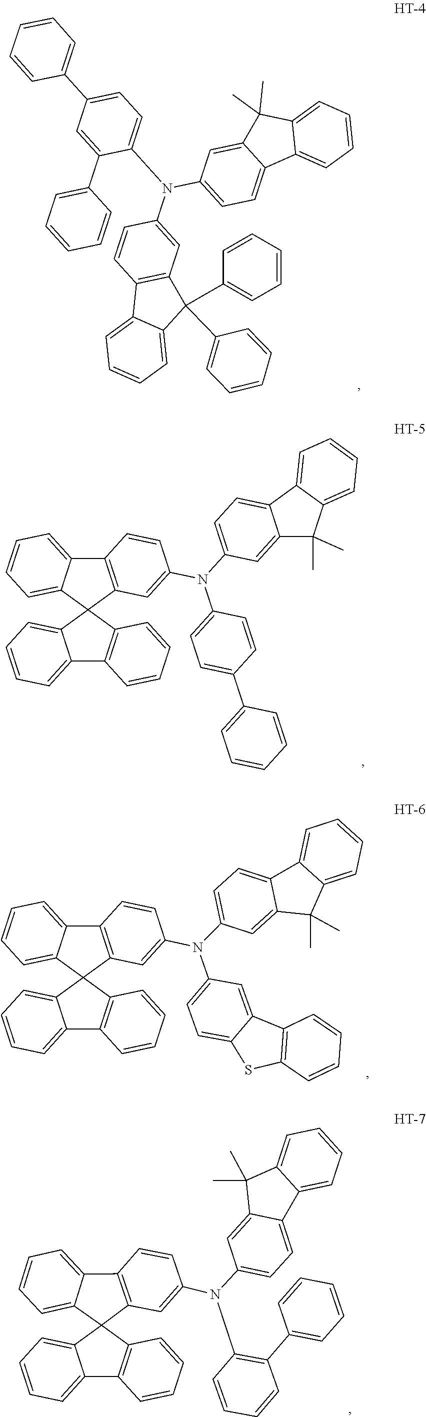 [SMILES: CC1(C)c2ccccc2-c2ccc(N(c3ccc4c(c3)C(c3ccccc3)(c3ccccc3)c3ccccc3-4)c3ccc(-c4ccccc4)cc3-c3ccccc3)cc21 ; CC1(C)c2ccccc2-c2ccc(N(c3ccc(-c4ccccc4)cc3)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccc4sc5ccccc5c4c3)cc21 ; CC1(C)c2ccccc2-c2ccc(N(c3ccc4c(c3)C3(c5ccccc5-c5ccccc53)c3ccccc3-4)c3ccccc3-c3ccccc3)cc21]

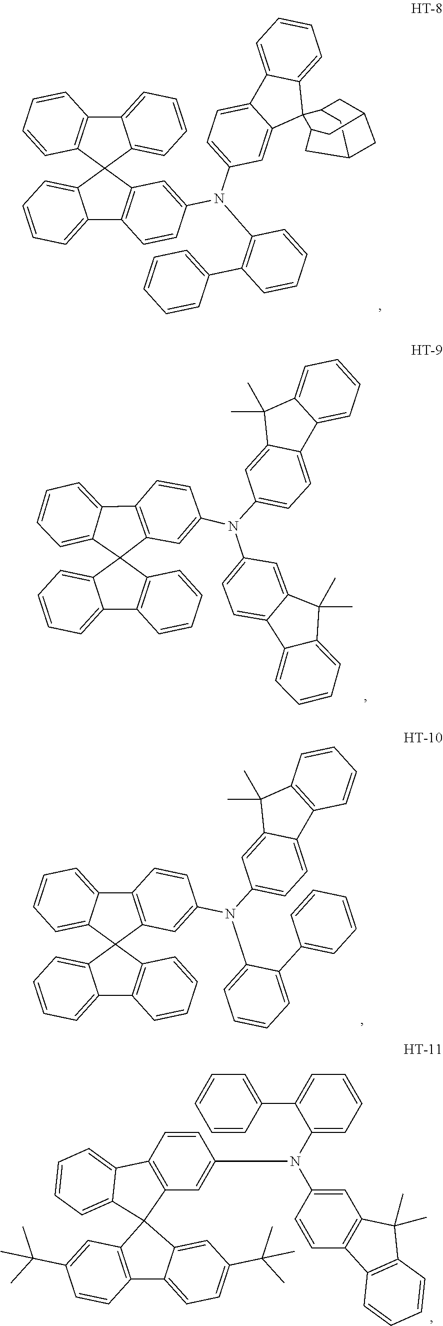 [SMILES: c1ccc(-c2ccccc2N(c2ccc3c(c2)C2(c4ccccc4-c4ccccc42)c2ccccc2-3)c2ccc3c(c2)C2(c4ccccc4-3)C3CC4CC(C3)CC2C4)cc1 ; CC1(C)c2ccccc2-c2ccc(N(c3ccc4c(c3)C(C)(C)c3ccccc3-4)c3ccc4c(c3)C3(c5ccccc5-c5ccccc53)c3ccccc3-4)cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2]

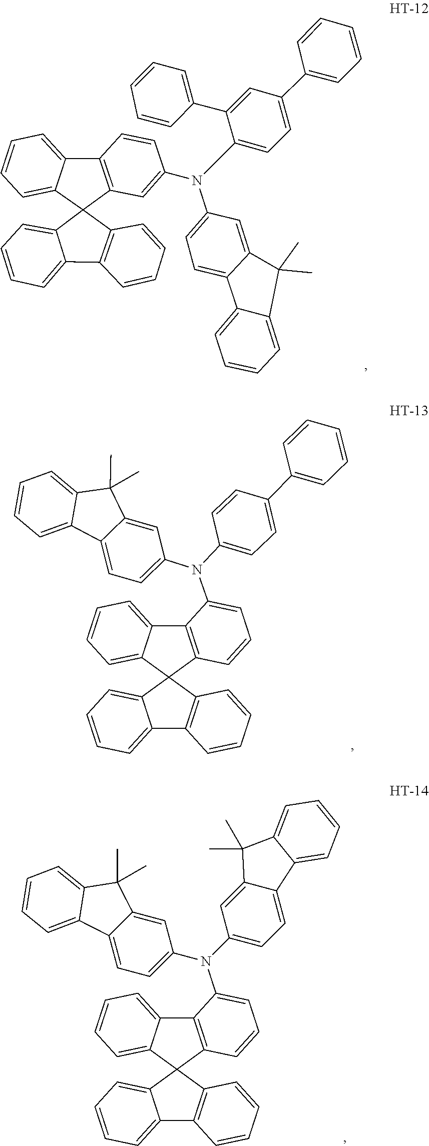 [SMILES: CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21 ; CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21]

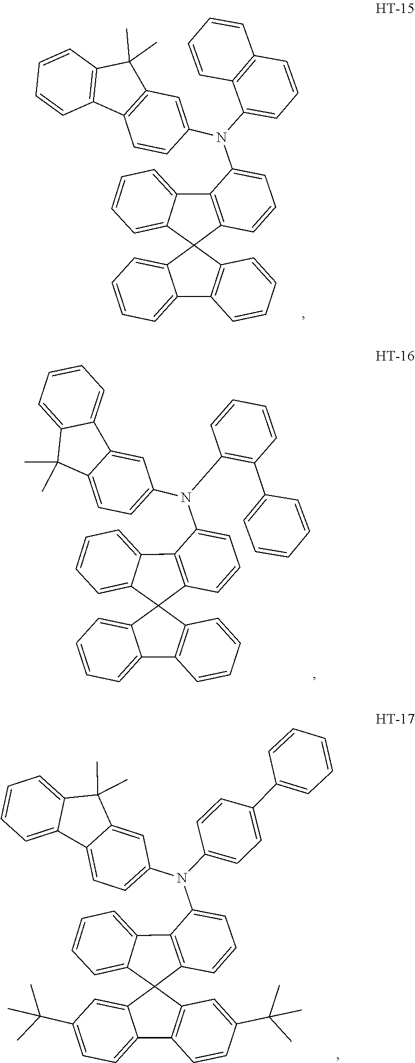 [SMILES: CC1(C)c2ccccc2-c2ccc(N(c3cccc4c3-c3ccccc3C43c4ccccc4-c4ccccc43)c3cccc4ccccc34)cc21 ; CC1(C)c2ccccc2-c2cc(N(c3ccccc3-c3ccccc3)c3cccc4c3-c3ccccc3C43c4ccccc4-c4ccccc43)ccc21 ; CC(C)(C)c1ccc2c(c1)C1(c3cc(C(C)(C)C)ccc3-2)c2ccccc2-c2c(N(c3ccc(-c4ccccc4)cc3)c3ccc4c(c3)C(C)(C)c3ccccc3-4)cccc21]

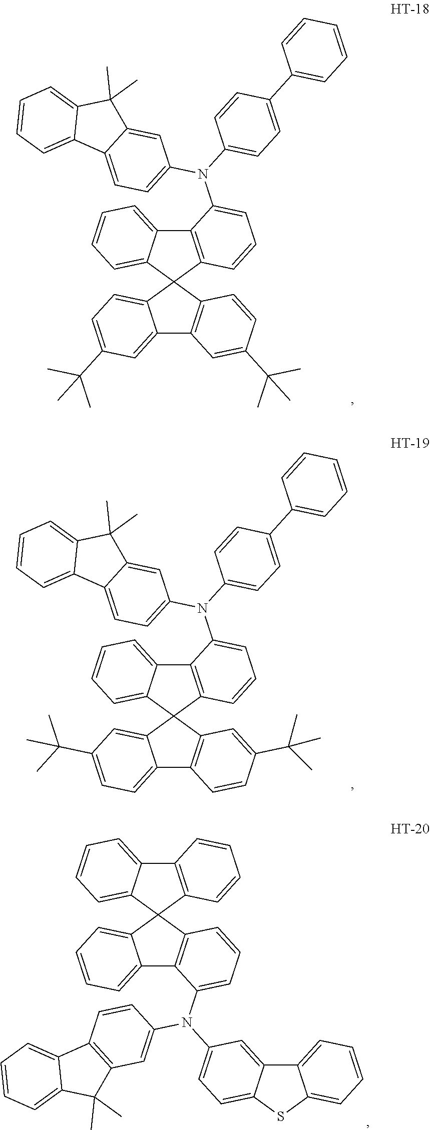 [SMILES: CC(C)(C)c1ccc2c(c1)-c1cc(C(C)(C)C)ccc1C21c2ccccc2-c2c(N(c3ccc(-c4ccccc4)cc3)c3ccc4c(c3)C(C)(C)c3ccccc3-4)cccc21 ; CC(C)(C)c1ccc2c(c1)C1(c3cc(C(C)(C)C)ccc3-2)c2ccccc2-c2c(N(c3ccc(-c4ccccc4)cc3)c3ccc4c(c3)C(C)(C)c3ccccc3-4)cccc21 ; CC1(C)c2ccccc2-c2ccc(N(c3ccc4sc5ccccc5c4c3)c3cccc4c3-c3ccccc3C43c4ccccc4-c4ccccc43)cc21]

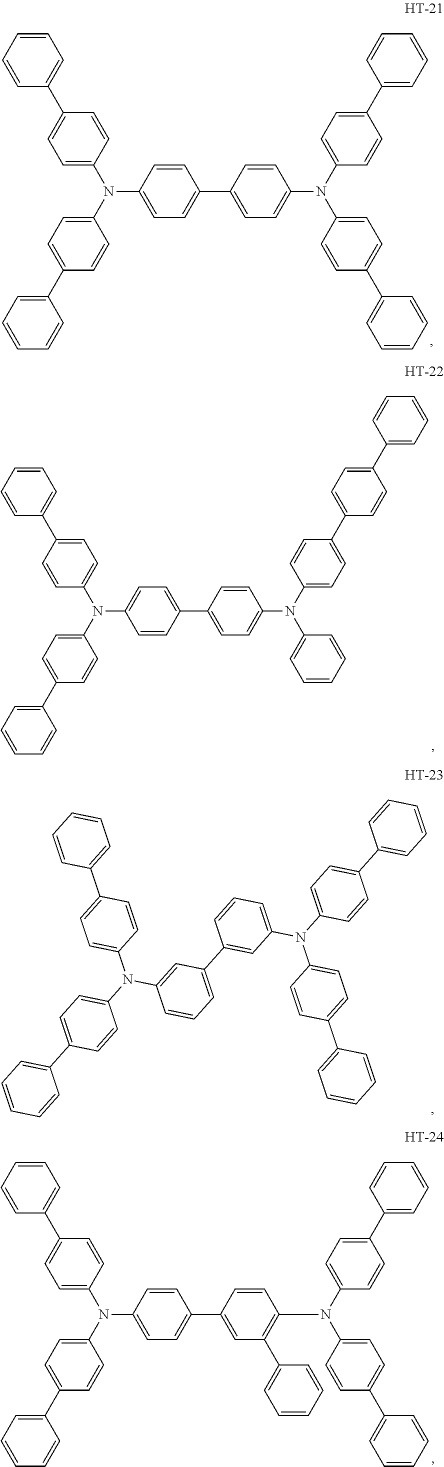 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(-c2ccc(N(c3ccc(-c4ccccc4)cc3)c3cccc(-c4cccc(N(c5ccc(-c6ccccc6)cc5)c5ccc(-c6ccccc6)cc5)c4)c3)cc2)cc1 ; c1ccc(-c2ccc(N(c3ccc(-c4ccccc4)cc3)c3ccc(-c4ccc(N(c5ccc(-c6ccccc6)cc5)c5ccc(-c6ccccc6)cc5)c(-c5ccccc5)c4)cc3)cc2)cc1]

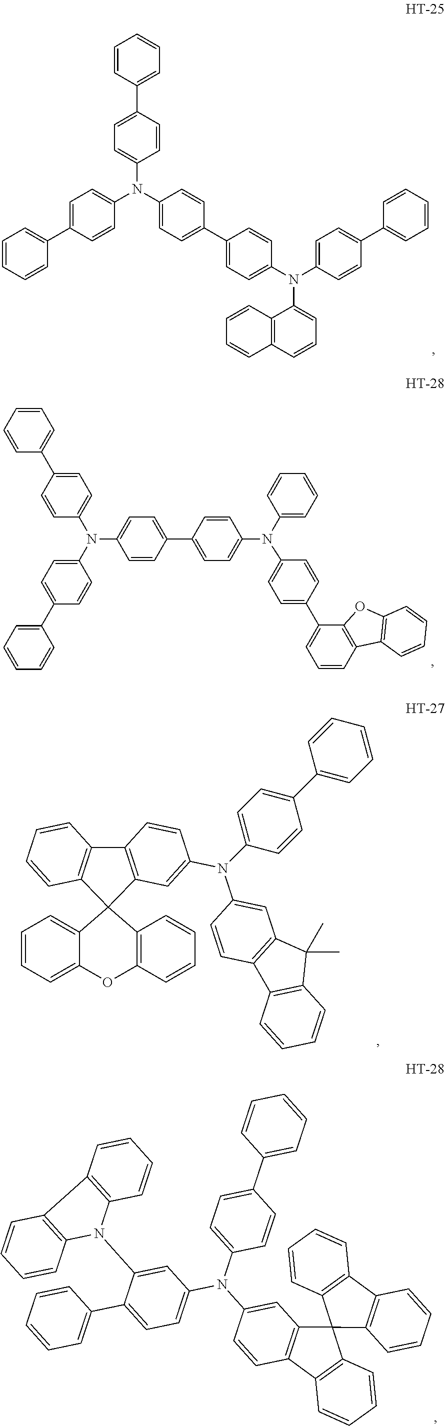 [SMILES: c1ccc(-c2ccc(N(c3ccc(-c4ccccc4)cc3)c3ccc(-c4ccc(N(c5ccc(-c6ccccc6)cc5)c5cccc6ccccc56)cc4)cc3)cc2)cc1 ; c1ccc(-c2ccc(N(c3ccc(-c4ccccc4)cc3)c3ccc(-c4ccc(N(c5ccccc5)c5ccc(-c6cccc7c6oc6ccccc67)cc5)cc4)cc3)cc2)cc1 ; CC1(C)c2ccccc2-c2ccc(N(c3ccc(-c4ccccc4)cc3)c3ccc4c(c3)C3(c5ccccc5Oc5ccccc53)c3ccccc3-4)cc21 ; c1ccc(-c2ccc(N(c3ccc(-c4ccccc4)c(-n4c5ccccc5c5ccccc54)c3)c3ccc4c(c3)C3(c5ccccc5-c5ccccc53)c3ccccc3-4)cc2)cc1]

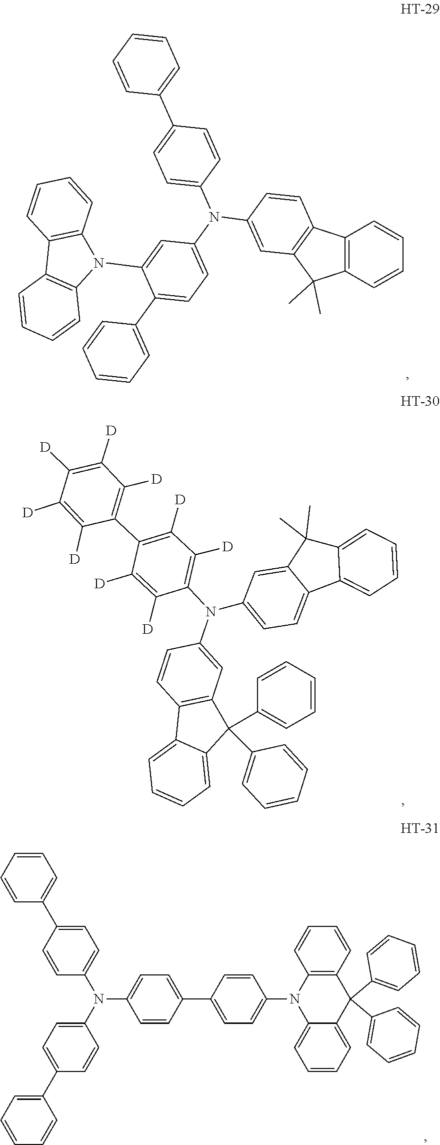 [SMILES: CC1(C)c2ccccc2-c2ccc(N(c3ccc(-c4ccccc4)cc3)c3ccc(-c4ccccc4)c(-n4c5ccccc5c5ccccc54)c3)cc21 ; [2H]c1c([2H])c([2H])c(-c2c([2H])c([2H])c(N(c3ccc4c(c3)C(C)(C)c3ccccc3-4)c3ccc4c(c3)C(c3ccccc3)(c3ccccc3)c3ccccc3-4)c([2H])c2[2H])c([2H])c1[2H] ; c1ccc(-c2ccc(N(c3ccc(-c4ccccc4)cc3)c3ccc(-c4ccc(N5c6ccccc6C(c6ccccc6)(c6ccccc6)c6ccccc65)cc4)cc3)cc2)cc1]

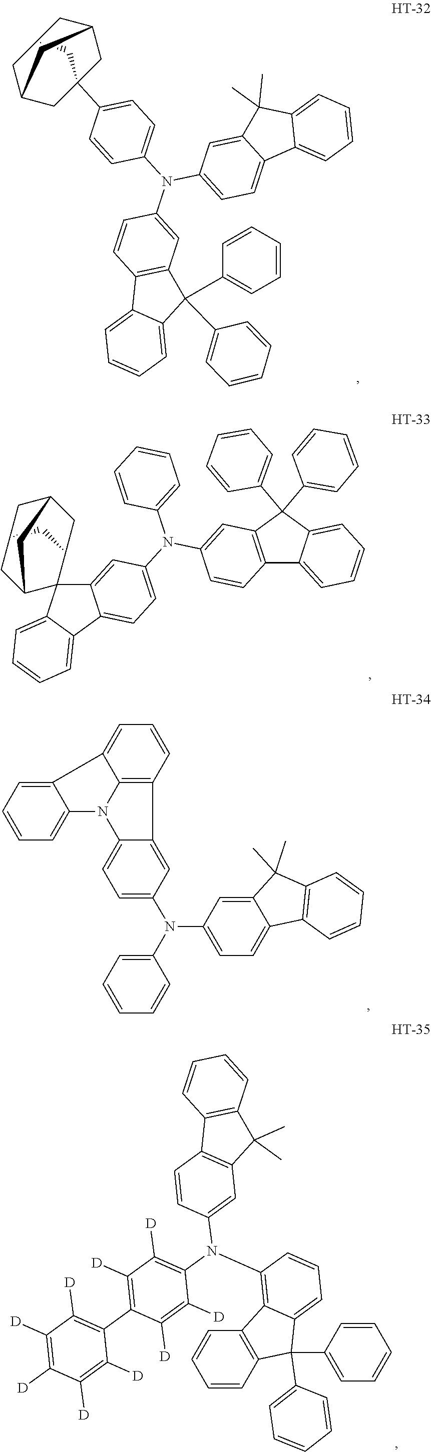 [SMILES: CC1(C)c2ccccc2-c2ccc(N(c3ccc([C@]45C[C@H]6C[C@H](C[C@H](C6)C4)C5)cc3)c3ccc4c(c3)C(c3ccccc3)(c3ccccc3)c3ccccc3-4)cc21 ; c1ccc(N(c2ccc3c(c2)C(c2ccccc2)(c2ccccc2)c2ccccc2-3)c2ccc3c(c2)C2(c4ccccc4-3)[C@H]3C[C@@H]4C[C@@H](C[C@H]2C4)C3)cc1 ; CC1(C)c2ccccc2-c2ccc(N(c3ccccc3)c3ccc4c(c3)c3cccc5c6ccccc6n4c53)cc21 ; [2H]c1c([2H])c([2H])c(-c2c([2H])c([2H])c(N(c3ccc4c(c3)C(C)(C)c3ccccc3-4)c3cccc4c3-c3ccccc3C4(c3ccccc3)c3ccccc3)c([2H])c2[2H])c([2H])c1[2H]]

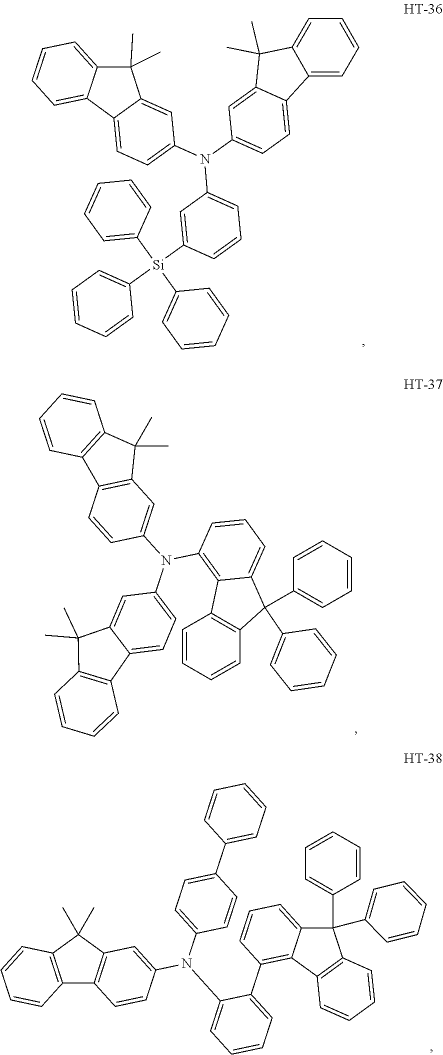 [SMILES: CC1(C)c2ccccc2-c2ccc(N(c3cccc([Si](c4ccccc4)(c4ccccc4)c4ccccc4)c3)c3ccc4c(c3)C(C)(C)c3ccccc3-4)cc21 ; CC1(C)c2ccccc2-c2ccc(N(c3ccc4c(c3)C(C)(C)c3ccccc3-4)c3cccc4c3-c3ccccc3C4(c3ccccc3)c3ccccc3)cc21 ; CC1(C)c2ccccc2-c2ccc(N(c3ccc(-c4ccccc4)cc3)c3ccccc3-c3cccc4c3-c3ccccc3C4(c3ccccc3)c3ccccc3)cc21]

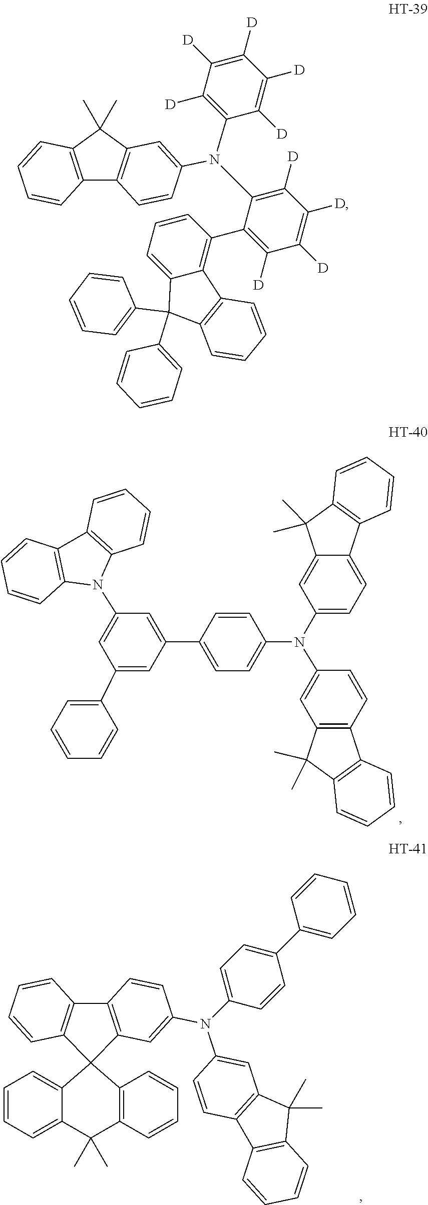

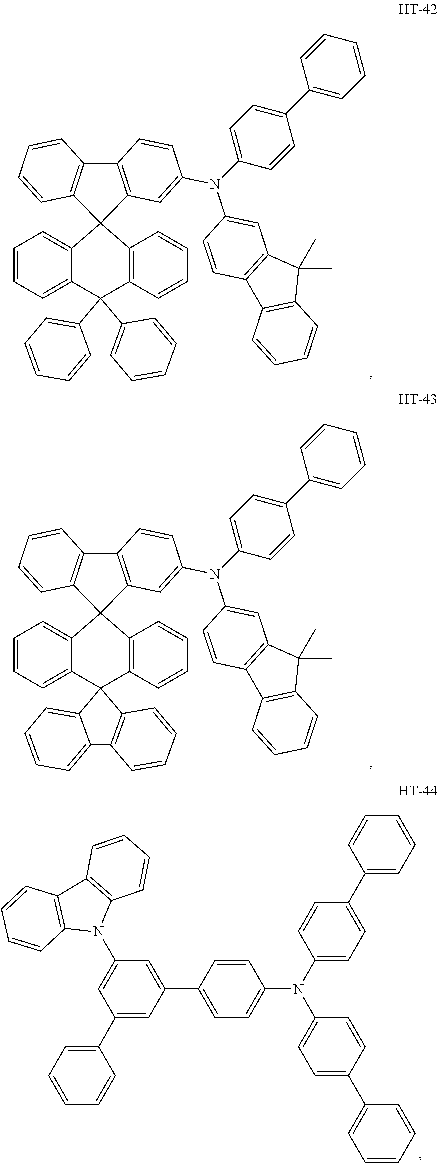 [SMILES: CC1(C)c2ccccc2-c2ccc(N(c3ccc(-c4ccccc4)cc3)c3ccc4c(c3)C3(c5ccccc5-4)c4ccccc4C(c4ccccc4)(c4ccccc4)c4ccccc43)cc21 ; CC1(C)c2ccccc2-c2ccc(N(c3ccc(-c4ccccc4)cc3)c3ccc4c(c3)C3(c5ccccc5-4)c4ccccc4C4(c5ccccc5-c5ccccc54)c4ccccc43)cc21 ; c1ccc(-c2ccc(N(c3ccc(-c4ccccc4)cc3)c3ccc(-c4cc(-c5ccccc5)cc(-n5c6ccccc6c6ccccc65)c4)cc3)cc2)cc1]

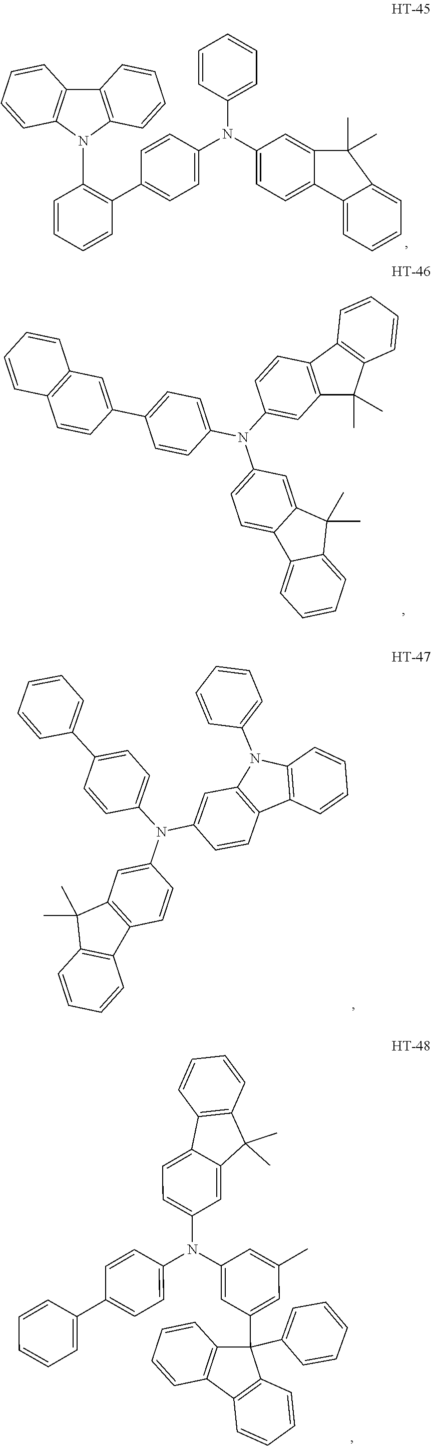

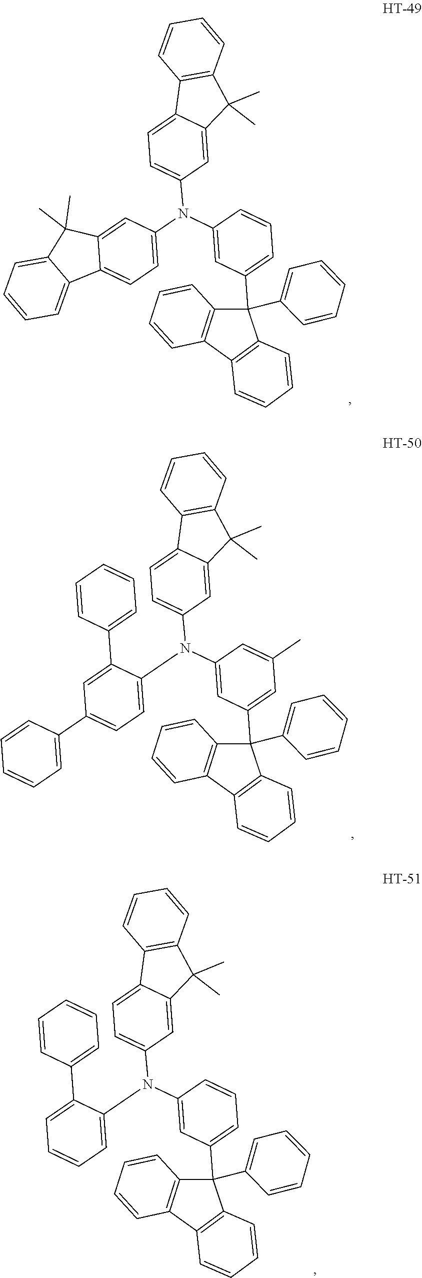 [SMILES: CC1(C)c2ccccc2-c2ccc(N(c3cccc(C4(c5ccccc5)c5ccccc5-c5ccccc54)c3)c3ccc4c(c3)C(C)(C)c3ccccc3-4)cc21 ; Cc1cc(N(c2ccc3c(c2)C(C)(C)c2ccccc2-3)c2ccc(-c3ccccc3)cc2-c2ccccc2)cc(C2(c3ccccc3)c3ccccc3-c3ccccc32)c1 ; CC1(C)c2ccccc2-c2ccc(N(c3cccc(C4(c5ccccc5)c5ccccc5-c5ccccc54)c3)c3ccccc3-c3ccccc3)cc21]

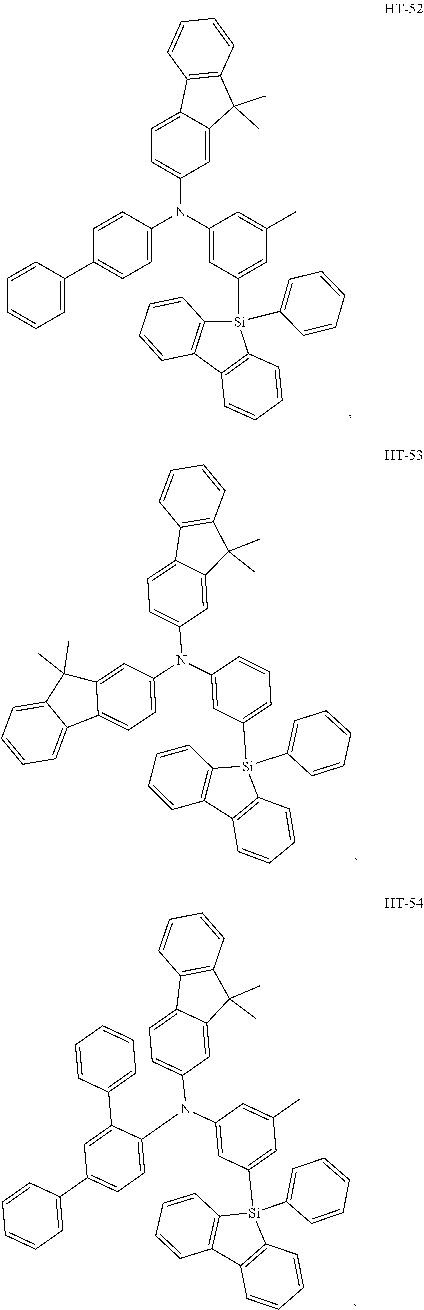 [SMILES: Cc1cc(N(c2ccc(-c3ccccc3)cc2)c2ccc3c(c2)C(C)(C)c2ccccc2-3)cc([Si]2(c3ccccc3)c3ccccc3-c3ccccc32)c1 ; CC1(C)c2ccccc2-c2ccc(N(c3cccc([Si]4(c5ccccc5)c5ccccc5-c5ccccc54)c3)c3ccc4c(c3)C(C)(C)c3ccccc3-4)cc21 ; Cc1cc(N(c2ccc3c(c2)C(C)(C)c2ccccc2-3)c2ccc(-c3ccccc3)cc2-c2ccccc2)cc([Si]2(c3ccccc3)c3ccccc3-c3ccccc32)c1]

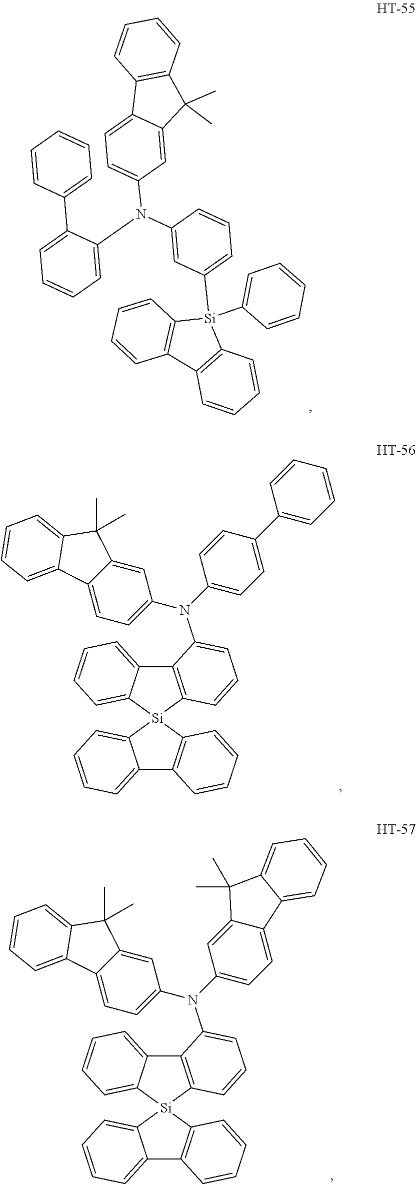 [SMILES: CC1(C)c2ccccc2-c2ccc(N(c3cccc([Si]4(c5ccccc5)c5ccccc5-c5ccccc54)c3)c3ccccc3-c3ccccc3)cc21 ; CC1(C)c2ccccc2-c2ccc(N(c3ccc(-c4ccccc4)cc3)c3cccc4c3-c3ccccc3[Si]43c4ccccc4-c4ccccc43)cc21 ; CC1(C)c2ccccc2-c2ccc(N(c3ccc4c(c3)C(C)(C)c3ccccc3-4)c3cccc4c3-c3ccccc3[Si]43c4ccccc4-c4ccccc43)cc21]

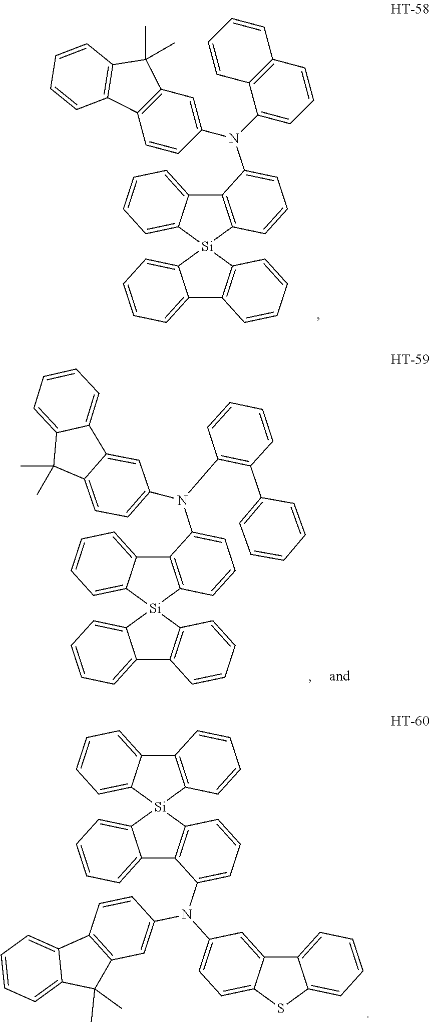 [SMILES: CC1(C)c2ccccc2-c2ccc(N(c3cccc4c3-c3ccccc3[Si]43c4ccccc4-c4ccccc43)c3cccc4ccccc34)cc21 ; CC1(C)c2ccccc2-c2cc(N(c3ccccc3-c3ccccc3)c3cccc4c3-c3ccccc3[Si]43c4ccccc4-c4ccccc43)ccc21 ; CC1(C)c2ccccc2-c2ccc(N(c3ccc4sc5ccccc5c4c3)c3cccc4c3-c3ccccc3[Si]43c4ccccc4-c4ccccc43)cc21]

According to an embodiment of the present disclosure, hydrogen in the structures of Compound HT-1 to Compound HT-60 can be partially or fully substituted with deuterium.

According to an embodiment of the present disclosure, a method for testing the lateral conductivity B_{A} of the common p-type charge generation layer is as follows: depositing the first organic material and the second organic material on a test substrate prepared with an aluminum electrode in advance at a certain mass ratio through co-deposition at a vacuum degree of about 10⁻⁶ Torr, forming a to-be-tested region with a thickness of 100 nm, a length of 6 mm and a width of 1 mm, obtaining an electric resistance value of the region through a method of applying a voltage to the electrode and measuring a current at room temperature, and calculating the lateral conductivity B_{A} of the layer according to Ohm's law and a geometric dimension.

According to an embodiment of the present disclosure, the lateral conductivity of the common p-type charge generation layer is B_{A}, and 0.2×10⁻⁴ S/m<B_{A}<20×10⁻⁴ S/m.

According to an embodiment of the present disclosure, the lateral conductivity of the common p-type charge generation layer is B_{A}, and 0.3×10⁻⁴ S/m<B_{A}<20×10⁻⁴ S/m.

According to an embodiment of the present disclosure, the lateral conductivity of the common p-type charge generation layer is B_{A}, and 0.4×10⁻⁴ S/m<B_{A}<20×10⁻⁴ S/m.

According to an embodiment of the present disclosure, the lateral conductivity of the common p-type charge generation layer is B_{A}, and 0.5×10⁻⁴ S/m<B_{A}<20×10⁻⁴ S/m.

According to an embodiment of the present disclosure, the lateral conductivity of the common p-type charge generation layer is B_{A}, and 0.2×10⁻⁴ S/m<B_{A}<18×10⁻⁴ S/m.

According to an embodiment of the present disclosure, the lateral conductivity of the common p-type charge generation layer is B_{A}, and 0.2×10⁻⁴ S/m<B_{A}<16×10⁻⁴ S/m.

According to an embodiment of the present disclosure, the lateral conductivity of the common p-type charge generation layer is B_{A}, and 0.2×10⁻⁴ S/m<B_{A}<14×10⁻⁴ S/m.

According to an embodiment of the present disclosure, the lateral conductivity of the common p-type charge generation layer is B_{A}, and 0.2×10⁻⁴ S/m<B_{A}<12×10⁻⁴ S/m.

According to an embodiment of the present disclosure, the lateral conductivity of the common p-type charge generation layer is B_{A}, and 0.2×10⁻⁴ S/m<B_{A}<10×10⁻⁴ S/m.

According to an embodiment of the present disclosure, −0.05 eV≤LUMO_{first_organic_material}−HOMO_{second_organic_material}<0.20 eV.

According to an embodiment of the present disclosure, 0 eV≤LUMO_{first_organic_material}−HOMO_{second_organic_material}<0.20 eV.

According to an embodiment of the present disclosure, 0.02 eV≤LUMO_{first_organic_material}−HOMO_{second_organic_material}<0.20 eV.

According to an embodiment of the present disclosure, 0.04 eV≤LUMO_{first_organic_material}−HOMO_{second_organic_material}<0.20 eV.

According to an embodiment of the present disclosure, 0.06 eV≤LUMO_{first_organic_material}−HOMO_{second_organic_material}<0.20 eV.

According to an embodiment of the present disclosure, 0.08 eV≤LUMO_{first_organic_material}−HOMO_{second_organic_material}<0.20 eV.

According to an embodiment of the present disclosure, 0.10 eV≤LUMO_{first_organic_material}−HOMO_{second_organic_material}<0.20 eV.

According to an embodiment of the present disclosure, 0 eV≤LUMO_{first_organic_material}−HOMO_{second_organic_material}<0.18 eV.

According to an embodiment of the present disclosure, 0 eV≤LUMO_{first_organic_material}−HOMO_{second_organic_material}<0.15 eV.

According to an embodiment of the present disclosure, the mass doping proportion of the first organic material in the common p-type charge generation layer is A %, and 6≤A≤19.

According to an embodiment of the present disclosure, the mass doping proportion of the first organic material in the common p-type charge generation layer is A %, and 6≤A≤18.

According to an embodiment of the present disclosure, the mass doping proportion of the first organic material in the common p-type charge generation layer is A %, and 7≤A≤18.

According to an embodiment of the present disclosure, the mass doping proportion of the first organic material in the common p-type charge generation layer is A %, and 7≤A≤15.

According to an embodiment of the present disclosure, the mass doping proportion of the first organic material in the common p-type charge generation layer is A %, and 7≤A≤12.

According to an embodiment of the present disclosure, the mass doping proportion of the first organic material in the common p-type charge generation layer is A %, and 12≤A≤20.

According to an embodiment of the present disclosure, the mass doping proportion of the first organic material in the common p-type charge generation layer is A %, and 12≤A≤18.

According to an embodiment of the present disclosure, the lateral conductivity per unit doping of the common p-type charge generation layer is σ_{A}, wherein σ_{A}=B_{A}/A, and at least one σ_{A} satisfies 0.06×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least one σ_{A} satisfies 0.07×10⁻⁴ S/m≤σA≤1×10⁻⁴ S/m.

According to an embodiment of the present disclosure, the lateral conductivity per unit doping of the common p-type charge generation layer is σ_{A}, wherein σ_{A}=B_{A}/A, and at least one σ_{A} satisfies 0.08×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least one σ_{A} satisfies 0.09×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least one σ_{A} satisfies 0.10×10⁻⁴ S/m≤σ_{A}<1×10⁻⁴ S/m.

According to an embodiment of the present disclosure, the lateral conductivity per unit doping of the common p-type charge generation layer is JA, wherein σ_{A}=B_{A}/A, and at least two σ_{A} satisfy 0.05×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least two σ_{A} satisfy 0.06×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least two σ_{A} satisfy 0.07×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least two σ_{A} satisfy 0.08×10⁻⁴ S/m≤σA≤1×10⁻⁴ S/m.

According to an embodiment of the present disclosure, the lateral conductivity per unit doping of the common p-type charge generation layer is σ_{A}, wherein σ_{A}=B_{A}/A, and at least two σ_{A} satisfy 0.09×10⁻⁴ S/m≤σ_{A}<1×10⁻⁴ S/m.

According to an embodiment of the present disclosure, the lateral conductivity per unit doping of the common p-type charge generation layer is σ_{A}, wherein σ_{A}=B_{A}/A, and at least two σ_{A} satisfy 0.10×10⁻⁴ S/m≤σ_{A}1×10⁻⁴ S/m.

According to an embodiment of the present disclosure, the lateral conductivity per unit doping of the common p-type charge generation layer is σ_{A}, wherein σ_{A}=B_{A}/A, and at least three σ_{A} satisfy 0.05×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least three σ_{A} satisfy 0.06×10⁻⁴ S/m≤σ_{A}≤1×10⁻⁴ S/m.

According to an embodiment of the present disclosure, the lateral conductivity per unit doping of the common p-type charge generation layer is JA, wherein σ_{A}=B_{A}/A, and at least three σ_{A} satisfy 0.07×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least three σ_{A} satisfy 0.08×10⁻⁴ S/m≤σ_{A}≤1×10⁻⁴ S/m.

According to an embodiment of the present disclosure, the lateral conductivity per unit doping of the common p-type charge generation layer is JA, wherein σ_{A}=B_{A}/A, and at least three σ_{A} satisfy 0.09×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least three σ_{A} satisfy 0.10×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₅ and σ₁₈ all satisfy 0.05×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₅ and σ₁₈ all satisfy 0.06×10⁻⁴ S/m≤σ_{A}≤1×10⁻⁴ S/m.

According to an embodiment of the present disclosure, the lateral conductivity per unit doping of the common p-type charge generation layer is JA, wherein σ_{A}=B_{A}/A, and at least σ₁₂, σ₁₅ and σ₁₈ all satisfy 0.07×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₅ and σ₁₈ all satisfy 0.08×10⁻⁴ S/m≤σ_{A}≤1×10⁻⁴ S/m.

According to an embodiment of the present disclosure, the lateral conductivity per unit doping of the common p-type charge generation layer is JA, wherein σ_{A}=B_{A}/A, and at least σ₁₂, σ₁₅ and σ₁₈ all satisfy 0.09×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₅ and σ₁₈ all satisfy 0.10×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₅ and σ₁₈ all satisfy 0.05×10⁻⁴ S/m≤σ_{A}≤0.9×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₅ and σ₁₈ all satisfy 0.05×10⁻⁴ S/m≤σ_{A}≤0.8×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₅ and σ₁₈ all satisfy 0.05×10⁻⁴ S/m≤σ_{A}≤0.7×10⁻⁴ S/m.

According to an embodiment of the present disclosure, the lateral conductivity per unit doping of the common p-type charge generation layer is σ_{A}, wherein σ_{A}=B_{A}/A, and at least five σ_{A} satisfy 0.05×10⁻⁴ S/m≤σ_{A}≤1×10⁻⁴ S/m.

According to an embodiment of the present disclosure, the lateral conductivity per unit doping of the common p-type charge generation layer is JA, wherein σ_{A}=B_{A}/A, and at least five σ_{A} satisfy 0.06×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least five σ_{A} satisfy 0.07×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least five σ_{A} satisfy 0.08×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least five σ_{A} satisfy 0.09×10⁻⁴ S/m≤σ_{A}≤1×10⁻⁴ S/m.

According to an embodiment of the present disclosure, the lateral conductivity per unit doping of the common p-type charge generation layer is JA, wherein σ_{A}=B_{A}/A, and at least five σ_{A} satisfy 0.10×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₄, σ₁₅, σ₁₆ and σ₁₈ all satisfy 0.05×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₄, σ₁₅, σ₁₆ and 018 all satisfy 0.06×10⁻⁴ S/m<<<1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₄, σ₁₅, σ₁₆ and σ₁₈ all satisfy 0.07×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₄, σ₁₅, σ₁₆ and σ₁₈ all satisfy 0.08×10⁻⁴ S/m≤σ_{A}≤1×10⁻⁴ S/m.

According to an embodiment of the present disclosure, the lateral conductivity per unit doping of the common p-type charge generation layer is JA, wherein σ_{A}=B_{A}/A, and at least σ₁₂, σ₁₄, σ₁₅, σ₁₆ and σ₁₈ all satisfy 0.09×10⁻⁴ S/m≤σA≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₄, σ₁₅, σ₁₆ and σ₁₈ all satisfy 0.10×10⁻⁴ S/m≤σ_{A}≤1×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₄, σ₁₅, σ₁₆ and σ₁₈ all satisfy 0.05×10⁻⁴ S/m<<0.9×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₄, σ₁₅, σ₁₆ and σ₁₈ all satisfy 0.05×10⁻⁴ S/m<<<0.8×10⁻⁴ S/m.

According to an embodiment of the present disclosure, the lateral conductivity per unit doping of the common p-type charge generation layer is σ_{A}, wherein σ_{A}=B_{A}/A, and at least σ₁₂, σ₁₅ and σ₁₈ all satisfy 0.05×10⁻⁴ S/m<<<0.7×10⁻⁴ S/m.

According to an embodiment of the present disclosure, the lateral conductivity per unit doping of the common p-type charge generation layer is JA, wherein σ_{A}=B_{A}/A, and all σ_{A} satisfy 0.05×10⁻⁴ S/m≤σ_{A}≤1×10⁻⁴ S/m, 0.06×10⁻⁴ S/m≤σ_{A}≤1×10⁻⁴ S/m, 0.07×10⁻⁴ S/m≤σ_{A}≤1×10⁻⁴ S/m, 0.08×10⁻⁴ S/m≤σ_{A}≤1×10⁻⁴ S/m, 0.09×10⁻⁴ S/m≤σ_{A}≤1×10⁻⁴ S/m, 0.10×10⁻⁴ S/m<<<1×10⁻⁴ S/m, 0.05×10⁻⁴ S/m≤σA≤0.9×10⁻⁴ S/m, 0.05×10⁻⁴ S/m<<<0.8×10⁻⁴ S/m, 0.05×10⁻⁴ S/m≤σ_{A}≤0.7×10⁻⁴ S/m, 0.05×10⁻⁴ S/m≤σ_{A}≤0.6×10⁻⁴ S/m or 0.05×10⁻⁴ S/m≤σ_{A}≤0.5×10⁻⁴ S/m.

According to an embodiment of the present disclosure, −5.30 eV≤LUMO_{first_organic_material}≤−4.80 eV.

According to an embodiment of the present disclosure, −5.25 eV≤LUMO_{first_organic_material}≤−4.85 eV.

According to an embodiment of the present disclosure, −5.20 eV≤LUMO_{first_organic_material}≤−4.90 eV.

According to an embodiment of the present disclosure, −5.18 eV≤LUMO_{first_organic_material}≤−4.95 eV.

According to an embodiment of the present disclosure, −5.16 eV≤LUMO_{first_organic_material}≤−4.80 eV.

According to an embodiment of the present disclosure, −5.15 eV≤LUMO_{first_organic_material}≤−4.80 eV.

According to an embodiment of the present disclosure, −5.14 eV≤LUMO_{first_organic_material}≤−4.80 eV.

According to an embodiment of the present disclosure, −5.13 eV≤LUMO_{first_organic_material}≤−4.80 eV.

According to an embodiment of the present disclosure, −5.12 eV≤LUMO_{first_organic_material}≤−4.80 eV.

According to an embodiment of the present disclosure, −5.11 eV≤LUMO_{first_organic_material}≤−4.80 eV.

According to an embodiment of the present disclosure, −5.10 eV≤LUMO_{first_organic_material}≤−4.80 eV.

According to an embodiment of the present disclosure, −5.15 eV≤LUMO_{first_organic_material}≤−4.90 eV.

According to an embodiment of the present disclosure, −5.15 eV≤LUMO_{first_organic_material}≤−4.95 eV.

According to an embodiment of the present disclosure, −5.35 eV≤HOMO_{second_organic_material}≤−5.00 eV.

According to an embodiment of the present disclosure, −5.33 eV≤HOMO_{second_organic_material}≤−5.00 eV.

According to an embodiment of the present disclosure, −5.31 eV≤HOMO_{second_organic_material}≤−5.00 eV.

According to an embodiment of the present disclosure, −5.29 eV≤HOMO_{second_organic_material}≤−5.00 eV.

According to an embodiment of the present disclosure, −5.28 eV≤

HOMO_{second_organic_material}≤−5.00 eV.

According to an embodiment of the present disclosure, −5.25 eV≤HOMO_{second_organic_material}≤−5.00 eV.

According to an embodiment of the present disclosure, −5.24 eV≤HOMO_{second_organic_material}≤−5.00 eV.

According to an embodiment of the present disclosure, −5.23 eV≤HOMO_{second_organic_material}≤−5.00 eV.

According to an embodiment of the present disclosure, −5.22 eV≤HOMO_{second_organic_material}≤−5.00 eV.

According to an embodiment of the present disclosure, −5.21 eV≤HOMO_{second_organic_material}≤−5.00 eV.

According to an embodiment of the present disclosure, −5.30 eV≤HOMO_{second_organic_material}≤−5.02 eV.

According to an embodiment of the present disclosure, −5.30 eV≤HOMO_{second_organic_material}≤−5.04 eV.

According to an embodiment of the present disclosure, −5.30 eV≤HOMO_{second_organic_material}≤−5.06 eV.

According to an embodiment of the present disclosure, −5.30 eV≤HOMO_{second_organic_material}≤−5.08 eV.

According to an embodiment of the present disclosure, −5.30 eV≤HOMO_{second_organic_material}≤−5.10 eV.

According to an embodiment of the present disclosure, the light-emitting units comprise a common second organic layer disposed between the common p-type charge generation layer and the cathode.

According to an embodiment of the present disclosure, the common second organic layer is in direct contact with the common p-type charge generation layer.

According to an embodiment of the present disclosure, the common second organic layer is a hole injection layer or a hole transport layer.

According to an embodiment of the present disclosure, the common second organic layer has a thickness of greater than or equal to 20 nm, a thickness of greater than or equal to 30 nm, a thickness of greater than or equal to 40 nm, a thickness of greater than or equal to 50 nm, a thickness of greater than or equal to 60 nm, a thickness of greater than or equal to 70 nm, a thickness of greater than or equal to 80 nm, a thickness of greater than or equal to 90 nm or a thickness of greater than or equal to 100 nm.

According to an embodiment of the present disclosure, the common second organic layer comprises a third organic material.

According to an embodiment of the present disclosure, the third organic material is the same as or different from the second organic material.

According to an embodiment of the present disclosure, the third organic material is the same as the second organic material.

According to an embodiment of the present disclosure, the light-emitting units comprise a common third organic layer disposed between the common p-type charge generation layer and the anode.

According to an embodiment of the present disclosure, the common third organic layer is in direct contact with the anode.

According to an embodiment of the present disclosure, the common third organic layer is a hole injection layer.

According to an embodiment of the present disclosure, the common third organic layer comprises at least one p-type conductive dopant and at least one hole transport material.

According to an embodiment of the present disclosure, the p-type conductive dopant is the same as or different from the first organic material.

According to an embodiment of the present disclosure, the p-type conductive dopant is the same as the first organic material.

According to an embodiment of the present disclosure, the hole transport material is the same as or different from the second organic material.

According to an embodiment of the present disclosure, the hole transport material is the same as the second organic material.

According to an embodiment of the present disclosure, the common third organic layer has a thickness of greater than or equal to 2 nm.

According to an embodiment of the present disclosure, the common third organic layer has a thickness of greater than or equal to 5 nm.

According to an embodiment of the present disclosure, at a constant current density of 10 mA/cm², the stacked organic electroluminescent device has a voltage of less than or equal to 8.6 V, a voltage of less than or equal to 8.4 V, a voltage of less than or equal to 8.2 V, a voltage of less than or equal to 8.0 V, a voltage of less than or equal to 7.8 V, a voltage of less than or equal to 7.6 V, a voltage of less than or equal to 7.4 V, a voltage of less than or equal to 7.2 V, a voltage of less than or equal to 7.0 V, a voltage of less than or equal to 6.8 V, a voltage of less than or equal to 6.6 V, a voltage of less than or equal to 6.4 V, a voltage of less than or equal to 6.3 V, a voltage of less than or equal to 6.2 V, a voltage of less than or equal to 6.1 V, a voltage of less than or equal to 6.0 V, a voltage of less than or equal to 5.9 V, a voltage of less than or equal to 5.8 V, a voltage of less than or equal to 5.7 V, a voltage of less than or equal to 5.6 V, a voltage of less than or equal to 5.5 V, a voltage of less than or equal to 5.4 V, a voltage of less than or equal to 5.3 V or a voltage of less than or equal to 5.2 V.

According to an embodiment of the present disclosure, the common p-type charge generation layer is shared by all pixels.

According to an embodiment of the present disclosure, a common n-type charge generation layer is comprised between the two adjacent light-emitting units.

According to an embodiment of the present disclosure, the common n-type charge generation layer comprises at least one metal, and the metal is selected from Yb, Li, Na, K, Zn, Cs, Mg, Ca, Sr, Ba, Sm, Eu or a combination thereof.

According to an embodiment of the present disclosure, the metal is selected from Yb, Li or a combination thereof.

According to an embodiment of the present disclosure, the common n-type charge generation layer comprises at least one electron transporting material, and the electron transporting material comprises at least one substituted or unsubstituted heteroaryl having 3 to 30 carbon atoms.

According to an embodiment of the present disclosure, the electron transporting material comprises any one or more chemical structural units selected from the group consisting of: pyridine, pyrimidine, triazine, imidazole, carbazole, a cyano group, acridine, azine, a phosphoroso group, sulfone, sulfoxide, benzoxazole, quinone, benzoquinone, quinoxaline, benzoquinoxaline, phenanthroline and benzacridine.

According to an embodiment of the present disclosure, the common n-type charge generation layer comprises at least one electron transporting material and at least one metal.

According to an embodiment of the present disclosure, the stacked organic electroluminescent device comprises at least three light-emitting units disposed between the anode and the cathode, and each light-emitting unit includes at least one light-emitting layer.

According to an embodiment of the present disclosure, the stacked organic electroluminescent device comprises at least four light-emitting units disposed between the anode and the cathode, and each light-emitting unit includes at least one light-emitting layer.

According to an embodiment of the present disclosure, the plurality of pixels can emit light of the same color or light of different colors.

According to an embodiment of the present disclosure, further disclosed is an electronic device comprising the active-matrix organic electroluminescent display in the preceding embodiment.

Combination with Other Materials

The materials described in the present disclosure for a particular layer in an organic light emitting device can be used in combination with various other materials present in the device. The combinations of these materials are described in more detail in U.S. patent application No. 20160359122 at paragraphs 0132-0161, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The materials described herein as useful for a particular layer in an organic light emitting device may be used in combination with a variety of other materials present in the device. For example, compounds disclosed herein may be used in combination with a wide variety of light-emitting dopants, hosts, transporting layers, blocking layers, injection layers, electrodes, and other layers that may be present. The combination of these materials is described in detail in paragraphs 0080-0101 of U.S. patent application No. 20150349273, which is incorporated by reference herein in its entirety. The materials described or referred to the disclosure are non-limiting examples of materials that may be useful in combination with the compounds disclosed herein, and one of skill in the art can readily consult the literature to identify other materials that may be useful in combination.

The preparation method of an organic electroluminescent device is not limited. In the embodiments of the device, the characteristics of the device were also tested using conventional equipment in the art (including, but not limited to, evaporator produced by ANGSTROM ENGINEERING, optical testing system produced by SUZHOU FSTAR, lifetime testing system produced by SUZHOU FSTAR, and ellipsometer produced by BEIJING ELLITOP, etc.) by methods well known to the persons skilled in the art. As the persons skilled in the art are aware of the above-mentioned equipment use, test methods, and other related contents, the inherent data of the sample can be obtained with certainty and without influence, so the above related contents are not further described in this patent.

Preparation methods in the following device examples are only examples and not to be construed as limiting. Those skilled in the art can make reasonable improvements on the preparation methods in the following device examples based on the related art.

The LUMO energy levels and HOMO energy levels of the organic materials obtained herein were measured through cyclic voltammetry (CV). The test through cyclic voltammetry (CV) was conducted using an electrochemical workstation CorrTest CS120 produced by Wuhan Corrtest Instruments Corp., Ltd and using a three-electrode working system where a platinum disk electrode served as a working electrode, a Ag/AgNO₃ electrode served as a reference electrode, and a platinum wire electrode served as an auxiliary electrode. Anhydrous DCM is used as a solvent, 0.1 mol/L tetrabutylammonium hexafluorophosphate is used as a supporting electrolyte, a compound to be tested is prepared into a solution of 103 mol/L, and nitrogen is introduced into the solution for 10 min for oxygen removal before the test. The parameters of the instrument are set as follows: a scan rate of 100 mV/s, a potential interval of 0.5 mV, and a test window of −1 V to 1 V.

Herein, a method for testing the lateral conductivity per unit doping of the common p-type charge generation layer is as follows: depositing the first organic material and the second organic material on a test substrate prepared with an aluminum electrode in advance at a certain mass ratio through co-deposition at a vacuum degree of about 10 6 Torr, forming a to-be-tested region with a thickness of 100 nm, a length of 6 mm and a width of 1 mm, obtaining an electric resistance value of the region through a method of applying a voltage to the electrode and measuring a current at room temperature, calculating the lateral conductivity B_{A} of the layer according to Ohm's law and a geometric dimension, and calculating the lateral conductivity per unit doping σ_{A} of the common p-type charge generation layer according to σ_{A}=B_{A}/A.

Table 1 shows LUMO energy levels of some first organic materials and HOMO energy levels of some second organic materials that were measured through the above method, energy level differences between the LUMO energy levels of the first organic materials and the HOMO energy levels of the second organic materials and lateral conductivities per unit doping σ_{A} of common p-type charge generation layers formed by combinations of different first organic materials at their mass doping proportions (A %) as recorded and different second organic materials (the layer structure represents first organic material: second organic material).

TABLE 1
Layer structures, material energy levels and lateral conductivities per unit doping

| | | | | | | Lateral |
|---|---|---|---|---|---|---|
| | | | | | Doping | conductivity |
| | | | | LUMO_{first}_{_{—}}_{organic}_{_{—}}ₘₐₜₑᵣᵢₐₗ − | Proportion | per unit |
| Layer | Layer | LUMO_{first}_{_{—}}_{organic}_{_{—}}ₘₐₜₑᵣᵢₐₗ | HOMO_{second}_{_{—}}_{organic}_{_{—}}ₘₐₜₑᵣᵢₐₗ | HOMO_{second}_{_{—}}_{organic}_{_{—}}ₘₐₜₑᵣᵢₐₗ | A | doping σ_{A} |
| No. | Structure | (eV) | (eV) | (eV) | (wt. %) | (10⁻⁴ S/m) |
| Example | 1-20:HT-11 | −5.07 | −5.13 | 0.06 | 18 | 0.39 |
| layer 1 | | | | | | |
| Example | | | | | 15 | 0.25 |
| layer 2 | | | | | | |
| Example | | | | | 12 | 0.18 |
| layer 3 | | | | | | |
| Comparative | | | | | 4 | 0.04 |
| layer 3 | | | | | | |
| Example | 1-24:HT-11 | −5.07 | −5.13 | 0.06 | 15 | 0.93 |
| layer 4 | | | | | | |
| Example | | | | | 12 | 0.72 |
| layer 5 | | | | | | |
| Example | 1-28:HT-13 | −5.09 | −5.24 | 0.15 | 15 | 0.08 |
| layer 6 | | | | | | |
| Example | 2-23:HT-11 | −4.99 | −5.13 | 0.14 | 16 | 0.75 |
| layer 7 | | | | | | |
| Example | | | | | 14 | 0.62 |
| layer 8 | | | | | | |
| Example | | | | | 12 | 0.65 |
| layer 9 | | | | | | |
| Comparative | 4-1:HT-A | −5.04 | −5.26 | 0.22 | 10 | 0.27 |
| layer 1 | | | | | | |
| Comparative | 4-1:HT-11 | −5.04 | −5.13 | 0.09 | 10 | 4.6 |
| layer 2 | | | | | | |

The materials used in the common p-type charge generation layers have the following structures:

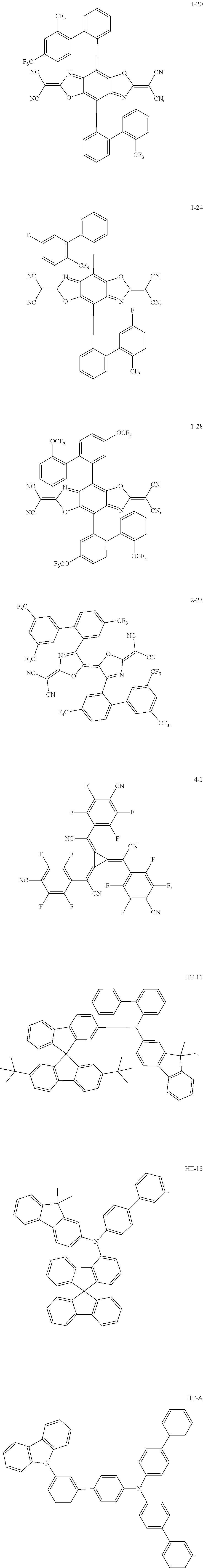

Table 1 shows the lateral conductivities per unit doping σ_{A} of different common p-type charge generation layers. The numerical values can reflect hole transport abilities of the materials in the layers. As can be seen from the data in Table 1, when the first organic material has a particular high mass doping proportion, each of the Example Layers 1 to 9 has a particular low lateral conductivity per unit doping. This ensures a sufficient number of holes in the common p-type charge generation layer and sufficient hole injection. Moreover, the holes can be controlled not to be accumulated excessively, the hole density is at an appropriate low level, and the lateral migration amount of the holes is at a relatively low level. Apparently, the holes can be inhibited from laterally migrating from one pixel to other pixels via the common p-type charge generation layer, thereby significantly inhibiting the lateral crosstalk between pixels in the display. Further verification was performed through a crosstalk test.

### Device Example 1 of Crosstalk Test

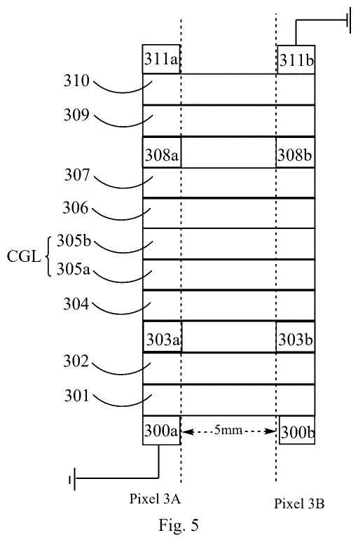

As shown in FIG. 5, a glass substrate having a thickness of 0.7 mm, on which two anodes 300a and 300b (ITO (75 Å)/Ag (1500 Å)/ITO (150 Å)) with a thickness of 1725 Å had been patterned, was washed with deionized water and detergent, and then the anode surfaces were treated with oxygen plasma and UV ozone. The substrate was dried in a glovebox to remove moisture, mounted on a support, and transferred into a vacuum chamber. Organic layers specified below were sequentially evaporated through vacuum thermal evaporation on the anode layers at a rate of 0.1 to 10 Angstroms per second and a vacuum degree of about 10 6 torr. First, a first light-emitting unit was evaporated, which includes: evaporating Compound HT-11 as a hole transport layer 301 (HTL, 400 Å), evaporating Compound HT-54 as an electron blocking layer 302 (EBL, 50 Å), evaporating Compound RH-1 and Compound RD-1 to form two mutually independent red emissive layers 303a and 303b (EMLs, at a weight ratio of 98:2, 400 Å), co-depositing Compound ET-1 and Liq as an electron transport layer 304 (ETL, at a weight ratio of 1:1, 150 Å), evaporating a metal Yb and Compound ET-2 as an n-type charge generation layer 305a (n-CGL, at a weight ratio of 1:99, 140 Å), and evaporating Compound 1-20 and Compound HT-11 as a p-type charge generation layer 305b (at a weight ratio of 15:85, 100 Å). Then, a second light-emitting unit was evaporated, which includes: evaporating Compound HT-11 as a hole transport layer 306 (HTL, 500 Å), evaporating Compound HT-54 as an electron blocking layer 307 (EBL, 700 Å), evaporating Compound RH-1 and Compound RD-1 to form two mutually independent red emissive layers 308a and 308b (EMLs, at a weight ratio of 98:2, 400 Å), co-depositing Compound ET-1 and Liq as an electron transport layer 309 (ETL, at a weight ratio of 1:1, 300 Å), evaporating Yb with a thickness of 10 Å as an electron injection layer 310 (EIL), evaporating a metal Mg and a metal Ag as cathodes 311a and 311b (at a weight ratio of 10:90, 120 Å), and finally evaporating a CPL material as a capping layer (CPL, 800 Å). Then, the device was transferred back to the glovebox and encapsulated with a glass lid to complete the device.

The CPL material is a capping layer material purchased from Jiangsu Sunera Technology Co., Ltd. with a refractive index nσ630 nm of 1.95. A method for measuring the refractive index of the CPL material is as follows: attaching a clean silicon wafer to a glass surface, treated with UV, mounted on a substrate support and placed into a vacuum chamber. The to-be-tested sample material was evaporated through vacuum thermal evaporation on the silicon wafer at a rate of 0.01 to 10 Å/s and a vacuum degree of about 106 torr to form a thin film with a thickness of 300 Å. Subsequently, the prepared sample film was placed on an ESNano spectroscopic ellipsometer manufactured by BEIJING ELLITOP SCIENTIFIC CO., LTD. for a refractive index (n) test with a wavelength range of 450-800 nm.

Device Comparative Example 1 of crosstalk test: the preparation method was the same as that in Device Example 1 of the crosstalk test, except that Compound 1-20 and Compound HT-11 were replaced with Compound 4-1 and Compound HT-11 as the common p-type charge generation layer, and the weight ratio of Compound 4-1 to Compound HT-11 was adjusted to 10:90.

The materials used in the devices have the following structures:

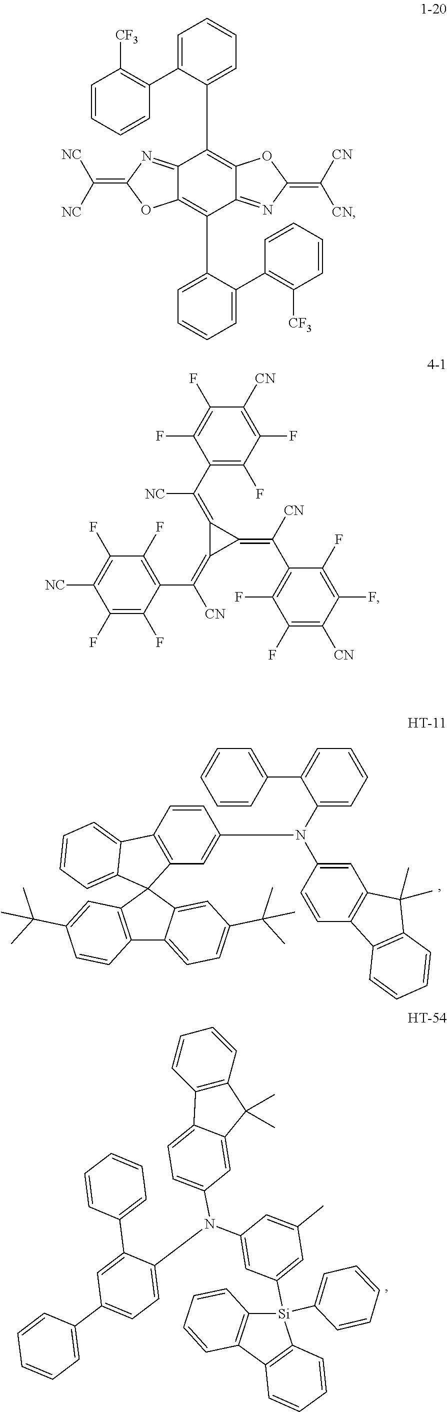

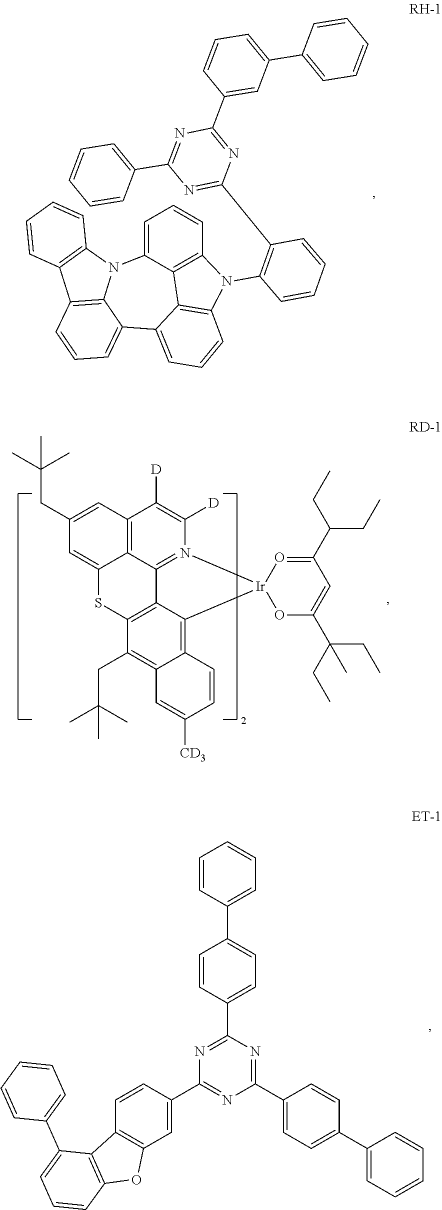

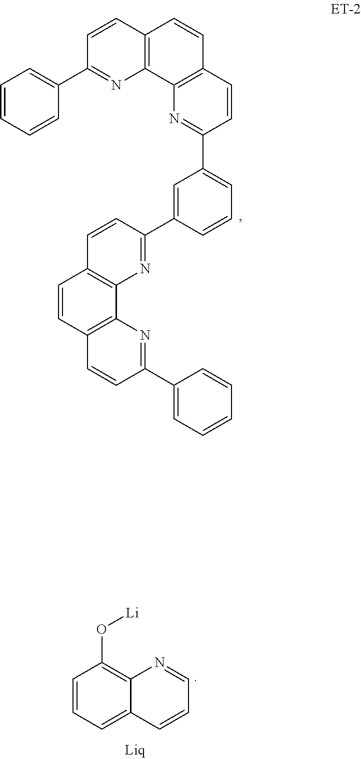

As shown in FIG. 5, the crosstalk test device comprises a pixel 3A and a pixel 3B. The anode 300a and the cathode 311b were electrically connected to a driving device, and the brightness (cd/m²) of the pixel 3B was tested at a constant voltage of 21 V. The data are recorded and shown in Table 2.

TABLE 2
Brightness of pixels 3B of Device Example 1 of the crosstalk
test and Device Comparative Example 1 of the crosstalk test

| | | Lateral | |
|---|---|---|---|
| | Common P-type | conductivity per | Bright- |
| | Charge Generation | unit doping σ_{A} | ness |
| Device No. | Layer (p-CGL) | (10⁻⁴ S/m) | (cd/m²) |
| Device Example 1 of | 1-20:HT-11 (15:85) | 0.25 | 0 |
| Crosstalk Test | (100 Å) | | |
| Device Comparative | 4-1:HT-11 (10:90) | 4.60 | 1.9 |
| Example 1 of | (100 Å) | | |
| Crosstalk Test | | | |

As can be seen from the data in Table 2, Device Example 1 of the crosstalk test differs from Device Comparative Example 1 of the crosstalk test only in that the common p-CGL shared by the pixel 3A and the pixel 3B is different. The common p-CGL shared by the pixel 3A and the pixel 3B in Device Example 1 of the crosstalk test has a low lateral conductivity per unit doping (0.25×10⁻⁴ S/m), and the brightness of the pixel 3B in Device Example 1 of the crosstalk test is measured to be 0 cd/m² at a constant voltage of 21 V, indicating that the lateral migration amount of holes in the common p-CGL of Device Example 1 of the crosstalk test is at a low level and the holes have difficulty in the migration from the pixel 3A to the pixel 3B via the common p-CGL. Therefore, the pixel point in Device Example 1 of the crosstalk test do not emit light, indicating that there is little or even no crosstalk between the two pixels. The mass doping proportion (10%) of the p-type conductive doping material in the common p-CGL of Device Comparative Example 1 of the crosstalk test is lower than the mass doping proportion (15%) of the p-type conductive doping material in the common p-CGL of Device Example 1 of the crosstalk test. However, the lateral conductivity per unit doping of the common p-CGL shared by the pixel 3A and the pixel 3B in Device Comparative Example 1 of the crosstalk test is higher (4.6×10⁻⁴ S/m). Under the same test conditions, the brightness of the pixel 3B in Device Comparative Example 1 of the crosstalk test is measured to be 1.9 cd/m². The pixel point emits light with relatively large brightness, indicating that the lateral crosstalk between the two pixels is relatively large. The above data analysis indicates that since the common p-CGL layer of the active-matrix stacked organic electroluminescent display of the present disclosure has a particular low lateral conductivity per unit doping, the lateral crosstalk between the pixels can be effectively inhibited.

In addition, since the common p-CGL in the active-matrix OLED display of the present disclosure comprises a first organic material and a second organic material that satisfy a particular energy level relationship and has a particular low lateral conductivity per unit doping, the device can obtain excellent device performance while the crosstalk between the pixels is inhibited. Device examples and device data are provided below for demonstration.

### Device Example

### Example 1

As shown in FIG. 3, a glass substrate having a thickness of 0.7 mm, on which two anodes 110 (ITO (75 Å)/Ag (1500 Å)/ITO (150 Å)) with a thickness of 1725 Å had been patterned, was washed with deionized water and detergent, and then the anode surfaces were treated with oxygen plasma and UV ozone. The substrate was dried in a glovebox to remove moisture, mounted on a support, and transferred into a vacuum chamber. Organic layers specified below were sequentially evaporated through vacuum thermal evaporation on the anode layers 110 at a rate of 0.1 to 10 Angstroms per second and a vacuum degree of about 10⁻⁶ torr. First, a first light-emitting unit 130a was evaporated, which includes: evaporating Compound 1-20 and Compound HT-11 as a hole injection layer 131a (HIL, at a weight ratio of 3:97, 100 Å), evaporating Compound HT-11 as a hole transport layer 132a (HTL, 300 Å), evaporating Compound HT-54 as an electron blocking layer 133a (EBL, 50 Å), evaporating Compound RH-1 and Compound RD-1 as a red emissive layer 134a (EML, at a weight ratio of 98:2, 400 Å), co-depositing Compound ET-1 and Liq as an electron transport layer 135a (ETL, at a weight ratio of 1:1, 150 Å), evaporating a metal Yb and Compound ET-2 as an n-type charge generation layer 140a (n-CGL, at a weight ratio of 1:99, 140 Å), and evaporating Compound 1-20 and Compound HT-11 as a p-type charge generation layer 140b (p-CGL, at a weight ratio of 18:82, 100 Å). Then, a second light-emitting unit 130b was evaporated, which includes: evaporating

Compound HT-11 as a hole transport layer 132b (HTL, 500 Å), evaporating Compound HT-54 as an electron blocking layer 133b (EBL, 700 Å), evaporating Compound RH-1 and Compound RD-1 as a red emissive layer 134b (EML, at a weight ratio of 98:2, 400 Å), co-depositing Compound ET-1 and Liq as an electron transport layer 135b (ETL, at a weight ratio of 1:1, 300 Å), evaporating Yb with a thickness of 10 Å as an electron injection layer 136b (EIL), evaporating a metal Mg and a metal Ag as a cathode 120 (at a weight ratio of 10:90, 120 Å), and finally evaporating a CPL material as a capping layer (CPL, 800 Å). Then, the device was transferred back to the glovebox and encapsulated with a glass lid to complete the device.

Example 2: the preparation method was the same as that in Example 1, except that the weight ratio of Compound 1-20 to Compound HT-11 in the p-type charge generation layer was adjusted to 15:85.

Example 3: the preparation method was the same as that in Example 1, except that the weight ratio of Compound 1-20 to Compound HT-11 in the p-type charge generation layer was adjusted to 12:88.

Example 4: the preparation method was the same as that in Example 2, except that Compound 1-20 and Compound HT-11 were replaced with Compound 1-24 and Compound HT-11 as the p-type charge generation layer.

Example 5: the preparation method was the same as that in Example 4, except that the weight ratio of Compound 1-24 to Compound HT-11 in the p-type charge generation layer was adjusted to 12:88.

Example 6: the preparation method was the same as that in Example 2, except that Compound 1-20 and Compound HT-11 were replaced with Compound 1-28 and Compound HT-13 as the p-type charge generation layer, and Compound HT-11 was replaced with Compound HT-13 as the hole transport layer 132b (HTL, 500 Å) of the second light-emitting unit.

Example 7: the preparation method was the same as that in Example 1, except that Compound 1-20 and Compound HT-11 were replaced with Compound 2-23 and Compound HT-11 as the p-type charge generation layer, and the weight ratio of Compound 2-23 to Compound HT-11 was adjusted to 16:84.

Example 8: the preparation method was the same as that in Example 7, except that the weight ratio of Compound 2-23 to Compound HT-11 in the p-type charge generation layer was adjusted to 14:86.

Example 9: the preparation method was the same as that in Example 7, except that the weight ratio of Compound 2-23 to Compound HT-11 in the p-type charge generation layer was adjusted to 12:88.

Comparative Example 1: the preparation method was the same as that in Example 1, except that Compound 1-20 and Compound HT-11 were replaced with Compound 4-1 and Compound HT-A as the p-type charge generation layer, the weight ratio of Compound 4-1 to Compound HT-A was adjusted to 10:90, and Compound HT-A was used as the hole transport layer 132b (HTL, 500 Å) of the second light-emitting unit.

Comparative Example 2: the preparation method was the same as that in Example 1, except that Compound 1-20 and Compound HT-11 were replaced with Compound 4-1 and Compound HT-11 as the p-type charge generation layer, and the weight ratio of Compound 4-1 to Compound HT-11 was adjusted to 10:90.

Comparative Example 3: the preparation method was the same as that in Example 1, except that the weight ratio of Compound 1-20 to Compound HT-11 was adjusted to 4:96.

The structures and thicknesses of some layers of the devices are shown in Table 3. A layer using more than one material is obtained by doping different compounds at their weight ratio as recorded.

TABLE 3
Part of device structures in Examples
1 and 9 and Comparative Examples 1 to 3

| Device | | HTL in Second Light- |
|---|---|---|
| No. | p-CGL | emitting Unit |
| Example 1 | Compound 1-20:Compound HT-11 | Compound HT-11 |
| | (18:82) (100 Å) | (500 Å) |
| Example 2 | Compound 1-20:Compound HT-11 | Compound HT-11 |
| | (15:85) (100 Å) | (500 Å) |
| Example 3 | Compound 1-20:Compound HT-11 | Compound HT-11 |
| | (12:88) (100 Å) | (500 Å) |
| Example 4 | Compound 1-24:Compound HT-11 | Compound HT-11 |
| | (15:85) (100 Å) | (500 Å) |
| Example 5 | Compound 1-24:Compound HT-11 | Compound HT-11 |
| | (12:88) (100 Å) | (500 Å) |
| Example 6 | Compound 1-28:Compound HT-13 | Compound HT-13 |
| | (15:85) (100 Å) | (500 Å) |
| Example 7 | Compound 2-23:Compound HT-11 | Compound HT-11 |
| | (16:84) (100 Å) | (500 Å) |
| Example 8 | Compound 2-23:Compound HT-11 | Compound HT-11 |
| | (14:86) (100 Å) | (500 Å) |
| Example 9 | Compound 2-23:Compound HT-11 | Compound HT-11 |
| | (12:88) (100 Å) | (500 Å) |
| Comparative | Compound 4-1:Compound HT-A | Compound HT-A |
| Example 1 | (10:90) (100 Å) | (500 Å) |
| Comparative | Compound 4-1:Compound HT-11 | Compound HT-11 |
| Example 2 | (10:90) (100 Å) | (500 Å) |
| Comparative | Compound 1-20:Compound HT-11 | Compound HT-11 |
| Example 3 | (4:96) (100 Å) | (500 Å) |

The materials used in the devices have the following structures:

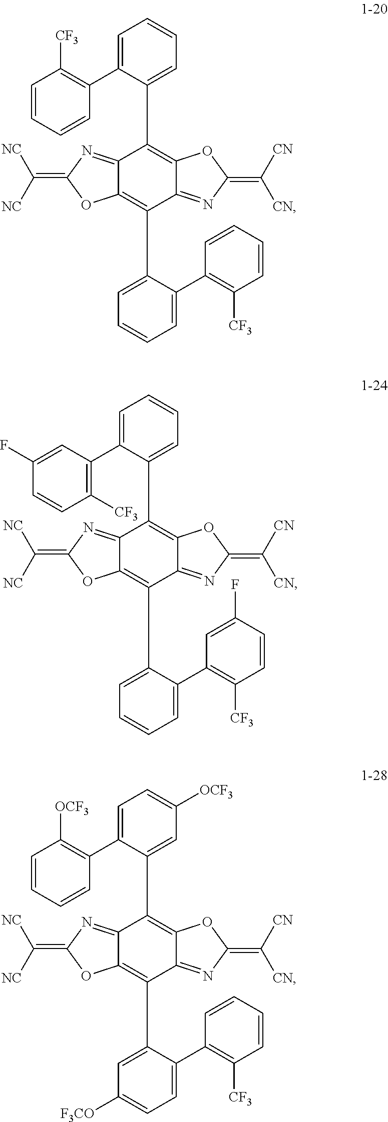 [SMILES: N#CC(C#N)=c1nc2c(-c3ccccc3-c3ccccc3C(F)(F)F)c3oc(=C(C#N)C#N)nc3c(-c3ccccc3-c3ccccc3C(F)(F)F)c2o1 ; N#CC(C#N)=c1nc2c(-c3ccccc3-c3cc(F)ccc3C(F)(F)F)c3oc(=C(C#N)C#N)nc3c(-c3ccccc3-c3cc(F)ccc3C(F)(F)F)c2o1 ; N#CC(C#N)=c1nc2c(-c3cc(OC(F)(F)F)ccc3-c3ccccc3C(F)(F)F)c3oc(=C(C#N)C#N)nc3c(-c3cc(OC(F)(F)F)ccc3-c3ccccc3OC(F)(F)F)c2o1]

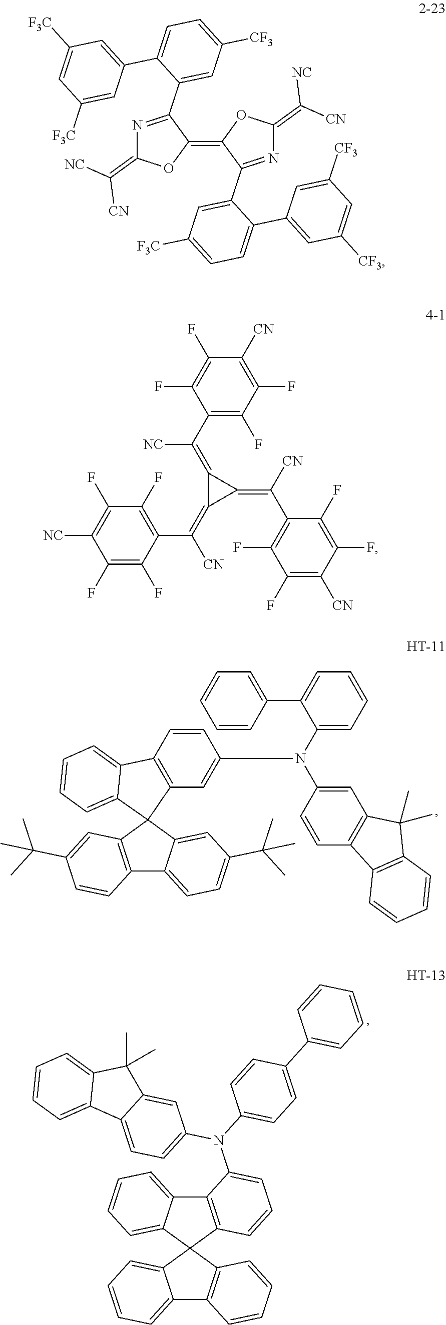

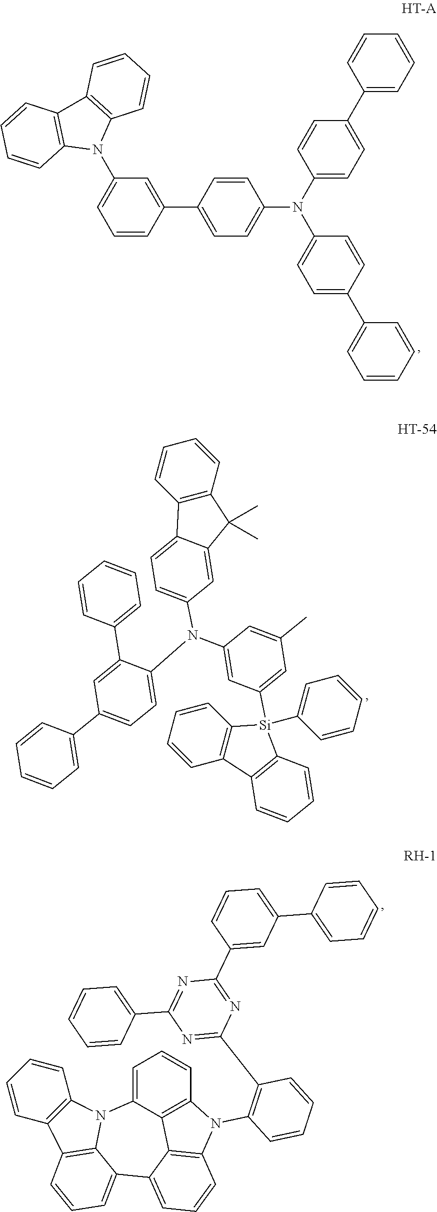 [SMILES: c1ccc(-c2ccc(N(c3ccc(-c4ccccc4)cc3)c3ccc(-c4cccc(-n5c6ccccc6c6ccccc65)c4)cc3)cc2)cc1 ; Cc1cc(N(c2ccc3c(c2)C(C)(C)c2ccccc2-3)c2ccc(-c3ccccc3)cc2-c2ccccc2)cc([Si]2(c3ccccc3)c3ccccc3-c3ccccc32)c1 ; c1ccc(-c2cccc(-c3nc(-c4ccccc4)nc(-c4ccccc4-n4c5cccc6c7cccc8c9ccccc9n(c9cccc4c9c65)c78)n3)c2)cc1]

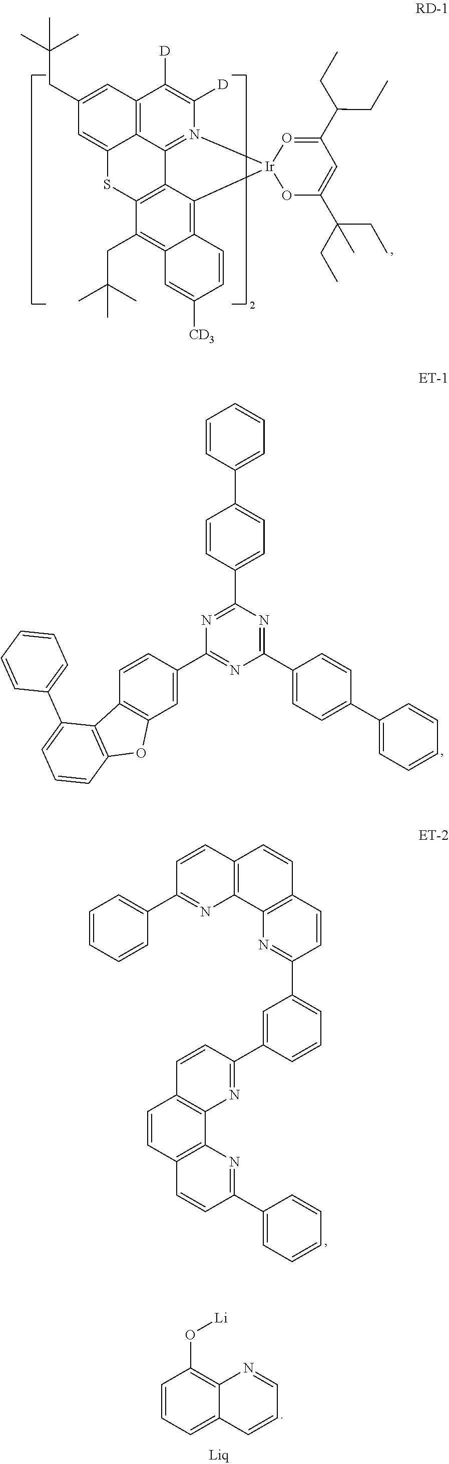

The performance of devices of Examples 1 to 9 and Comparative Examples 1 to 3 is summarized in Table 4. Voltage, current efficiency (CE), power efficiency (PE) and external quantum efficiency (EQE) were measured at a constant current density of 10 mA/cm².

TABLE 4
Device data in Examples 1 to 9 and Comparative Examples 1 to 3

| | Voltage | CE | PE | EQE |
|---|---|---|---|---|
| Device No. | (V) | (cd/A) | (lm/W) | (%) |
| Example 1 | 5.8 | 100 | 54 | 98 |
| Example 2 | 5.8 | 100 | 54 | 98 |
| Example 3 | 5.9 | 101 | 54 | 98 |
| Example 4 | 5.7 | 102 | 57 | 98 |
| Example 5 | 5.7 | 99 | 55 | 96 |
| Example 6 | 5.9 | 108 | 55 | 97 |
| Example 7 | 5.8 | 116 | 63 | 98 |
| Example 8 | 5.8 | 115 | 62 | 96 |
| Example 9 | 5.9 | 116 | 62 | 98 |
| Comparative Example 1 | 6.5 | 88 | 43 | 94 |
| Comparative Example 2 | 5.7 | 101 | 55 | 98 |
| Comparative Example 3 | 6.9 | 100 | 46 | 99 |

### Discussion

### Comparison of Examples 1 to 3 with Comparative Examples 1, 2 and 3

In Examples 1 to 3, Compound HT-11 is doped with Compound 1-20 as p-CGL, and the mass doping proportions of Compound 1-20 are 18%, 15% and 12%, respectively. As can be seen from the data in Table 1, the energy level difference between Compound 1-20 and Compound HT-11 is 0.06 eV, which satisfies the limitation of greater than −0.1 eV and less than 0.20 eV, and the lateral conductivities per unit doping σ₁₈, σ₁₅ and σ₁₂ of p-CGL of Examples 1 to 3 are 0.39×10⁻⁴ S/m, 0.25×10⁻⁴ S/m and 0.18×10⁻⁴ S/m, respectively, all satisfy the limitation of greater than or equal to 0.05×10⁻⁴ S/m and less than or equal to 1×10⁻⁴ S/m.

In Comparative Example 1, Compound HT-A is doped with 10% Compound 4-1 as p-CGL. As can be seen from the data in Table 1, the lateral conductivity per unit doping σ₁₀ of p-CGL of Comparative Example 1 is 0.27×10⁻⁴ S/m. Although p-CGL of Comparative Example 1 has a low lateral conductivity per unit doping, the energy level difference between Compound 4-1 and Compound HT-A is 0.22 eV, which is relatively large and makes it difficult to balance the carrier concentration in the organic layer. Compared with Comparative Example 1, the energy level difference of Examples 1 to 3 is smaller and the energy levels are more matched, which makes the amount of hole injection suitable, and the carriers in the device are more balanced, which is beneficial to improving the device performance. As can be seen from the data in Table 4, compared with Comparative Example 1, in Examples 1 to 3, the voltage is reduced by more than 0.6 V, the CE is improved by more than 13.6%, the PE is improved by more than 25.6%, and the EQE is improved slightly, exhibiting more excellent overall device performance.

In Comparative Example 2, Compound HT-11 is doped with 10% Compound 4-1 as p-CGL. As can be seen from the data in Table 1, the energy level difference between Compound 4-1 and Compound HT-11 is 0.09 eV. Although 0.09 eV satisfies the limitation of the present application, the lateral conductivity per unit doping of p-CGL in Comparative Example 2 is very high, σ₁₀ is 4.60×10⁻⁴ S/m, which is much higher than 1.0×10⁻⁴ S/m. Compared with Comparative Example 2, since p-CGL of Examples 1 to 3 has a particular low lateral conductivity per unit doping, the lateral crosstalk between the pixels can be significantly inhibited. Moreover, the material used in Comparative Example 2 is a commonly used material in the industry. As can be seen from the data in Table 4, Comparative Example 2 has very good device performance. The voltage, CE, PE and EQE of Examples 1 to 3 are basically equivalent to those of Comparative Example 2, and Examples 1 to 3 also have very excellent overall device performance.

In Comparative Example 3, as in Examples 1 to 3, Compound HT-11 is doped with Compound 1-20 as p-CGL. However, the mass doping proportion of Compound 1-20 used in Comparative Example 3 is only 4%. As can be seen from the data in Table 1, the lateral conductivity per unit doping σ₄ of p-CGL of Comparative Example 3 is 0.04×10⁻⁴ S/m. The lateral conductivity per unit doping is too low, and the number of holes in the entire common p-type charge generation layer is too small, resulting in a relatively high device voltage and relatively low PE. As can be seen from the data in Table 4, compared with Comparative Example 3, in Examples 1 to 3, the voltage is reduced by more than 1 V, the PE is improved by 17.4%, and the CE and the EQE are also maintained at high levels. It indicates that the particular active-matrix OLED display of the present disclosure still has a particular low lateral conductivity per unit doping while the mass doping proportion of the first organic material is increased and the amount of hole injection is ensured, effectively inhibiting the lateral crosstalk, further improving the device performance and having unique advantages.

### Comparison of Examples 4 and 5 with Comparative Examples 1, 2 and 3

In Examples 4 and 5, Compound HT-11 is doped with 15% and 12% Compound 1-24 as p-CGL, respectively. As can be seen from the data in Table 1, the energy level difference, doping proportion and lateral conductivity per unit doping of Examples 4 to 5 all satisfy the limitations of the present application.

Compared with Comparative Example 1, the energy level difference of Examples 4 to 5 is smaller and the energy levels are more matched. As can be seen from the data in Table 4, compared with Comparative Example 1, in Examples 4 to 5, the voltage is reduced by more than 0.8 V, the CE is improved by more than 12%, the PE is improved by more than 27%, and the EQE is improved slightly, exhibiting more excellent overall device performance.

Compared with Comparative Examples 2 and 3, since p-CGL of Examples 4 and 5 has the low lateral conductivity per unit doping, the lateral crosstalk can be significantly inhibited. As can be seen from the data in Table 4, Comparative Example 2 has very good device performance. The voltage, CE, PE and EQE of Examples 4 and 5 are basically equivalent to those of Comparative Example 2, exhibiting very excellent overall device performance. Compared with Comparative Example 3, in Examples 4 and 5, the voltage is reduced by more than 1.2 V, the PE is improved by 19.6%, and the CE and the EQE are also maintained at high levels basically equivalent to those of Comparative Example 3, having very excellent overall device performance.

In Example 6, Compound HT-3 is doped with 15% Compound 1-28 as p-CGL. As can be seen from the data in Table 1, the energy level difference, doping proportion and lateral conductivity per unit doping of Example 6 all satisfy the limitations of the present application. As can be seen from the data in Table 4, Example 6 also has very excellent overall device performance.

### Comparison of Examples 7 to 9 with Comparative Examples 1, 2 and 3

In Examples 7 to 9, Compound HT-11 is doped with 16%, 14% and 12% Compound 2-23 as p-CGL, respectively. As can be seen from the data in Table 1, the energy level difference, doping proportion and lateral conductivity per unit doping of Examples 7 to 9 all satisfy the limitations of the present application.

Compared with Comparative Example 1, the energy level difference of Examples 7 to 9 is smaller and the energy levels are more matched. As can be seen from the data in Table 4, compared with Comparative Example 1, in Examples 7 to 9, the voltage is reduced by more than 0.6 V, the CE is improved by more than 30.6%, the PE is improved by more than 44.1%, and the EQE is improved slightly, exhibiting more excellent overall device performance.

Compared with Comparative Examples 2 and 3, since p-CGL of Examples 7 to 9 has the low lateral conductivity per unit doping, the lateral crosstalk can be significantly inhibited. As can be seen from the data in Table 4, Comparative Example 2 already has very good device performance. The voltage and EQE of Examples 7 to 9 are basically equivalent to those of Comparative Example 2, the CE is improved by more than 13.8%, the PE is improved by more than 12.7%, exhibiting very excellent overall device performance. Compared with Comparative Example 3, in Examples 7 to 9, the voltage is reduced by more than 1.0 V, the CE is improved by more than 15%, the PE is improved by 34.7%, and the EQE are also maintained at high levels basically equivalent to those of Comparative Example 3, having very excellent overall device performance.

In conclusion, the particular energy level difference, particular high doping proportion and particular low lateral conductivity per unit doping of the two materials in the common p-type charge generation layer all play an important role in the device performance. In the common p-type charge generation layer of the active-matrix OLED display of the present application, the energy levels of the first organic material and the second_organic_material are matched, the carriers in the organic layer are balanced, and the first organic material has a particular high mass doping proportion so that a proper amount of hole injection can be ensured, improving device performance such as voltage and efficiency and having excellent overall performance. Moreover, the low lateral conductivity per unit doping ensures that the lateral migration amount of holes in the common p-type charge generation layer is at a low level, thereby significantly inhibiting the lateral crosstalk between the pixels in the display and having apparent advantages in commercial application.

It should be understood that various embodiments described herein are merely embodiments and not intended to limit the scope of the present disclosure. Therefore, it is apparent to those skilled in the art that the present disclosure as claimed may include variations of specific embodiments and preferred embodiments described herein. Many of the materials and structures described herein may be replaced with other materials and structures without departing from the spirit of the present disclosure. It should be understood that various theories as to why the present disclosure works are not intended to be limitative.

What is claimed is:

1. An active-matrix organic electroluminescent display, comprising a plurality of pixels;
wherein each of the plurality of pixels comprises at least one stacked organic electroluminescent device;
the stacked organic electroluminescent device comprises an anode, a cathode and at least two light-emitting units disposed between the anode and the cathode;
wherein at least one common p-type charge generation layer is comprised between two adjacent light-emitting units, and the common p-type charge generation layer is shared by at least two pixels;
the common p-type charge generation layer comprises a first organic material and a second organic material;
a LUMO energy level of the first organic material is denoted as LUMO_{first_organic_material}, a HOMO energy level of the second organic material is denoted as HOMO_{second_organic_material}, and −0.1 eV≤LUMO_{first_organic_material}−HOMO_{second_organic_material}<0.20 eV;
a mass doping proportion of the first organic material in the common p-type charge generation layer is A %, and 6≤A≤20; and
a lateral conductivity of the common p-type charge generation layer is B_{A}, a lateral conductivity per unit doping of the common p-type charge generation layer is σ_{A}, wherein σ_{A}=B_{A}/A, and at least one σ_{A} satisfies 0.05×10⁻⁴ S/m≤σ_{A}≤1.0×10⁻⁴ S/m.

2. The active-matrix organic electroluminescent display of claim 1, wherein the first organic material is selected from the following compounds: quinones or quinone derivatives, radialene compounds, dehydrobenzoxazole and dehydrobenzothiazole compounds, and bisoxazole or bisthiazole compounds.

3. The active-matrix organic electroluminescent display of claim 1, wherein the second organic material comprises any one or more chemical structural units selected from the group consisting of triarylamine, carbazole, fluorene, spirobifluorene, thiophene, furan, phenyl, oligophenylenevinylene, oligofluorene and combinations thereof;
preferably, the second organic material is a monotriarylamine compound or a bistriarylamine compound.

4. The active-matrix organic electroluminescent display of claim 1, wherein a method for testing the lateral conductivity B_{A} of the common p-type charge generation layer is as follows: depositing the first organic material and the second organic material on a test substrate prepared with an aluminum electrode in advance at a certain mass ratio through co-deposition at a vacuum degree of about 10⁻⁶ Torr, forming a to-be-tested region with a thickness of 100 nm, a length of 6 mm and a width of 1 mm, obtaining an electric resistance value of the region through a method of applying a voltage to the electrode and measuring a current at room temperature, and calculating the lateral conductivity B_{A} of the layer of Ohm's law and a geometric dimension.

5. The active-matrix organic electroluminescent display of claim 1, wherein the lateral conductivity of the common p-type charge generation layer is B_{A}, and 0.2×10⁻⁴ S/m<B_{A}<20×10⁻⁴ S/m;
preferably, 0.2×10⁻⁴ S/m<B_{A}<16×10⁻⁴ S/m;
more preferably, 0.2×10⁻⁴ S/m<B_{A}<12×10⁻⁴ S/m.

6. The active-matrix organic electroluminescent display of claim 1, wherein −0.05 eV≤LUMO_{first_organic_material}−HOMO_{second_organic_material}<0.20 eV;
preferably, 0.04 eV≤LUMO_{first_organic_material}−HOMO_{second_organic_material}<0.20 eV;
more preferably, 0.08 eV≤LUMO_{first_organic_material}−HOMO_{second_organic_material}<0.20 eV.

7. The active-matrix organic electroluminescent display of claim 1, wherein the mass doping proportion of the first organic material in the common p-type charge generation layer is A %, and 6≤A≤18;
preferably, 7≤A≤18;
more preferably, 7≤A≤15.

8. The active-matrix organic electroluminescent display of claim 1, wherein the lateral conductivity per unit doping of the common p-type charge generation layer is σ_{A}, wherein σ_{A}=B_{A}/A, and at least one σ_{A} satisfies 0.06×10⁻⁴ S/m≤σ_{A}≤1×10⁻⁴ S/m;
preferably, at least one Of satisfies 0.08×10⁻⁴ S/m<<<1×10⁻⁴ S/m;
more preferably, at least one σ_{A} satisfies 0.10×10⁻⁴ S/m≤σ_{A}<1×10⁻⁴ S/m.

9. The active-matrix organic electroluminescent display of claim 1, wherein the lateral conductivity per unit doping of the common p-type charge generation layer is A, wherein σ_{A}=B_{A}/A, and at least two σ_{A} satisfy 0.06×10⁻⁴ S/m≤σ_{A}≤1×10⁻⁴ S/m;
preferably, at least two σ_{A} satisfy 0.08×10⁻⁴ S/m≤σ_{A}<1×10⁻⁴ S/m;
more preferably, at least two σ_{A} satisfy 0.10×10⁻⁴ S/m≤σ₄<1×10⁻⁴ S/m.

10. The active-matrix organic electroluminescent display of claim 1, wherein the lateral conductivity per unit doping of the common p-type charge generation layer is σ_{A}, wherein σ_{A}=B_{A}/A, and at least three Of satisfy 0.06×10⁻⁴ S/m<<<1×10⁻⁴ S/m;
preferably, at least three σ_{A} satisfy 0.08×10⁻⁴ S/m≤σ_{A}<1×10⁻⁴ S/m;
more preferably, at least three σ_{A} satisfy 0.10×10⁻⁴ S/m≤σ_{A}<1×10⁻⁴ S/m.

11. The active-matrix organic electroluminescent display of claim 1, wherein the lateral conductivity per unit doping of the common p-type charge generation layer is σ_{A}, wherein σ_{A}=B_{A}/A, and at least σ₁₂, σ₁₅ and σ₁₈ all satisfy 0.06×10⁻⁴ S/m≤σ_{A}≤1×10⁻⁴ S/m;
preferably, at least σ₁₂, σ₁₅ and σ₁₈ all satisfy 0.08×10⁻⁴ S/m≤σ₄<1×10⁻⁴ S/m;
more preferably, at least σ₁₂, σ₁₅ and σ₁₈ all satisfy 0.10×10⁻⁴ S/m≤σ_{A}≤1×10⁻⁴ S/m.

12. The active-matrix organic electroluminescent display of claim 1, wherein the lateral conductivity per unit doping of the common p-type charge generation layer is σ_{A}, wherein σ_{A}=B_{A}/A, and all σ_{A} satisfy 0.06×10⁻⁴ S/m≤σ_{A}≤1×10⁻⁴ S/m;
preferably, all σ_{A} satisfy 0.08×10⁻⁴ S/m≤σ_{A}<1×10⁻⁴ S/m;
more preferably, all σ_{A} satisfy 0.10×10⁻⁴ S/m≤σ_{A}<1×10⁻⁴ S/m.

13. The active-matrix organic electroluminescent display of claim 1, wherein −5.30 eV≤LUMO_{first_organic_material}≤−4.80 eV;
preferably, −5.20 eV≤LUMO_{first_organic_material}≤−4.90 eV;
more preferably, −5.18 eV≤LUMO_{first_organic_material}≤−4.95 eV.

14. The active-matrix organic electroluminescent display of claim 1, wherein −5.35 eV≤HOMO_{second_organic_material}≤−5.00 eV;
preferably, −5.33 eV≤HOMO_{second_organic_material}≤−5.00 eV;
more preferably, −5.30 eV≤HOMO_{second_organic_material}≤−5.04 eV.

15. The active-matrix organic electroluminescent display of claim 1, wherein the light-emitting units comprise a common second organic layer disposed between the common p-type charge generation layer and the cathode;
preferably, the second organic layer is in direct contact with the common p-type charge generation layer;
more preferably, the common second organic layer is a hole transport layer.

16. The active-matrix organic electroluminescent display of claim 15, wherein the common second organic layer has a thickness of greater than or equal to 20 nm;
preferably, the common second organic layer has a thickness of greater than or equal to 40 nm;
more preferably, the common second organic layer has a thickness of greater than or equal to 60 nm.

17. The active-matrix organic electroluminescent display of claim 15, wherein the common second organic layer comprises a third organic material;
preferably, the third organic material is the same as or different from the second organic material;
more preferably, the third organic material is the same as the second organic material.

18. The active-matrix organic electroluminescent display of claim 1, wherein the light-emitting units comprise a common third organic layer disposed between the common p-type charge generation layer and the anode;
preferably, the common third organic layer is in direct contact with the anode;
more preferably, the common third organic layer is a hole injection layer.

19. The active-matrix organic electroluminescent display of claim 18, wherein the common third organic layer comprises at least one p-type conductive dopant and at least one hole transport material;
preferably, the third organic layer has a thickness of greater than or equal to 2 nm;
more preferably, the third organic layer has a thickness of greater than or equal to 5 nm.

20. The active-matrix organic electroluminescent display of claim 1, wherein at a constant current density of 10 mA/cm², the stacked organic electroluminescent device has a voltage of less than or equal to 8 V;
preferably, at a constant current density of 10 mA/cm², the stacked organic electroluminescent device has a voltage of less than or equal to 7 V;
more preferably, at a constant current density of 10 mA/cm², the stacked organic electroluminescent device has a voltage of less than or equal to 6 V.

21. An electronic device, comprising the active-matrix organic electroluminescent display of claim 1.
